(19) United States
(12) Patent Application Publication
(10) Pub. No.: US 2026/0237346 A1
(43) Pub. Date: Aug. 13, 2026

(54) METHOD FOR DRIVING DISPLAY DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Junichi KOEZUKA, Tochigi, Tochigi (JP); Daisuke KUBOTA, Atsugi, Kanagawa (JP); Koji KUSUNOKI, Isehara, Kanagawa (JP)

(21) Appl. No.: 19/470,915

(22) PCT Filed: Apr. 22, 2024
(86) PCT No.: PCT/IB2024/053883

§ 371 Date: Sep. 30, 2025

(30) Foreign Application Priority Data
Apr. 27, 2023 (JP) 2023-073786

(51) Int. Cl. G09G 3/3208; G06F 3/042; H10K 59/40

(52) U.S. Cl. CPC G09G 3/3208; G06F 3/042; G09G 2300/0426; G09G 2310/08; H10K 59/40

(57) ABSTRACT

A display device capable of image capturing with high sensitivity is provided. A light-emitting element emitting visible light, an infrared light-emitting element emitting infrared light, and a light-receiving element that has sensitivity to infrared light are provided in a display region. After the light-emitting element emits light to display an image on the display region, black display is performed. In the period in which black display is performed, the infrared light-emitting element emits light and light exposure is performed on the light-receiving element. The light-receiving element detects infrared light emitted from the infrared light-emitting element and reflected by an object that is in contact with or approaches the display region. The display device functions as a touch sensor or a noncontact sensor.

### TECHNICAL FIELD

One embodiment of the present invention relates to a display device and a driving method thereof. One embodiment of the present invention relates to an imaging device and a driving method thereof. One embodiment of the present invention relates to a display device having an image capturing function. One embodiment of the present invention relates to a display module. One embodiment of the present invention relates to an electronic device.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, display apparatuses have been required to have higher definition in order to display high-resolution images. In addition, display apparatuses used in information terminal devices such as smartphones, tablet terminals, and notebook PCs (personal computers) have been required to have lower power consumption as well as higher resolution. Furthermore, display apparatuses have been required to have a variety of functions such as a function of a touch sensor and a function of capturing images of fingerprints for authentication, in addition to a function of displaying images.

Light-emitting apparatuses including light-emitting elements have been developed, for example, as display apparatuses. Light-emitting elements (also referred to as EL elements) utilizing an electroluminescence (hereinafter, referred to as EL) phenomenon have features such as ease of reduction in thickness and weight, high-speed response to an input signal, and driving with a direct-constant voltage source, and have been used in display apparatuses. For example, Patent Document 1 discloses a flexible light-emitting apparatus including an organic EL element.

Non-Patent Document 1 discloses a method for manufacturing an organic optoelectronic device using standard UV photolithography.

### REFERENCES

### Patent Document

[Patent Document 1] Japanese Published Patent Application No. 2014-197522

### Non-Patent Document

[Non-Patent Document 1] B. Lamprecht et al., “Organic optoelectronic device fabrication using standard UV photolithography” phys. stat. sol. (RRL) 2, No. 1, p. 16-18 (2008)

### SUMMARY OF THE INVENTION

### Problems to be Solved by the Invention

An object of one embodiment of the present invention is to provide a display device capable of image capturing with high sensitivity or an imaging device capable of image capturing with high sensitivity. Another object of one embodiment of the present invention is to provide a display device capable of displaying a high-quality image. Another object of one embodiment of the present invention is to provide a display device functioning as a touch sensor. Another object of one embodiment of the present invention is to provide a high-resolution display device or a high-resolution imaging device. Another object of one embodiment of the present invention is to provide a display device with a high aperture ratio or an imaging device with a high aperture ratio. Another object of one embodiment of the present invention is to provide a highly reliable display device or a highly reliable imaging device. Another object of one embodiment of the present invention is to provide a display device with a novel structure or an imaging device with a novel structure. Another object of one embodiment of the present invention is to provide an electronic device including the display device or the imaging device. Another object of one embodiment of the present invention is to provide a method for manufacturing the display device, the imaging device, or the electronic device.

An object of one embodiment of the present invention is to provide a method for driving a display device capable of image capturing with high sensitivity or a method for driving an imaging device capable of image capturing with high sensitivity. Another object of one embodiment of the present invention is to provide a method for driving a display device capable of displaying a high-quality image. Another object of one embodiment of the present invention is to provide a method for driving a display device functioning as a touch sensor. Another object of one embodiment of the present invention is to provide a method for driving a high-resolution display device or a method for driving a high-resolution imaging device. Another object of one embodiment of the present invention is to provide a method for driving a display device with a high aperture ratio or a method for driving an imaging device with a high aperture ratio. Another object of one embodiment of the present invention is to provide a method for driving a highly reliable display device or a method for driving a highly reliable imaging device. Another object of one embodiment of the present invention is to provide a method for driving a display device with a novel structure or a method for driving an imaging device with a novel structure.

Note that the description of these objects does not preclude the existence of other objects. One embodiment of the present invention does not necessarily achieve all these objects. Note that other objects can be derived from the description of the specification, the drawings, the claims, and the like.

### Means for Solving the Problems

One embodiment of the present invention is a method for driving a display device including a display region. A first pixel including a first light-emitting element, a second pixel including a second light-emitting element, and a first sensor pixel including a first light-receiving element are provided in the display region. The method includes: a first period in which first image data is written to the first pixel; a second period in which second image data is written to the second pixel; a third period in which the first light-emitting element and the second light-emitting element are brought into a light-emitting state; and a fourth period in which the first light-emitting element and the second light-emitting element are brought into a non-light-emitting state. Light exposure is performed on the first light-receiving element in the fourth period.

Alternatively, in the above embodiment, the first pixel may include a first transistor. The second pixel may include a second transistor. The first transistor may be in a conduction state in the first period and may be in a non-conduction state in the second to the fourth periods. The second transistor may be in a conduction state in the second period, and may be in a non-conduction state in the first period, the third period, and the fourth period. The first transistor may include a first semiconductor layer provided with a first channel formation region. The second transistor may include a second semiconductor layer provided with a second channel formation region. The first semiconductor layer and the second semiconductor layer may each include a metal oxide.

Alternatively, in the above embodiment, the first channel formation region and the second channel formation region may each be provided along a side surface of an insulating layer.

Alternatively, in the above embodiment, a third pixel including a third light-emitting element, a fourth pixel including a fourth light-emitting element, and a second sensor pixel including a second light-receiving element may be provided in the display region. A fifth period in which third image data is written to the third pixel and a sixth period in which fourth image data is written to the fourth pixel may be provided between the second period and the third period. The third light-emitting element and the fourth light-emitting element may be brought into a light-emitting state in the third period. The third light-emitting element and the fourth light-emitting element may be brought into a non-light-emitting state in the fourth period. Light exposure may be performed on the second light-receiving element in the fourth period.

Alternatively, in the above embodiment, the first semiconductor layer and the second semiconductor layer may each include a metal oxide.

Another embodiment of the present invention is a method for driving a display device comprising a display region. A first pixel including a first light-emitting element, a second pixel including a second light-emitting element, a third pixel including a third light-emitting element, a fourth pixel including a fourth light-emitting element, a first sensor pixel including a first light-receiving element, a second sensor pixel including a second light-receiving element are provided in the display region. The method includes: a first period in which first image data is written to the first pixel; a second period in which second image data is written to the second pixel; a third period in which the first light-emitting element and the second light-emitting element are brought into a light-emitting state and third image data is written to the third pixel and fourth image data is written to the fourth pixel sequentially; a fourth period in which the first light-emitting element and the second light-emitting element are brought into a non-light-emitting state and the third light-emitting element and the fourth light-emitting element are brought into a light-emitting state; and a fifth period in which the third light-emitting element and the fourth light-emitting element are brought into a non-light-emitting state. Light exposure is performed on the first light-receiving element in the fourth period, and light exposure is performed on the second light-receiving element in the fifth period.

Alternatively, in the above embodiment, the first sensor pixel may include a first transistor. The second sensor pixel may include a second transistor. The first transistor may include a first semiconductor layer provided with a first channel formation region. The second transistor may include a second semiconductor layer provided with a second channel formation region. The first channel formation region and the second channel formation region may each be provided along a side surface of an insulating layer.

Another embodiment of the present invention is a method for driving a display device including a display region. A first pixel including a first light-emitting element, a second pixel including a second light-emitting element, and a sensor pixel including a light-receiving element are provided in the display region. A first operation for writing first image data to the first pixel, a second operation for bringing the first light-emitting element into a light-emitting state, and a third operation for bringing the first light-emitting element into a non-light-emitting state are performed sequentially. A fourth operation for writing second image data to the second pixel is performed in a period in which the second operation is performed, and then a fifth operation for bringing the second light-emitting element into a light-emitting state and a sixth operation for bringing the second light-emitting element into a non-light-emitting state are performed sequentially. A period in which the third operation is performed and a period in which the sixth operation is performed partly overlap with each other. Light exposure is performed on the light-receiving element in the overlap period in which both the third operation and the sixth operation are performed.

Alternatively, in the one embodiment of the present invention, the sensor pixel may include a transistor. The transistor may include a semiconductor layer provided with a channel formation region. The channel formation region may be provided along a side surface of an insulating layer.

Alternatively, in the one embodiment of the present invention, an infrared light-emitting element emitting infrared light may be provided in the display region.

### Effect of the Invention

One embodiment of the present invention can provide a display device capable of image capturing with high sensitivity or an imaging device capable of image capturing with high sensitivity. Another embodiment of the present invention can provide a display device capable of displaying a high-quality image. Another embodiment of the present invention can provide a display device functioning as a touch sensor. Another embodiment of the present invention can provide a high-resolution display device or a high-resolution imaging device. Another embodiment of the present invention can provide a display device with a high aperture ratio or an imaging device with a high aperture ratio. Another embodiment of the present invention can provide a highly reliable display device or a highly reliable imaging device. Another embodiment of the present invention can provide a display device with a novel structure or an imaging device with a novel structure. Another embodiment of the present invention can provide an electronic device including the display device or the imaging device. Another embodiment of the present invention can provide a method for manufacturing the display device, the imaging device, or the electronic device.

One embodiment of the present invention can provide a method for driving a display device capable of image capturing with high sensitivity or an imaging device capable of image capturing with high sensitivity. Another embodiment of the present invention can provide a method for driving a display device capable of displaying a high-quality image. Another embodiment of the present invention can provide a method for driving a display device functioning as a touch sensor. Another embodiment of the present invention can provide a method for driving a high-resolution display device or a method for driving a high-resolution imaging device. Another embodiment of the present invention can provide a method for driving a display device with a high aperture ratio or a method for driving an imaging device with a high aperture ratio. Another embodiment of the present invention can provide a method for driving a highly reliable display device or a method for driving a highly reliable imaging device. Another embodiment of the present invention can provide a method for driving a display device with a novel structure or a method for driving an imaging device with a novel structure.

Note that the description of these effects does not preclude the existence of other effects. One embodiment of the present invention does not need to have all these effects. Note that effects other than these can be derived from the descriptions of the specification, the drawings, the claims, and the like.

### BRIEF DESCRIPTION OF THE DRAWINGS

FIG. 1A is a block diagram illustrating a structure example of a display device. FIG. 1B and FIG. 1C are each a plan view illustrating a structure example of a pixel. FIG. 1D and FIG. 1E are schematic views illustrating functions of the display device.

FIG. 2 is a block diagram illustrating a structure example of a display device.

FIG. 3 is a circuit diagram illustrating a structure example of a subpixel.

FIG. 4 is a circuit diagram illustrating a structure example of a subpixel.

FIG. 5A to FIG. 5C are circuit diagrams each illustrating a structure example of a pixel.

FIG. 6A and FIG. 6B are circuit diagrams each illustrating a structure example of a pixel.

FIG. 7A to FIG. 7C are schematic views illustrating examples of a method for driving a display device.

FIG. 8A and FIG. 8B are schematic views illustrating an example of a method for driving a display device.

FIG. 9A and FIG. 9B are schematic views illustrating an example of a method for driving a display device.

FIG. 10 is a timing chart showing an example of a method for driving a display device.

FIG. 11 is a timing chart showing an example of a method for driving a display device.

FIG. 12 is a timing chart showing an example of a method for driving a display device.

FIG. 13A is a plan view illustrating a structure example of a semiconductor device. FIG. 13B and FIG. 13C are cross-sectional views illustrating a structure example of a semiconductor device.

FIG. 14 is a perspective view illustrating a structure example of a semiconductor device.

FIG. 15A is a plan view illustrating a structure example of a semiconductor device. FIG. 15B is a cross-sectional view illustrating a structure example of a semiconductor device.

FIG. 16A and FIG. 16B are cross-sectional views each illustrating a structure example of a semiconductor device.

FIG. 17A is a plan view illustrating a structure example of a semiconductor device. FIG. 17B and FIG. 17C are cross-sectional views illustrating a structure example of the semiconductor device.

FIG. 18A is a plan view illustrating a structure example of a semiconductor device. FIG. 18B and FIG. 18C are cross-sectional views illustrating a structure example of the semiconductor device.

FIG. 19 is a perspective view illustrating a structure example of a display device.

FIG. 20 is a cross-sectional view illustrating a structure example of a display device.

FIG. 21 is a cross-sectional view illustrating a structure example of a display device.

FIG. 22 is a cross-sectional view illustrating a structure example of a display device.

FIG. 23 is a cross-sectional view illustrating a structure example of a display device.

FIG. 24 is a cross-sectional view illustrating a structure example of a display device.

FIG. 25A to FIG. 25D are diagrams illustrating structure examples of an electronic device.

FIG. 26A to FIG. 26D are diagrams illustrating structure examples of electronic devices.

FIG. 27A to FIG. 27G are diagrams illustrating structure examples of electronic devices.

### MODE FOR CARRYING OUT THE INVENTION

Hereinafter, embodiments are described with reference to the drawings. Note that the embodiments can be implemented in many different modes, and it is readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatching pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that in this specification and the like, the ordinal numbers such as “first” and “second” are used in order to avoid confusion among components and do not limit the number.

Hereinafter, the expressions indicating directions such as “over” and “under” are basically used to correspond to the directions of drawings. However, in some cases, the direction indicating “over” or “under” in the specification does not correspond to the direction in the drawings for the purpose of description simplicity, for example. For example, in the explanation of a stacking order (or formation order) of a stack, even when a surface on which the stack is provided (e.g., a formation surface, a support surface, an adhesion surface, or a flat surface) is positioned above the stack in the drawing, the expression “the formation surface is under the stack” or “the stack is above the surface” is employed in some cases.

Note that in this specification and the like, a “conduction state” or an “on state” of a transistor refers to a state where a source and a drain of the transistor can be regarded as being electrically short-circuited or a state where a current can be made to flow between the source and the drain. For example, the “conduction state” or the “on state” refers to a state where a voltage between a gate and a source is higher than a threshold voltage in an n-channel transistor, a state where a voltage between a gate and a source is lower than a threshold voltage in a p-channel transistor, or the like in some cases. A “non-conduction state”, a “cutoff state”, or an “off state” of a transistor refers to a state where a source and a drain of the transistor can be regarded as being electrically disconnected. For example, the “non-conduction state”, the “cutoff state”, or the “off state” refers to a state where a voltage between a gate and a source is lower than a threshold voltage in an n-channel transistor, a state where a voltage between a gate and a source is higher than a threshold voltage in a p-channel transistor, or the like in some cases.

In this specification and the like, a “gate voltage” refers to a voltage between a gate and a source, a “drain voltage” refers to a voltage between a drain and a source, and a “back gate voltage” refers to a voltage between a back gate and a source in some cases. In addition, “drain current” refers to current flowing from a drain to a source in some cases.

In this specification and the like, “off-state current” of a transistor refers to a drain current of the transistor in the off state unless otherwise specified. Note that in this specification and the like, an off-state current and a current flowing from a gate to a source and a drain (also referred to as a gate leakage current) are sometimes referred to as leakage current.

In this specification and the like, the term “film” and the term “layer” can be interchanged with each other depending on the case or according to circumstances. For example, in some cases, the term “conductive layer” and the term “insulating layer” can be interchanged with the term “conductive film” and the term “insulating film”, respectively.

Note that in this specification and the like, an EL layer means a layer containing at least a light-emitting substance (also referred to as a light-emitting layer) or a stack including the light-emitting layer provided between a pair of electrodes of a light-emitting element. A PD layer refers to a layer that is provided between a pair of electrodes of a light-receiving element and contains at least a light-receiving material (such a layer is also referred to as an active layer, a light-receiving layer, or a photoelectric conversion layer), or a stack including an active layer.

In this specification and the like, a display panel that is one embodiment of a display apparatus has a function of displaying (outputting), for example, an image on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### EMBODIMENT 1

In this embodiment, a structure example of a display device of one embodiment of the present invention, an example of a method for driving the display device, and the like will be described.

One embodiment of the present invention is a display device in which a light-emitting element (also referred to as a light-emitting device) and a light-receiving element (also referred to as a light-receiving device) are provided in a display region and a method for driving the display device. In the display device of one embodiment of the present invention, the light-emitting element emits visible light (light with a wavelength greater than or equal to 400 nm and less than 780 nm), so that an image can be displayed on the display region. The display device of one embodiment of the present invention can perform image capturing using the light-receiving element. The display device of one embodiment of the present invention performs image capturing and thus can function as a touch sensor (also referred to as a direct touch sensor) or a noncontact sensor (also referred to as a hover sensor, a hover touch sensor, or a touchless sensor).

The touch sensor can detect an object (e.g., a finger, a hand, or a pen) when the display device and the object come in direct contact with each other. The noncontact sensor can detect the object even when the object is not in contact with but is approaching the display device. Here, the display device of one embodiment of the present invention can perform image capturing using the light-receiving element and thus functions as an imaging device. Accordingly, one embodiment of the present invention can be regarded as a display device having an image capturing function or an imaging device having a display function.

When black display is performed after an image is displayed in the display region by making the light-emitting element emit light, an afterimage, an image blur, and the like in moving image display can be reduced, for example. Thus, a high-quality image can be displayed particularly when a moving image is displayed in the display region. A driving method by which black display is performed in this manner is referred to as black insertion driving. The black insertion driving is also referred to as a “pseudo impulsive type” or “pseudo impulsive driving”.

In the method for driving the display device of one embodiment of the present invention, light exposure is performed on the light-receiving element in a period in which black display is performed. This can prevent light emitted from the light-emitting element from entering the light-receiving element and becoming a noise during the light exposure period. The display device of one embodiment of the present invention can perform image capturing with less noise and high sensitivity. Thus, the display device of one embodiment of the present invention can detect contact of an object with or proximity of the object to a display region with high sensitivity, for example. Accordingly, the display device of one embodiment of the present invention can function as, for example, a highly sensitive touch sensor or a highly sensitive noncontact sensor.

In this specification and the like, the term “light exposure” can be replaced with image capturing or shooting.

In the display device of one embodiment of the present invention, a light-receiving element having sensitivity to infrared light and a light-emitting element emitting infrared light are provided in a display region, for example. Here, a light-emitting element emitting infrared light is also referred to as an infrared light-emitting element. The infrared light-emitting element emits light in a black display period. Then, infrared light emitted from the infrared light-emitting element and incident on the light-receiving element is detected by the light-receiving element. For example, the light-receiving element detects infrared light emitted from the infrared light-emitting element and reflected by an object that is in contact with or approaches the display region. Thus, the display device of one embodiment of the present invention can detect contact of the object with or proximity of the object to the display region, for example. Note that the infrared light-emitting element may emit light in a period in which an image is displayed on the display region, i.e., a period in which the light-emitting element emits visible light.

### Structure Example_1 of Display Device

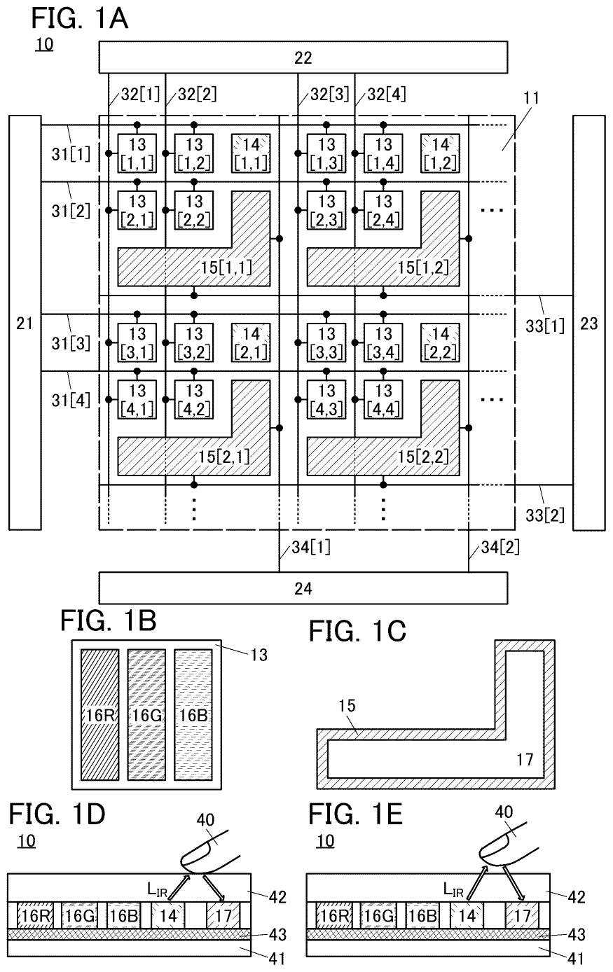

FIG. 1A is a block diagram illustrating a structure example of a display device 10 that is the display device of one embodiment of the present invention. The display device 10 includes a display region 11, a driver circuit 21, a driver circuit 22, a driver circuit 23, and a driver circuit 24. In the display region 11, a plurality of pixels 13 arranged in a matrix and a plurality of pixels 15 arranged in a matrix are provided. In the display region 11, light-emitting elements 14 are also provided.

FIG. 1A illustrates the pixels 13 in four rows and four columns, the pixels 15 in two rows and two columns, and the light-emitting elements 14 in two rows and two columns. In FIG. 1A, for example, the pixel 13 in the first row and the first column is denoted by a pixel 13[1,1], and the pixel 13 in the fourth row and the fourth column is denoted by a pixel 13[4,4]. For example, the pixel 15 in the first row and the first column is denoted by a pixel 15[1,1], and the pixel 15 in the second row and the second column is denoted by a pixel 15[2,2]. Furthermore, for example, the light-emitting element 14 in the first row and the first column is denoted by a light-emitting element 14[1,1], and the light-emitting element 14 in the second row and the second column is denoted by a light-emitting element 14[2,2].

The driver circuit 21 is electrically connected to the pixels 13 through wirings 31. The wirings 31 extend in the row direction of the matrix, for example. Here, the wirings 31 electrically connected to the pixels 13 in the first to fourth rows are denoted by a wiring 31[1] to a wiring 31[4], respectively.

The driver circuit 22 is electrically connected to the pixels 13 through wirings 32. The wirings 32 extend in the column direction of the matrix, for example. Here, the wirings 32 electrically connected to the pixels 13 in the first to fourth columns are denoted by a wiring 32[1] to a wiring 32[4], respectively. Note that as illustrated in FIG. 1A, the wiring 32 includes a region overlapping with the pixel 15 in some cases. The wiring 31 includes a region overlapping with the pixel 15 in some cases.

The driver circuit 23 is electrically connected to the pixels 15 through wirings 33. The wirings 33 extend in the row direction of the matrix, for example. Here, the wirings 33 electrically connected to the pixels 15 in the first row and the second row are denoted by a wiring 33[1] and a wiring 33[2], respectively.

The driver circuit 24 is electrically connected to the pixels 15 through wirings 34. The wirings 34 extend in the column direction of the matrix, for example. Here, the wirings 34 electrically connected to the pixels 15 in the first column and the second column are denoted by a wiring 34[1] and a wiring 34[2], respectively. Note that one or both of the wiring 33 and the wiring 34 include a region overlapping with the pixel 13 in some cases. Furthermore, at least one of the wiring 31 to the wiring 34 includes a region overlapping with the light-emitting element 14 in some cases.

The pixel 13 includes a light-emitting element, and an image can be displayed on the display region 11 due to visible light emission by the light-emitting element. Meanwhile, the light-emitting element 14 emits invisible light, for example, infrared light. The light-emitting element 14 preferably emits near-infrared light having a peak at a wavelength greater than or equal to 780 nm and less than or equal to 2500 nm, for example. Note that in the case where the light-emitting element 14 emits infrared light, the light-emitting element 14 is also referred to as an infrared light-emitting element or an infrared light-emitting device.

The pixel 15 includes a light-receiving element and can detect light incident on the pixel 15. Specifically, light incident on the pixel 15 can be detected during the light exposure period. The light-receiving element has sensitivity to light emitted from the light-emitting element 14, for example.

The driver circuit 21 has a function of selecting, row by row, the pixels 13 to which image data is to be written, for example. Specifically, the driver circuit 21 can select the pixel 13 to which image data is to be written by outputting a signal to the wiring 31. Here, the driver circuit 21 can select all the pixels 13 by, for example, outputting the signal to the wiring 31 in the first row, outputting the signal to the wiring 31 in the second row, and then outputting the signal to the wirings 31 from the third row to the last row sequentially. Thus, the signal output from the driver circuit 21 to the wirings 31 is a scan signal. Accordingly, the wiring 31 can be referred to as a scan line, and the driver circuit 21 can be referred to as a scan line driver circuit. Although FIG. 1A illustrates an example in which one pixel 13 is electrically connected to one wiring 31, one pixel 13 may be electrically connected to a plurality of wirings 31. In that case, some of the plurality of wirings 31 do not necessarily function as scan lines. That is, some of the signals output from the driver circuit 21 to the wirings 31 are not necessarily scan signals.

The driver circuit 22 has a function of generating image data. The image data is supplied to the pixel 13 through the wiring 32. For example, image data can be written to all the pixels 13 included in a row selected by the driver circuit 21. Here, the image data can be represented as a signal (image signal). Thus, the wiring 32 can be referred to as a signal line, and the driver circuit 22 can be referred to as a signal line driver circuit. Although FIG. 1A illustrates an example in which one pixel 13 is electrically connected to one wiring 32, one pixel 13 may be electrically connected to a plurality of wirings 32. In that case, some of the plurality of wirings 32 do not necessarily function as signal lines. That is, some of the signals output from the driver circuit 22 to the wirings 32 are not necessarily image signals.

The driver circuit 23 has a function of selecting a row of the pixels 15 and is also referred to as a row driver circuit or a row selection driver circuit. The driver circuit 23 has a function of selecting the pixel 15 from which imaging data obtained by light exposure is read, for example. Although FIG. 1A illustrates an example in which one pixel 15 is electrically connected to one wiring 33, one pixel 15 may be electrically connected to a plurality of wirings 33.

The driver circuit 24 has a function of reading imaging data from the pixel 15 and is also referred to as a reading circuit. The driver circuit 24 can read imaging data from the pixels 15 selected by the driver circuit 23, for example. The driver circuit 24 includes, for example, a column driver circuit (also referred to as a column selection driver circuit) having a function of selecting a column of the pixels 15. The driver circuit 24 includes a CDS circuit having a function of performing correlated double sampling (CDS) on imaging data output from the pixel 15. Furthermore, the driver circuit 24 includes an analog-digital converter circuit (also referred to as an A/D converter circuit) having a function of converting analog data output from a CDS circuit into digital data.

As illustrated in FIG. 1A, the number of pixels 15 provided in the display region 11 can be smaller than the number of pixels 13. Although the details will be described later, light exposure is performed on the light-receiving element included in the pixel 15 in a period in which the light-emitting element included in the pixel 13 does not emit light, i.e., the light-emitting element is in a non-light-emitting state (also referred to as a non-light-emitting period). Thus, by reducing the number of pixels 15, a period for performing light exposure on each of the pixels 15 can be ensured even when the non-emission period is short. Furthermore, by reducing the number of pixels 15, the area of a light-receiving region per pixel 15 can be increased. In the above manner, the display device 10 can perform image capturing with high sensitivity.

FIG. 1A illustrates an example in which one pixel 15 is provided per four pixels 13 (two rows and two columns) in the display region 11. Note that, for example, one pixel 15 may be provided per nine (three rows and three columns) pixels 13 in the display region 11, one pixel 15 may be provided per sixteen (four rows and four columns) pixels 13 in the display region 11, or one pixel 15 may be provided per more than sixteen pixels 13 in the display region 11.

Although FIG. 1A illustrates an example in which one pixel 15 is provided outside four pixels 13 and has a shape obtained by combining two rectangles, one embodiment of the present invention is not limited thereto. For example, four pixels 13 may be provided around the pixel 15. In that case, at least part of the pixel 15 can be surrounded by the four pixels 13. The pixel 15 may be provided to surround the entire four pixels 13. The same applies to the case where one pixel 15 is provided per pixel 13, two pixels 13, or three pixels 13 in the display region 11, and the case where one pixel 15 is provided per five or more pixels 13 in the display region 11.

Although FIG. 1A illustrates an example in which the same number of light-emitting elements 14 as the pixel 15 are provided in the display region 11, one embodiment of the present invention is not limited thereto. For example, the number of the light-emitting elements 14 may be smaller than the number of the pixels 15. For example, the number of the light-emitting elements 14 may be ¼, 1/16, or smaller than the number of the pixels 15. For example, the light-emitting element 14 may be provided in the center of the display region 11 or a region in the vicinity thereof, and the pixel 13 and the pixel 15 may be provided around the light-emitting element 14.

For another example, four pixels 13 may be provided around the light-emitting element 14. In that case, at least part of the light-emitting element 14 can be surrounded by the four pixels 13. The light-emitting element 14 may be provided to surround the entire four pixels 13. Furthermore, the light-emitting element 14 may be provided to surround at least part of four pixels 13 and one pixel 15. The same applies to the case where one light-emitting element 14 is provided per pixel 13, two pixels 13, or three pixels 13 in the display region 11, and the case where one light-emitting element 14 is provided per five or more pixels 13 in the display region 11.

FIG. 1B is a plan view illustrating a structure example of the pixel 13. The pixel 13 includes a plurality of subpixels, and each subpixel is provided with a light-emitting element 16. FIG. 1B illustrates an example in which the pixel 13 includes a light-emitting element 16R, a light-emitting element 16G, and a light-emitting element 16B. Planar shapes of the light-emitting elements 16 illustrated in FIG. 1B correspond to planar shapes of light-emitting regions of the light-emitting elements 16. Although FIG. 1B illustrates the light-emitting element 16R, the light-emitting element 16G, and the light-emitting element 16B that have the same or substantially the same planar shapes, one embodiment of the present invention is not limited thereto. The planar shapes of the light-emitting element 16R, the light-emitting element 16G, and the light-emitting element 16B can be separately determined as appropriate. The light-emitting element 16R, the light-emitting element 16G, and the light-emitting element 16B may have different planar shapes, or two or more of the light-emitting elements 16R, 16G, and 16B may have the same or substantially the same planar shapes.

In this specification and the like, matters common to the light-emitting element 16R, the light-emitting element 16G, and the light-emitting element 16B are sometimes described using the collective term “light-emitting element 16” without letters of the alphabet distinguishing them from each other. As for other components that are distinguished from each other using letters of the alphabet, matters common to the components are sometimes described using reference numerals without the letters of the alphabet.

The pixel 13 illustrated in FIG. 1B employs stripe arrangement as a method for arranging the subpixels. Examples of the method for arranging the subpixels include S-stripe arrangement, matrix arrangement, delta arrangement, Bayer arrangement, and PenTile arrangement.

The light-emitting element 16R, the light-emitting element 16G, and the light-emitting element 16B emit visible light. The light-emitting element 16R, the light-emitting element 16G, and the light-emitting element 16B can emit light of different colors. The light-emitting element 16R, the light-emitting element 16G, and the light-emitting element 16B can emit red (R) light, green (G) light, and blue (B) light, respectively. Alternatively, the light-emitting element 16R, the light-emitting element 16G, and the light-emitting element 16B can emit yellow (Y), cyan (C), and magenta (M) light, for example. Furthermore, four or more light-emitting elements 16 may be provided in the pixel 13. That is, the pixel 13 may include four or more subpixels. For example, in the pixel 13, a light-emitting element that emits white light may be provided in addition to the light-emitting element 16R, the light-emitting element 16G, and the light-emitting element 16B. Note that since the light-emitting element 16R, the light-emitting element 16G, and the light-emitting element 16B emit visible light, the light-emitting element 16R, the light-emitting element 16G, and the light-emitting element 16B are each referred to as a visible light-emitting element or a visible light-emitting device.

As described above, due to the pixel 13 including a plurality of light-emitting elements 16 emitting light of different colors, a full-color image can be displayed on the display region 11. Note that the light-emitting element 16R, the light-emitting element 16G, and the light-emitting element 16B may emit light of the same color, and may emit white light, for example. In that case, color filters (also referred to as coloring layers) that transmit light of different colors are provided in the subpixel including the light-emitting element 16R, the subpixel including the light-emitting element 16G, and the subpixel including the light-emitting element 16B, whereby a full-color image can be displayed on the display region 11. Note that the pixel 13 includes light-emitting elements and can display an image when the light-emitting element emits light; thus, the pixel 13 is also referred to as a light-emitting pixel or a display pixel.

As the light-emitting element 14, the light-emitting element 16R, the light-emitting element 16G, and the light-emitting element 16B, EL elements such as OLEDs (Organic Light Emitting Diodes) or QLEDs (Quantum-dot Light Emitting Diodes) are preferably used. As a light-emitting substance contained in the EL element, a substance that emits fluorescent light (a fluorescent material), a substance that emits phosphorescent light (a phosphorescent material), an inorganic compound (e.g., a quantum dot material), a substance that exhibits thermally activated delayed fluorescence (a thermally activated delayed fluorescent (TADF) material), and the like can be given.

FIG. 1C is a plan view illustrating a structure example of the pixel 15. The pixel 15 includes a light-receiving element 17. A planar shape of the light-receiving element 17 illustrated in FIG. 1C corresponds to a planar shape of a light-receiving region of the light-receiving element 17. The light-receiving element 17 can have sensitivity to light emitted from the light-emitting element 14. For example, in the case where the light-emitting element 14 emits infrared light, the light-receiving element 17 has sensitivity to infrared light. Note that the pixel 15 includes a light-receiving element and can capture an image with the light-receiving element; thus, the pixel 15 is also referred to as a light-receiving pixel or a sensor pixel.

As the light-receiving element 17, a pn photodiode or a pin photodiode (also referred to as PD) can be used, for example. The light-receiving element 17 functions as a photoelectric conversion element (also referred to as a photoelectric conversion device) that detects light entering the light-receiving element 17 and generates electric charge. The amount of generated electric charge in the light-receiving element 17 is determined depending on the amount of incident light. The light-receiving element 17 can include an active layer containing an inorganic compound, for example. Examples of the inorganic compound include silicon, specifically amorphous silicon.

FIG. 1D and FIG. 1E are schematic views illustrating functions of the display device 10. FIG. 1D illustrates an example in which a functional layer 43, the light-emitting element 16R, the light-emitting element 16G, the light-emitting element 16B, the light-emitting element 14, and the light-receiving element 17 are provided between a substrate 41 and a substrate 42. For example, at least some components of the driver circuit 21 to the driver circuit 24 can be provided in the functional layer 43. For example, at least one of a switch, a transistor, a capacitor, a wiring, and the like can be provided in the functional layer 43.

FIG. 1D illustrates an example in which a finger 40 touches the surface of the substrate 42. FIG. 1E illustrates an example in which the finger 40 approaches the surface of the substrate 42. In the examples illustrated in FIG. 1D and FIG. 1E, the light-emitting element 14 emits light L_{IR}. The light L_{IR} can be infrared light, for example. In the case where the light L_{IR} is incident on the finger 40, at least part of the light L_{IR} is reflected by the finger 40 and enters the light-receiving element 17. Accordingly, the display device 10 can detect the contact of the finger 40 with or proximity of the finger 40 to the surface of the substrate 42. The finger 40 can be referred to as a detection target or simply an object. Note that an object is not limited to a finger, and a hand or a pen may be used as the object, for example.

The display device 10 may have a function of detecting an object by detecting external light with the use of the light-receiving element 17. For example, the illuminance of external light that irradiates a region overlapping with the object is lower than the illuminance of external light that irradiates a region not overlapping with the object. Thus, the display device 10 can detect contact of an object with or proximity of the object to the surface of the substrate 42 by detecting the illuminance of light that irradiates the light-receiving element 17, e.g., a low-visible-light-illuminance region. The display device 10 can detect contact of an object with or proximity of the object to the surface of the substrate 42 by calculating a difference between the highest illuminance and the lowest illuminance of light that irradiates the light-receiving elements 17, for example. Note that in the case where the display device 10 has a function of detecting an object by detecting external light, the light-emitting element 14 is not necessarily included.

As described above, the display device 10 can function as, for example, a touch sensor or a noncontact sensor. Note that the display device 10 can capture an image with the light-receiving element 17. Thus, the display device 10 can function as an image sensor, for example. In that case, the display device 10 can capture an image in the display region 11. Furthermore, when a finger, a palm, or the like touches the display region 11 of the display device 10, an image of the fingerprint or the palm print can be captured. In that case, the display device 10 can perform biometric authentication by using the captured image of the fingerprint or the palm print.

The display device 10 can perform image capturing using the light-receiving element 17 and thus functions as an imaging device. Accordingly, one embodiment of the present invention can be regarded as a display device having an image capturing function or an imaging device having a display function, as described above.

As illustrated in FIG. 1D and FIG. 1E, the display device 10 performs image capturing in a period in which the light-emitting element 16R, the light-emitting element 16G, and the light-emitting element 16B do not emit light, i.e., a period in which the display device 10 is in a non-light-emitting state. Specifically, the display device 10 performs light exposure on the light-receiving element 17 in a period in which the light-emitting element 16R, the light-emitting element 16G, and the light-emitting element 16B are in a non-light-emitting state. Thus, light emitted from at least one of the light-emitting element 16R, the light-emitting element 16G, and the light-emitting element 16B can be prevented from entering the light-receiving element 17 and becoming a noise in the light exposure period. The display device 10 can perform image capturing with less noise and high sensitivity. Thus, the display device 10 can detect contact of an object with or proximity of the object to the display region 11 with high sensitivity, for example. Accordingly, the display device 10 can function as, for example, a highly sensitive touch sensor or a highly sensitive noncontact sensor.

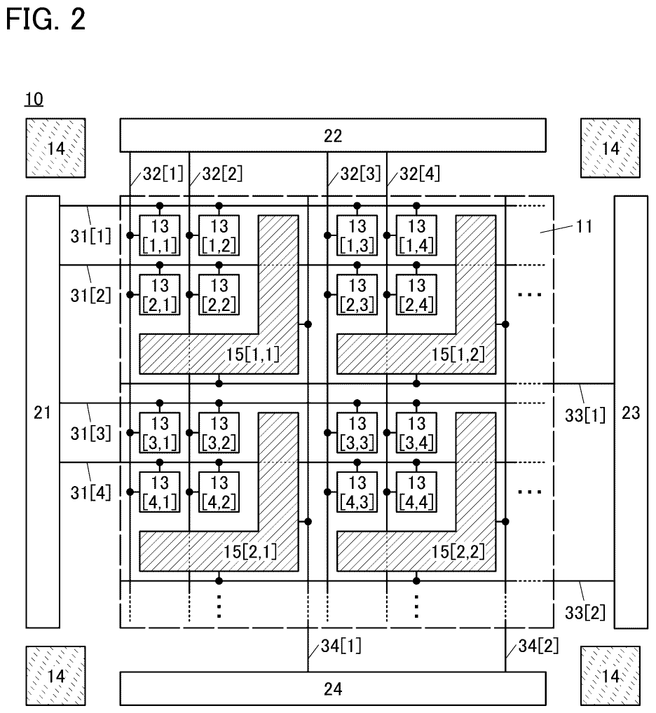

FIG. 2 is a block diagram illustrating an example in which the light-emitting element 14 illustrated in FIG. 1A is provided outside the display region 11. In the display device 10 illustrated in FIG. 2, a projector including the light-emitting element 14 is provided in the display device 10 and light emitted from the projector is detected by the pixel 15; thus, the display device 10 can detect contact or proximity of an object, for example. Although FIG. 2 illustrates an example in which the light-emitting element 14 is provided at four corners of the display device 10, one embodiment of the present invention is not limited thereto. The number of the light-emitting elements 14 provided in the display device 10 may be one, two, three, or five or larger. The light-emitting elements 14 may be provided along at least one side of the display region 11, for example. In that case, the light-emitting elements 14 can be provided outside the driver circuit 21 to the driver circuit 24.

As illustrated in FIG. 2, in the case where the light-emitting elements 14 are provided outside the display region 11, one or both of the area of the light-emitting region and the area of the light-receiving region can be larger than in the case where the light-emitting elements 14 are provided in the display region 11 in some cases. Accordingly, power consumption of the display device 10 can be reduced in some cases. Meanwhile, in the case where the light-emitting elements 14 are provided in the display region 11 as illustrated in FIG. 1A, the display device 10 may easily detect contact of an object with proximity of the object to the display region 11, for example, as compared with the case where the light-emitting elements 14 are provided outside the display region 11. Accordingly, the convenience of the display device 10 can be improved in some cases. Note that FIG. 2 illustrates an example in which the wiring 31 and the wiring 32 each include a region overlapping with the pixel 15.

### Pixel Structure Example_1

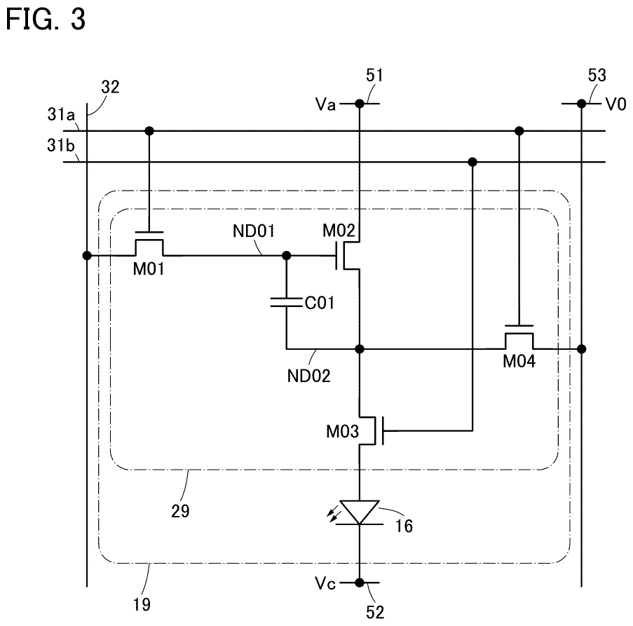

FIG. 3 is a circuit diagram illustrating a structure example of a subpixel 19 provided in the pixel 13. The subpixel 19 includes a pixel circuit 29 and a light-emitting element 16. The pixel circuit 29 includes a transistor M01, a transistor M02, a transistor M03, a transistor M04, and a capacitor C01.

In the pixel circuit 29, one of a source and a drain of the transistor M01 is electrically connected to a gate of the transistor M02. The gate of the transistor M02 is electrically connected to one electrode of the capacitor C01. One of a source and a drain of the transistor M02 is electrically connected to the other electrode of the capacitor C01. The other electrode of the capacitor C01 is electrically connected to one of a source and a drain of the transistor M03. The one of the source and the drain of the transistor M03 is electrically connected to one of a source and a drain of the transistor M04. Here, a node at which the one of the source and the drain of the transistor M01, the gate of the transistor M02, and the one electrode of the capacitor C01 are electrically connected is referred to as a node ND01. A node at which the one of the source and the drain of the transistor M02, the one of the source and the drain of the transistor M03, the one of the source and the drain of the transistor M04, and the other electrode of the capacitor C01 are electrically connected is referred to as a node ND02.

The other of the source and the drain of the transistor M01 is electrically connected to the wiring 32. A gate of the transistor M01 is electrically connected to a wiring 31a. The other of the source and the drain of the transistor M02 is electrically connected to a wiring 51. A gate of the transistor M03 is electrically connected to a wiring 31b. The other of the source and the drain of the transistor M04 is electrically connected to a wiring 53. A gate of the transistor M04 is electrically connected to the wiring 31a. Here, the wiring 31a and the wiring 31b are each a kind of the wiring 31.

One electrode of the light-emitting element 16 is electrically connected to the other of the source and the drain of the transistor M03. The other electrode of the light-emitting element 16 is electrically connected to a wiring 52. Here, the one electrode of the light-emitting element 16 is also referred to as a pixel electrode. The wiring 52 can be shared by all the subpixels 19, for example. Therefore, the other electrode of the light-emitting element 16 is also referred to as a common electrode.

A constant potential can be supplied to the wiring 51 to the wiring 53. FIG. 3 illustrates an example in which a potential Va is supplied to the wiring 51, a potential Vc is supplied to the wiring 52, and a potential V0 is supplied to the wiring 53. FIG. 3 illustrates an example in which one electrode of the light-emitting element 16 is an anode and the other electrode of the light-emitting element 16 is a cathode. In that case, the potential Va can be a high potential and the potential Vc can be a low potential. Thus, in a period in which the light-emitting element 16 emits light, a voltage with a forward bias (a voltage at which the anode potential is higher than or equal to the cathode potential) can be applied to the light-emitting element 16.

The transistor M01, the transistor M03, and the transistor M04 each have a function as a switch. The transistor M01 has a function of establishing or breaking electrical continuity between the node ND01 and the wiring 32. The transistor M03 has a function of establishing or breaking electrical continuity between the node ND02 and the one electrode of the light-emitting element 16. The transistor M04 has a function of establishing or breaking electrical continuity between the node ND02 and the wiring 53.

The transistor M02 has a function of controlling the amount of current flowing through the light-emitting element 16 and is also referred to as a driving transistor. The capacitor C01 has a function of retaining a potential of the gate of the transistor M02. The emission luminance of the light-emitting element 16 is controlled in accordance with a potential that corresponds to image data supplied to the gate of the transistor M02. Specifically, in the case where the potential Va is a high potential and the potential Vc is a low potential, the amount of current flowing from the wiring 51 to the wiring 52 is controlled in accordance with the potential of the gate of the transistor M02. Thus, the emission luminance of the light-emitting element 16 is controlled.

### Pixel Structure Example_2

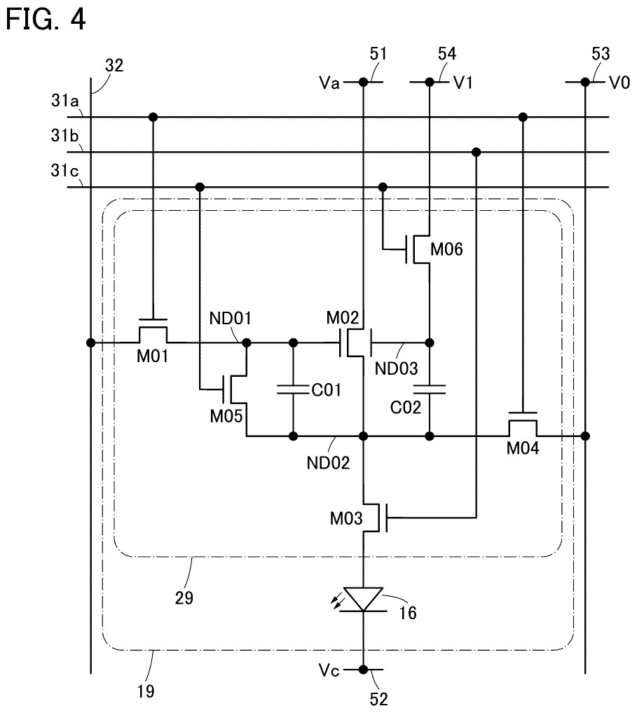

FIG. 4 is a circuit diagram illustrating an example in which the pixel circuit 29 illustrated in FIG. 3 includes a transistor M05, a transistor M06, and a capacitor C02, and the transistor M02 includes a back gate. In the pixel circuit 29 illustrated in FIG. 4, the one of the source and the drain of the transistor M01, the gate of the transistor M02, one electrode of the capacitor C01, and one of a source and a drain of the transistor M05 are electrically connected to the node ND01. One of the source and the drain of the transistor M02, the one of the source and the drain of the transistor M03, the one of the source and the drain of the transistor M04, the other electrode of the capacitor C01, the other of the source and the drain of the transistor M05, and one electrode of the capacitor C02 are electrically connected to the node ND02.

In the pixel circuit 29 illustrated in FIG. 4, a back gate of the transistor M02 is electrically connected to one of a source and a drain of the transistor M06. The one of the source and the drain of the transistor M06 is electrically connected to the other electrode of the capacitor C02. Here, a node where the back gate of the transistor M02, the one of the source and the drain of the transistor M06, and the other electrode of the capacitor C02 are electrically connected is referred to as a node ND03.

In the pixel circuit 29 illustrated in FIG. 4, a gate of the transistor M05 and a gate of the transistor M06 are electrically connected to a wiring 31c. The other of the source and the drain of the transistor M06 is electrically connected to a wiring 54. Here, the wiring 31c is a kind of the wiring 31.

A constant potential can be supplied to the wiring 54. FIG. 4 illustrates an example in which a potential V1 is supplied to the wiring 54.

The transistor M05 and the transistor M06 each have a function as a switch. The transistor M05 has a function of establishing or breaking electrical continuity between the node ND01 and the node ND02. The transistor M06 has a function of establishing or breaking electrical continuity between the node ND03 and the wiring 54. The capacitor C02 has a function of retaining a potential of the back gate of the transistor M02.

In the pixel circuit 29 illustrated in FIG. 4, a threshold voltage of the transistor M02 can be changed in accordance with a potential supplied to the back gate of the transistor M02. Thus, the threshold voltage of the transistor M02 can be corrected by a potential supplied to the back gate of the transistor M02. In the display device of one embodiment of the present invention, a plurality of subpixels 19 each including the pixel circuit 29 are provided; with the structure of the pixel circuit 29 illustrated in FIG. 4, variation in the threshold voltages of the transistors M02 between the plurality of subpixels 19 can be corrected.

In this specification and the like, a pixel circuit that can correct the threshold voltage of a driving transistor (the transistor M02 in FIG. 4) like the pixel circuit 29 illustrated in FIG. 4 is referred to as a pixel circuit incorporating internal correction circuit. When the pixel circuit is provided with an internal correction circuit, a high-quality image can be displayed on a display region.

In the pixel circuit 29 illustrated in FIG. 4, the potential V0 can be a potential at which the transistor M02 can be brought into a non-conduction state when supplied to the gate of the transistor M02, for example. The potential V1 can be higher than the potential V0, for example.

Although FIG. 3 and FIG. 4 each illustrate an example in which all the transistors provided in the pixel circuit 29 are n-channel transistors, at least some of the transistors may be p-channel transistors. For example, at least one of the transistor M01 to the transistor M06 may be a p-channel transistor.

As the transistor included in the pixel circuit 29, a transistor including a metal oxide in a semiconductor layer where a channel formation region is provided (also referred to as an OS transistor) can be used. An OS transistor features an extremely low off-state current because the band gap of the metal oxide where the channel is formed is greater than or equal to 2 eV. The off-state current value per micrometer of channel width of an OS transistor in a room-temperature environment can be lower than or equal to 1 aA (1×10⁻¹⁸ A), lower than or equal to 1 zA (1×10⁻²¹ A), or lower than or equal to 1 yA (1×10⁻²⁴ A). Note that the off-state current per micrometer of channel width of a transistor including silicon in a channel formation region (hereinafter also referred to as a Si transistor) in a room-temperature environment is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

Accordingly, for example, when OS transistors are used as the transistors serving as switches (the transistor M01 and the transistor M03 to the transistor M06) among the transistors included in the pixel circuit 29, electric charge accumulated in the capacitor C01 and the capacitor C02 can be retained for a long period. When electric charge accumulated in the capacitor C01 is retained for a long period, image data can be retained in the pixel circuit 29 for a long period. In addition, when electric charge accumulated in the capacitor C02 is retained for a long period, the potential of the back gate of the transistor M02 can be retained for a long period.

Accordingly, in the case where the display device including the pixel circuit 29 illustrated in FIG. 3 or FIG. 4 displays a still image for which rewriting every frame is not required, the display device can continue displaying the image even after the operation of a peripheral driver circuit that drives the pixel circuit 29 is stopped, for example. In this specification and the like, such a driving method in which the operation of a peripheral driver circuit is stopped during displaying a still image is also referred to as “idling stop driving”. The power consumption of the display device can be reduced by performing idling stop driving.

Furthermore, a high-quality image can be displayed on a display region even when the operation of correcting the threshold voltage of the driving transistor (the transistor M02) is not performed every frame and is performed at a frequency of once every several frames or once every several seconds, for example.

The off-state current of an OS transistor hardly increases even in a high-temperature environment. Specifically, the off-state current hardly increases even at an environment temperature higher than or equal to room temperature and lower than or equal to 200° C. Furthermore, the on-state current of an OS transistor is unlikely to decrease even in a high-temperature environment. Meanwhile, the on-state current of a Si transistor decreases in a high-temperature environment. That is, an OS transistor has a higher on-state current than a Si transistor in a high-temperature environment. In an OS transistor, the ratio between on-state current and off-state current is large even at an environmental temperature higher than or equal to 125° C. and lower than or equal to 150° C.; thus, an excellent switching operation can be performed. Accordingly, a display device including an OS transistor achieves stable operation and high reliability even in a high temperature environment. This means that the use of OS transistors as the transistors included in the pixel circuit 29 can increase the reliability of the display device using the pixel circuit 29.

Moreover, the OS transistor has high source-drain breakdown voltage (also referred to as drain breakdown voltage). Accordingly, a display device including an OS transistor achieves a stable operation and high reliability even when being driven with high voltage. That is, for example, with use of OS transistors as the transistor M02 and the transistor M03 among the transistors included in the pixel circuit 29, the operation of the pixel circuit 29 is stable even when the difference between the potential Va and the potential Vc is large. Thus, the reliability of the display device including the pixel circuit 29 can be improved.

In one embodiment of the present invention, the pixel circuit 29 is not limited to having the structure using OS transistors and may have a structure using a plurality of kinds of transistors including different semiconductor materials may be employed. For example, the pixel circuit 29 may include a Si transistor in addition to an OS transistor. As an example of a Si transistor, a transistor including low-temperature polysilicon (LTPS) in its channel formation region (an LTPS transistor) can be given. The LTPS transistor has high field-effect mobility and excellent frequency characteristics. A structure in which the LTPS transistor and the OS transistor are used in combination is referred to as LTPO in some cases.

For example, OS transistors can be used as the transistors serving as switches (the transistor M01 and the transistor M03 to the transistor M06 and an LTPS transistor can be used as the driving transistor (the transistor M02), among the transistors included in the pixel circuit 29. When the pixel circuit 29 employs LTPO (i.e., the pixel circuit 29 includes both an LTPS transistor and OS transistors), the display device using the pixel circuit 29 can achieve reduced power consumption and improved drive capability. Note that a transistor including amorphous silicon in its channel formation region may be used as the Si transistor. Alternatively, a transistor containing single crystal silicon in its channel formation region may be used, for example.

Note that in the case where the pixel circuit 29 includes a plurality of kinds of transistors including different semiconductor materials, the transistors may be provided in different layers for each kind of transistor. For example, in the case where the pixel circuit 29 includes a Si transistor and an OS transistor, a layer including the Si transistor and a layer including the OS transistor may be provided to overlap with each other. Such a structure enables the area occupied by the pixel circuit 29 to be small.

Note that as the transistor included in the pixel circuit 29, a transistor including a single-crystal semiconductor, a polycrystalline semiconductor, a microcrystalline semiconductor, or an amorphous semiconductor in a channel formation region may be used. Furthermore, as the semiconductor, for example, a compound semiconductor (e.g., silicon germanium, gallium arsenide, or the like), an oxide semiconductor, or the like as well as a single element semiconductor whose main component is a single element (e.g., silicon, germanium, or the like) can be used.

A transistor with any of a variety of structures can be used as the transistor included in the pixel circuit 29. For example, a transistor having any of a variety of structures such as a planar type, a staggered type, a FIN-type, a TRI-GATE type, a top-gate type, a bottom-gate type, and a dual-gate type (a structure in which gates are placed on the opposite sides with a channel formation region therebetween (placed above and below the channel formation region, for example)) can be used. As the transistor included in the pixel circuit 29, a vertical transistor, specifically, a transistor in which at least part of a channel formation region is provided along a side surface of an insulating layer is preferably used.

Note that in a vertical transistor, the source electrode and the drain electrode are positioned at different heights, which causes current to flow in the height direction (vertical direction) in the channel formation region of the semiconductor. In other words, the channel length direction can be regarded as having a component of the height direction (vertical direction). Thus, the vertical transistor described above can also be referred to as a VFET (Vertical Field Effect Transistor), a vertical-channel transistor, a vertical-channel-type transistor, or the like.

In a vertical transistor, the source region, the channel formation region, and the drain region can at least partly overlap with one another in the plan view, enabling a smaller occupied area (footprint). Such a transistor enables reduced channel length and increased channel width, reducing on-state resistance (increasing on-state current). Thus, with the use of a vertical transistor in the pixel circuit 29, for example, the resolution (also referred to as pixel density) of a display device using the pixel circuit 29 can be increased. Furthermore, as pixel arrangement, a PenTile arrangement can be replaced with a stripe arrangement without decreasing the resolution of the display device, for example. In addition, an internal correction circuit can be incorporated without decreasing the resolution of the display device, for example.

In one embodiment of the present invention, vertical transistors are preferably used as some or all of the transistors included in the pixel circuit 29. Vertical transistors are preferably used as the transistors serving as switches (the transistor M01 and the transistor M03 to the transistor M06), in particular.

Note that as the driving transistor (the transistor M02), a transistor having high saturation (a small change in drain current with respect to drain voltage in a saturation region of the transistor) is preferably used. For example, a transistor with a long channel length is used.

### Pixel Structure Example_3

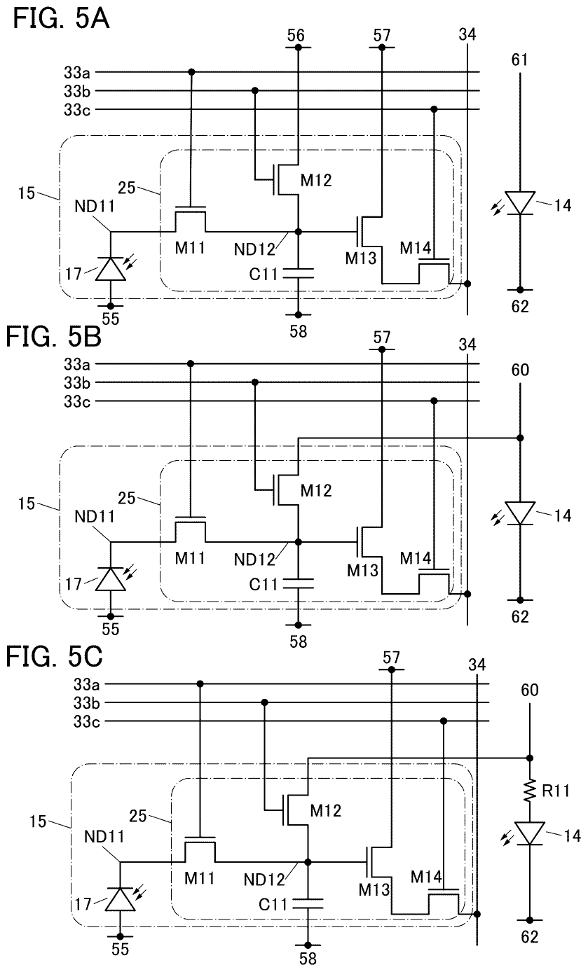

FIG. 5A is a circuit diagram illustrating a structure example of the pixel 15. FIG. 5A is a circuit diagram illustrating the light-emitting element 14. The pixel 15 includes a pixel circuit 25 and the light-receiving element 17. The pixel circuit 25 includes a transistor M11, a transistor M12, a transistor M13, a transistor M14, and a capacitor C11.

One electrode of the light-receiving element 17 is electrically connected to one of a source and a drain of the transistor M11. The other of the source and the drain of the transistor M11 is electrically connected to one of a source and a drain of the transistor M12. The one of the source and the drain of the transistor M12 is electrically connected to a gate of the transistor M13. The gate of the transistor M13 is electrically connected to one electrode of the capacitor C11. One of a source and a drain of the transistor M13 is electrically connected to one of a source and a drain of the transistor M14. Here, a node at which the one electrode of the light-receiving element 17 and the one of the source and the drain of the transistor M11 are electrically connected to each other is referred to as a node ND11. A node at which the other of the source and the drain of the transistor M11, the one of the source and the drain of the transistor M12, the gate of the transistor M13, and the one electrode of the capacitor C11 are electrically connected is referred to as a node ND12.

The other electrode of the light-receiving element 17 is electrically connected to a wiring 55. A gate of the transistor M11 is electrically connected to a wiring 33a. The other of the source and the drain of the transistor M12 is electrically connected to a wiring 56. A gate of the transistor M12 is electrically connected to a wiring 33b. The other of the source and the drain of the transistor M13 is electrically connected to a wiring 57. The other of the source and the drain of the transistor M14 is electrically connected to the wiring 34. A gate of the transistor M14 is electrically connected to a wiring 33c. The other electrode of the capacitor C11 is electrically connected to a wiring 58. Here, the wiring 33a, the wiring 33b, and the wiring 33c are each a kind of the wiring 33.

A constant potential can be supplied to the wiring 55 to the wiring 58. FIG. 5A illustrates an example in which one electrode of the light-receiving element 17 is a cathode and the other electrode of the light-receiving element 17 is an anode. In that case, a high potential can be supplied to the wiring 56 and the wiring 57, and a low potential can be supplied to the wiring 55 and the wiring 58. Thus, a reverse bias voltage (a voltage at which the anode potential is lower than the cathode potential) can be applied to the light-receiving element 17 in a period of light exposure. Note that one electrode of the light-receiving element 17 may be an anode and the other electrode of the light-receiving element 17 may be a cathode. In that case, a high potential can be supplied to the wiring 55, and a low potential can be supplied to the wiring 56.

The transistor M11, the transistor M12, and the transistor M14 each have a function of a switch. The transistor M11 has a function of establishing or breaking electrical continuity between the node ND11 and the node ND12. The transistor M12 has a function of establishing or breaking electrical continuity between the wiring 56 and the node ND12. The transistor M14 has a function of establishing or breaking electrical continuity between the one of the source and the drain of the transistor M13 and the wiring 34.

The transistor M13 has a function of controlling the potential of the wiring 34. The capacitor C11 has a function of retaining a gate potential of the transistor M13. After light exposure is performed and electric charge is accumulated in the node ND11, the electric charge is transferred to the node ND12, whereby the potential of the gate of the transistor M13 can be a potential corresponding to imaging data obtained by light exposure. When the transistor M14 is brought into a conduction state, the potential of the wiring 34 can be a potential corresponding to the potential of the gate of the transistor M13. Thus, the display device of one embodiment of the present invention can read out imaging data from the pixel 15. Accordingly, the transistor M13 can be referred to as a reading transistor.

One electrode of the light-emitting element 14 is electrically connected to a wiring 61. The other electrode of the light-emitting element 14 is electrically connected to a wiring 62. For example, a high potential is supplied to the wiring 61 and a low potential is supplied to the wiring 62, whereby a forward bias voltage can be applied to the light-emitting element 14. This enables the light-emitting element 14 to emit light.

In the structure illustrated in FIG. 5A, the pixel circuit 25 is not electrically connected to the light-emitting element 14. Thus, a potential supplied to the light-emitting element 14 can be controlled independently of the operation of the pixel circuit 25. Accordingly, the emission timing of the light-emitting element 14 can be controlled independently of the operation of the pixel circuit 25. In the structure illustrated in FIG. 5A, the light-emitting element 14 can emit light all the period in which the display device of one embodiment of the present invention is driven. Even in that case, when the light-emitting element 14 does not emit visible light, the quality of an image displayed on the display region is not lower than that in the case where the light-emitting element 14 is in a non-light-emitting state while the image is displayed on the display region.

FIG. 5B is a circuit diagram illustrating an example in which the one electrode of the light-emitting element 14 and the other of the source and the drain of the transistor M12, which are illustrated in FIG. 5A, are electrically connected to a wiring 60. A constant potential can be supplied to the wiring 60, and for example, a high potential can be supplied to the wiring 60. In the case where the potential supplied to the one electrode of the light-emitting element 14 and the potential supplied to the other of the source and the drain of the transistor M12 can be the same, the structure illustrated in FIG. 5B can be employed.

FIG. 5C is a circuit diagram illustrating an example in which a resistor R11 is provided between the one electrode of the light-emitting element 14 and the wiring 60 which are illustrated in FIG. 5B. One terminal of the resistor R11 is electrically connected to the wiring 60, and the other terminal of the resistor R11 is electrically connected to the one electrode of the light-emitting element 14. The resistor R11 functions as a current limitation resistor and can control current flowing through the light-emitting element 14. Accordingly, the amount of current flowing through the light-emitting element 14 can be reduced while the potential supplied to the other of the source and the drain of the transistor M12 can be increased, for example. Thus, the reliability of the light-emitting element 14 can be increased. The resistance value of the resistor R11 may be selected so as to be suitable for electrical characteristics of the light-emitting element 14.

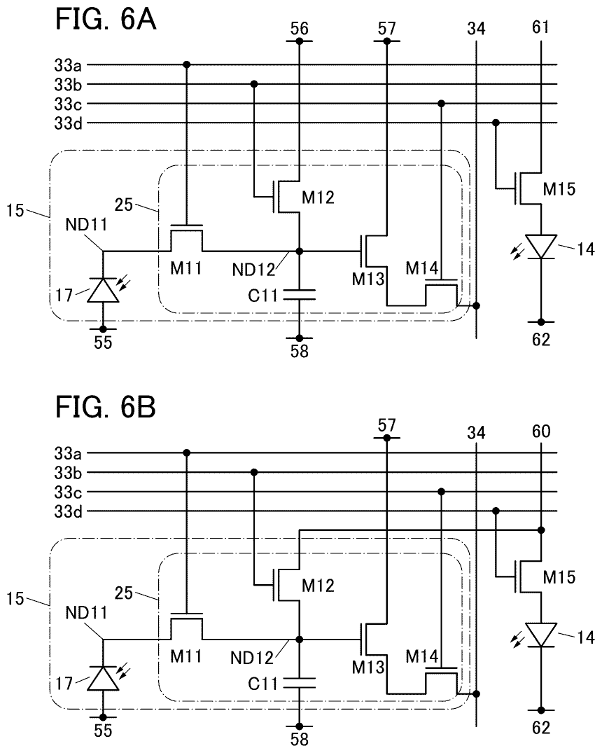

FIG. 6A is a circuit diagram illustrating an example in which a transistor M15 is provided between the one electrode of the light-emitting element 14 and the wiring 61 which are illustrated in FIG. 5A. FIG. 6B is a circuit diagram illustrating an example in which the transistor M15 is provided between the one electrode of the light-emitting element 14 and the wiring 60 which are illustrated in FIG. 5B.

In the example illustrated in FIG. 6A, one of a source and a drain of the transistor M15 is electrically connected to the wiring 61. In the example illustrated in FIG. 6B, the one of the source and the drain of the transistor M15 is electrically connected to the wiring 60. In the examples illustrated in FIG. 6A and FIG. 6B, the other of the source and the drain of the transistor M15 is electrically connected to the one electrode of the light-emitting element 14. A gate of the transistor M15 is electrically connected to a wiring 33d. The wiring 33d is a kind of the wiring 33.

In the examples illustrated in FIG. 6A and FIG. 6B, the light-emitting element 14 can be brought into a light-emitting state when the transistor M15 is brought into a conduction state, and the light-emitting element 14 can be brought into a non-light-emitting state when the transistor M15 is brought into a non-conduction state. For example, the light-emitting element 14 can be in a light-emitting state in a period in which light exposure is performed on the light-receiving element 17, and the light-emitting element 14 can be in a non-light-emitting state in a period in which the light exposure is not performed. Thus, the power consumption of the display device can be reduced as compared with the case where the light-emitting element 14 is made to emit light all the period in which the display device of one embodiment of the present invention is driven, for example. By contrast, with the structure in which the transistor M15 is not provided in the display device of one embodiment of the present invention as illustrated in FIG. 5A and FIG. 5B, for example, the area of a light-emitting region of the display device and the area of a light-receiving region can be increased.

As the transistor M11 to the transistor M15, a transistor having a structure similar to the above-described structure that can be used as the transistor included in the pixel circuit 29 can be used. In particular, as each of the transistor M11 to the transistor M15, vertical transistors are preferably used, for example.

As described above, the vertical transistor has a structure in which the channel length can be reduced and the channel width can be increased, so that the on-state current can be increased. Thus, with the use of vertical transistors as the transistor M11 to the transistor M15, the pixel circuit 25 can be driven at high speed, for example. As described above, in the display device of one embodiment of the present invention, light exposure is performed on the light-receiving element 17 in a period in which the light-emitting element 16 that emits visible light is in a non-light-emitting state. Accordingly, the use of the vertical transistors as the transistor M11 to the transistor M15 enables the pixel circuit 25 to be driven normally even when the period in which the light-emitting element 16 is in a non-light-emitting state is short. For example, even when the period in which the light-emitting element 16 is in a non-light-emitting state is short, a period in which light exposure is performed on the light-receiving element 17 can be ensured.

The semiconductor layers of the transistor M11 to the transistor M15 can be formed using a material similar to the material that can be used for the semiconductor layer of the transistor included in the pixel circuit 29. For example, OS transistors can be used as the transistor M11 to the transistor M15. For another example, Si transistors such as LTPS transistors may be used as the transistor M11 to the transistor M15.

### Example_1 of Method for Driving Display Device

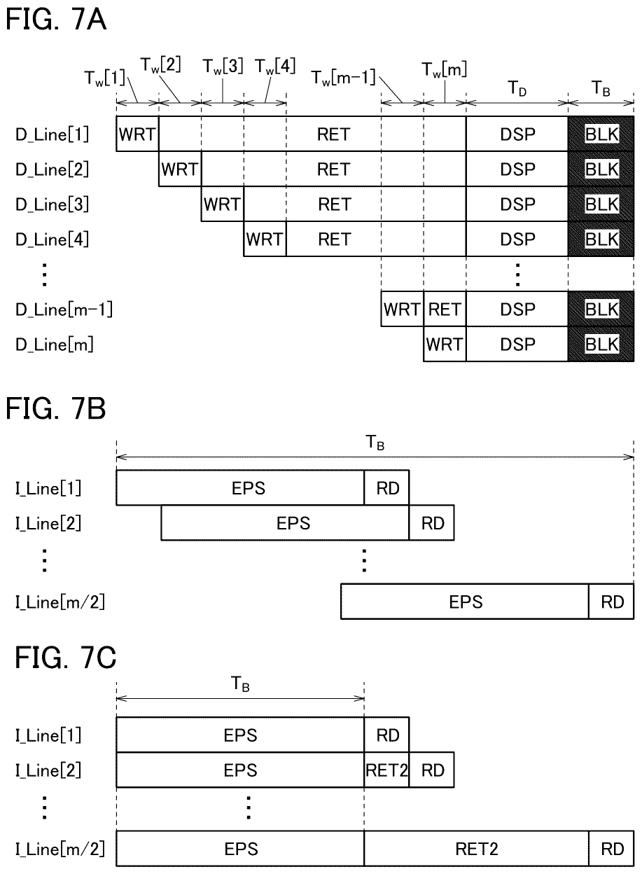

FIG. 7A and FIG. 7B are schematic views illustrating an example of a method for driving the display device 10 illustrated in FIG. 1A or FIG. 2. FIG. 7A illustrates an example of a method for driving the pixel 13, and FIG. 7B illustrates an example of a method for driving the pixel 15. FIG. 7A and FIG. 7B illustrate an example of a method for driving the display device 10 including m rows of the pixels 13 (m is an integer greater than or equal to 2. In the example in FIG. 7A and FIG. 7B, m is an integer greater than or equal to 6.) and m/2 rows of the pixels 15. In FIG. 7A, the pixels 13 in the first row, the second row, the third row, the fourth row, the (m−1)-th row, and the m-th row are denoted by D_Line[1], D_Line[2], D_Line[3], D_Line[4], D_Line[m−1], and D_Line[m], respectively. In FIG. 7B, the pixels 15 in the first row, the second row, and the (m/2)-th row are denoted by I_Line[1], I_Line[2], and I_Line[m/2], respectively. In the example illustrated in FIG. 1A and FIG. 2, for example, the pixel 13[1,1] to a pixel 13[1,4] are included in the D_Line[1], a pixel 13[2,1] to a pixel 13[2,4] are included in the D_Line[2], a pixel 13[3,1] to a pixel 13[3,4] are included in the D_Line[3], and a pixel 13[4,1] to the pixel 13[4,4] are included in the D_Line[4]. For example, the pixel 15[1,1] and a pixel 15[1,2] are included in the I_Line[1], and a pixel 15[2,1] and the pixel 15[2,2] are included in the I_Line[2]. The same applies to schematic views each illustrating an example of a method for driving a display device described below.

First, in a period T_{w}[1], image data is written to the pixels 13 in the first row (operation WRT). The image data is called first image data. The written first image data is retained in the pixels 13 (operation RET).

Subsequently, in a period T_{w}[2], image data is written to the pixels 13 in the second row (the operation WRT). The image data is called second image data. The written second image data is retained in the pixels 13 (the operation RET).

Similarly, third image data is written to the pixels 13 in the third row in a period T_{w}[3], and the third image data is written to the pixels 13 in the fourth row in a period T_{w}[4]. In this manner, image data is written sequentially the pixels 13 in the fifth and subsequent rows.

In a period T_{w}[m−1], (m−1)-th image data is written to the pixels 13 in the (m−1)-th row. After that, in a period T_{w}[m], m-th image data is written to the pixels 13 in the m-th row.

In the above manner, image data is written to all the pixels 13. Note that FIG. 7A illustrates an example in which a period in which the m-th image data is retained (a period in which the operation RET is performed) is not included in the method for driving the pixel 13.

In a period T_{w}[i] (i is an integer greater than or equal to 1 and less than or equal to m), the transistors M01 included in the pixels 13 in the i-th row are brought into a conduction state and the transistors M01 included in the pixels 13 in the rows other than the i-th row are brought into a non-conduction state. For example, in the period T_{w}[1], the transistors M01 included in the pixels 13 in the first row are brought into a conduction state and the transistors M01 included in the pixels 13 in the second to m-th rows are brought into a non-conduction state. In the period T_{w}[2], the transistors M01 included in the pixels 13 in the second row are brought into a conduction state, and the transistors M01 included in the pixels 13 in the first row and the third to m-th rows are brought into a non-conduction state. In the period T_{w}[3], the transistors M01 included in the pixels 13 in the third row are brought into a conduction state, and the transistors M01 included in the pixels 13 in the first row, the second row, and the fourth to m-th rows are brought into a non-conduction state. Furthermore, in the period T_{w}[4], the transistors M01 included in the pixels 13 in the fourth row are brought into a conduction state, and the transistors M01 included in the pixels 13 in the first to third rows and the fifth to m-th rows are brought into a non-conduction state.

Next, in a period TD, an image represented by the first to m-th image data is displayed on the display region 11 (operation DSP). Specifically, when the light-emitting element 16 included in the pixel 13 is brought into a light-emitting state, an image is displayed on the display region 11. In the period T_{D}, the light-emitting elements 16 included in the pixels 13 in the first to m-th rows emit light with luminance represented by the first to m-th image data, respectively, whereby an image is displayed on the display region 11.

Next, in a period T_{B}, image display on the display region 11 is stopped. In other words, black display is performed (operation BLK). Specifically, black display is performed by bringing the light-emitting element 16 included in the pixel 13 into a non-light-emitting state.

Thus, in the method for driving the display device of one embodiment of the present invention, black display is performed after an image is displayed. That is, in the method for driving the display device of one embodiment of the present invention, black insertion driving is performed. This can improve the sense of afterimage, blurring of an image, and the like in displaying a moving image, for example. Accordingly, a high-quality image can be displayed particularly when a moving image is displayed on the display region.

In the driving method of the display device of one embodiment of the present invention, light exposure is performed on the light-receiving element 17 included in the pixel 15 in the period T_{B} in which black display is performed (operation EPS). This can prevent light emitted from the light-emitting element 16 from entering the light-receiving element 17 and becoming a noise during the light exposure. The display device 10 can perform image capturing with less noise and high sensitivity. Thus, the display device 10 can detect contact of an object with or proximity of the object to the display region 11 with high sensitivity, for example. Accordingly, the display device 10 can function as, for example, a highly sensitive touch sensor or a highly sensitive noncontact sensor.

In the period T_{B}, the light-emitting element 14 is in a light-emitting state, and light emitted from the light-emitting element 14 is detected by the light-receiving element 17. For example, infrared light emitted from the light-emitting element 14 is incident on and reflected by an object, and enters the light-receiving element 17, whereby the display device 10 can detect the contact of the object with or proximity of the object to the display region 11. Note that in the period T_{w}[1] to the period T_{w}[m] and the period T_{D}, the light-emitting element 14 may be in a light-emitting state or a non-light-emitting state.

FIG. 7B illustrates an example of a driving method with a rolling shutter mode, in which obtaining imaging data by light exposure (the operation EPS) and reading imaging data (operation RD) are sequentially performed on the pixels 15 in the first to (m/2)-th rows. Although FIG. 7B illustrates an example in which not only the operation EPS but also the operation RD are performed in the period T_{B}, the operation RD is not necessarily performed in the period T_{B}.

The pixel 15 is preferably driven at high speed. This can ensure a period for performing light exposure on the light-receiving element 17 included in the pixel 15 even when the period T_{B} is short. When a vertical transistor is used as the transistor included in the pixel 15 as described above, the pixel 15 can be driven at high speed. For this reason, a vertical transistor is preferably used as the transistor included in the pixel 15. By reducing the number of rows of the pixels 15, a period for performing light exposure on the pixels 15 in each row can be ensured even when the period T_{B} is short.

Note that in the period T_{w}[1] to the period T_{w}[m], the light-emitting element 16 can be in a non-light-emitting state. However, in the period T_{w}[1] to the period T_{w}[m], the potential of the wiring 32, which can serve as a signal line, changes and thus a noise might be generated in the imaging data. Thus, light exposure is not performed on the light-receiving element 17 in the period T_{w}[1] to the period T_{w}[m], and light exposure is performed in the period T_{B} in which the potential of the wiring 32 does not change, whereby noise included in imaging data can be reduced. The display device 10 can perform image capturing with high sensitivity. Thus, the display device 10 can detect contact of an object with or proximity of the object to the display region 11 with high sensitivity, for example. Accordingly, the display device 10 can function as, for example, a highly sensitive touch sensor or a highly sensitive noncontact sensor.

FIG. 7C is a schematic view illustrating an example in which image capturing is performed in a global shutter mode in the period T_{B} shown in FIG. 7B. In the example illustrated in FIG. 7C, imaging data is obtained by performing light exposure (the operation EPS) on the light-receiving elements 17 included in the pixels 15 in the first to (m/2)-th rows at the same time, and then the imaging data is read out row by row (the operation RD). The imaging data is retained in the pixels 15 until the imaging data is read out (operation RET2). That is, the operation RET2 is performed after the operation EPS is performed and before the operation RD is performed. Note that FIG. 7C illustrates an example in which the pixels 15 in the first row do not perform the operation RET2. Although FIG. 7C illustrates an example in which the operation RD is not performed in the period T_{B}, the operation RD may be performed in the period T_{B}.

In the global shutter mode, an image without distortion can be obtained even when an image of a moving object is captured. On the other hand, in the global shutter mode, imaging data needs to be retained for a longer period than in the rolling shutter mode. Thus, when a transistor with a low off-state current is used as the transistor included in the pixel 15, imaging data can be retained in the pixel 15 for a long time. As described above, an OS transistor has a feature of an extremely low off-state current. Accordingly, it is preferable to use an OS transistor as the transistor included in the pixel 15 particularly in the case where the display device 10 is driven by the method illustrated in FIG. 7C.

### Example_2 of Method for Driving Display Device

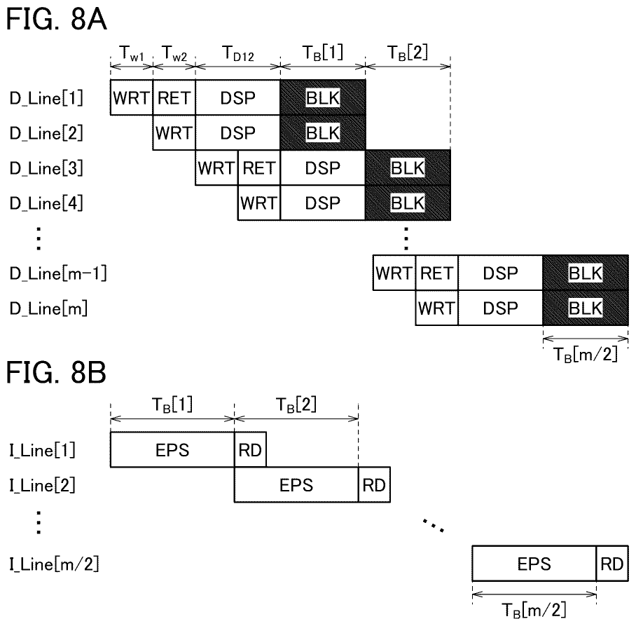

FIG. 8A and FIG. 8B are schematic views illustrating an example of a method for driving the display device 10 illustrated in FIG. 1A or FIG. 2. FIG. 8A illustrates an example of a method for driving the pixel 13, and FIG. 8B illustrates an example of a method for driving the pixel 15.

In the driving method illustrated in FIG. 8A and FIG. 8B, first, image data is written to the pixels 13 in the first row in a period T_{w1} (operation WRT). The image data is called first image data.

Subsequently, in a period T_{w2}, image data is written to the pixels 13 in the second row (the operation WRT). The image data is called second image data. In the period T_{w2}, the first image data is retained in the pixels 13 in the first row (the operation RET).

Next, in the period T_{D12}, an image represented by the first image data and the second image data is displayed on the display region 11 (the operation DSP). Specifically, the light-emitting elements 16 included in the pixels 13 in the first row and the second row are brought into a light-emitting state. In the period T_{D12}, the light-emitting elements 16 provided in the pixels 13 in the first row emit light with luminance represented by the first image data. The light-emitting elements 16 provided in the pixels 13 in the second row emit light with luminance represented by the second image data.

In the period T_{D12}, the third image data is written to the pixels 13 in the third row and the fourth image data is written to the pixels 13 in the fourth row sequentially. In a period in which the fourth image data is written to the pixels 13 in the fourth row, the third image data is retained in the pixels 13 in the third row.

Next, in the period T_{B}[1], the light-emitting elements 16 included in the pixels 13 in the first row and the second row are brought into a non-light-emitting state (the operation BLK). Thus, display of the image represented by the first image data and the second image data on the display region 11 is stopped.

In the period T_{B}[1], an image represented by the third image data and the fourth image data is displayed on the display region 11 (the operation DSP). Specifically, the light-emitting elements 16 included in the pixels 13 in the third row and the fourth row are brought into a light-emitting state. In the period T_{B}[1], the light-emitting elements 16 provided in the pixels 13 in the third row emit light with luminance represented by the third image data. The light-emitting elements 16 provided in the pixels 13 in the fourth row emit light with luminance represented by the fourth image data.

Furthermore, in the period T_{B}[1], light exposure is performed on the light-receiving elements 17 included in the pixels 15 in the first row (the operation EPS). In the period T_{B}[1], at least the light-emitting elements 14 in the first row are brought into a light-emitting state, and light emitted from the light-emitting element 14 is detected by the light-receiving element 17. After that, imaging data obtained by the light exposure is read (the operation RD). The imaging data is called first imaging data. Note that although FIG. 8B illustrates an example in which the pixels 15 in the first row perform the operation RD after the period T_{B}[1], the operation RD may be performed during the period T_{B}[1].

Although not illustrated in FIG. 8A, in the period T_{B}[1], fifth image data is written to the pixels 13 in the fifth row and sixth image data is written to the pixels 13 in the sixth row sequentially. In a period in which the sixth image data is sequentially written to the pixels 13 in the sixth row, the fifth image data is retained in the pixels 13 in the fifth row.

Next, in the period T_{B}[2], the light-emitting elements 16 included in the pixels 13 in the third row and the fourth row are brought into a non-light-emitting state (the operation BLK). Thus, display of the image represented by the third image data and the fourth image data on the display region 11 is stopped.

Furthermore, in the period T_{B}[2], light exposure is performed on the light-receiving elements 17 included in the pixels 15 in the second row (the operation EPS). In the period T_{B}[2], at least the light-emitting elements 14 in the second row are brought into a light-emitting state, and light emitted from the light-emitting element 14 is detected by the light-receiving element 17. After that, imaging data obtained by the light exposure is read (the operation RD). The imaging data is called second imaging data. Note that although FIG. 8B illustrates an example in which the pixels 15 in the second row perform the operation RD after the period T_{B}[2], the operation RD may be performed during the period T_{B}[2].

Although not illustrated in FIG. 8A, in the period T_{B}[2], an image represented by the fifth image data and the sixth image data is displayed on the display region 11. In the period T_{B}[2], seventh image data is written to the pixels 13 in the seventh row and eighth image data is written to the pixels 13 in the eighth row sequent sequentially.

As described above, the operation WRT, the operation DSP, and the operation BLK are sequentially performed on the pixels 13 in the first to m-th rows. In addition, the operation EPS and the operation RD are sequentially performed on the pixels 15 in the first to (m/2)-th rows. Note that in FIG. 8A, a period (the operation BLK) in which the light-emitting elements 16 included in the pixels 13 in the (m−1)-th row and the m-th row are brought into a non-light-emitting state corresponds to the period T_{B}[m/2]. As illustrated in FIG. 8B, in the period T_{B}[m/2], light exposure is performed on the light-receiving elements 17 included in the pixels 15 in the (m/2)-th row (the operation EPS). After that, imaging data obtained by the light exposure is read (the operation RD). Note that although FIG. 8B illustrates an example in which the pixels 15 in the (m/2)-th row perform the operation RD after the period T_{B}[m/2], the operation RD may be performed during the period T_{B}[m/2].

In the driving method illustrated in FIG. 8A and FIG. 8B, a period for retaining image data in the pixel 13 can be shorter than that in the driving method illustrated in FIG. 7A to FIG. 7C. This can inhibit the quality of an image displayed on the display region 11 from being lowered by leakage of electric charge accumulated in the capacitor C01 illustrated in FIG. 3 or FIG. 4, for example. Meanwhile, in the driving method illustrated in FIG. 7A to FIG. 7C, all the light-emitting elements 16 can emit light at the same time, for example.

### Example_3 of Method for Driving Display Device

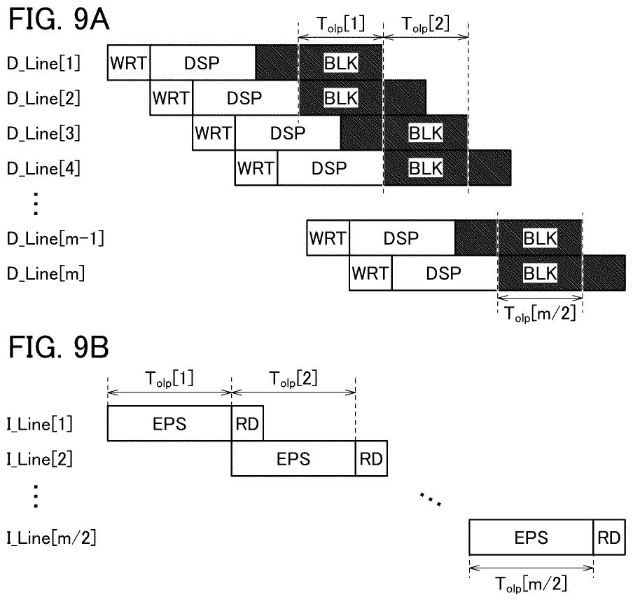

FIG. 9A and FIG. 9B are schematic views illustrating an example of a method for driving the display device 10 illustrated in FIG. 1A or FIG. 2. FIG. 9A illustrates an example of a method for driving the pixel 13, and FIG. 9B illustrates an example of a method for driving the pixel 15.

In the driving method illustrated in FIG. 9A and FIG. 9B, writing (the operation WRT) of the first to m-th image data, light emission (the operation DSP) of the light-emitting element 16, and black display (the operation BLK) are sequentially performed on the pixels 13 in the first to m-th rows. For example, after the first image data is written to the pixels 13 in the first row, the second image data is written to the pixels 13 in the second row. The second image data is written in a period in which the pixels 13 in the first row perform the operation DSP, for example. The third image data is written in a period in which the pixels 13 in the second row perform the operation DSP, for example. The fourth image data is written in a period in which the pixels 13 in the third row perform the operation DSP, for example. Furthermore, m-th image data is written in a period in which the pixels 13 in the (m−1)-th row perform the operation DSP, for example.

In FIG. 9A, a period in which the pixels 13 in the first row perform the operation BLK and a period in which the pixels 13 in the second row perform the operation BLK partly overlap with each other. The overlapping period is referred to as a period Tₒₗₚ[1]. A period in which the pixels 13 in the third row perform the operation BLK and a period in which the pixels 13 in the fourth row perform the operation BLK partly overlap with each other, and the overlapping period is referred to as a period Tₒₗₚ[2]. Furthermore, a period in which the pixels 13 in the (m−1)-th row perform the operation BLK and a period in which the pixels 13 in the m-th row perform the operation BLK partly overlap with each other, and the overlapping period is referred to as a period Tₒₗₚ[m/2]. Note that the period Tₒₗₚ[1] to the period Tₒₗₚ[m/2] are collectively referred to as a period Tₒₗₚ. The period Tₒₗₚ is also referred to as an overlap period. For example, in the period Tₒₗₚ[1], both the pixels 13 in the first row and the pixels 13 in the second row perform the operation BLK. In the period Tₒₗₚ[2], both the pixels 13 in the third row and the pixels 13 in the fourth row perform the operation BLK. Furthermore, in the period Tₒₗₚ[m/2], both the pixels 13 in the (m−1)-th row and the pixels 13 in the m-th row perform the operation BLK.

In the driving method illustrated in FIG. 9B, light exposure is performed on the light-receiving element 17 in the period Tₒₗₚ (the operation EPS). Specifically, in the period Tₒₗₚ[1], the pixels 15 in the first row perform the operation EPS. In addition, the pixels 15 in the second row perform the operation EPS in the period Tₒₗₚ[2]. Furthermore, in the period Tₒₗₚ[m/2], the pixels 15 in the (m/2)-th row perform the operation EPS. The pixels 15 in the first to m-th rows perform the operation EPS to obtain imaging data, and then read out the imaging data (the operation RD). Note that although FIG. 9B illustrates an example in which the pixels 15 in the first row perform the operation RD after the period Tₒₗₚ[1], the operation RD may be performed during the period Tₒₗₚ[1]. For example, the pixels 15 in the second row may perform the operation RD in the period Tₒₗₚ[2], and the pixels 15 in the (m/2)-th row may perform the operation RD in the period Tₒₗₚ[m/2].

In the driving method illustrated in FIG. 9A, all the pixels 13 do not need to perform the operation RET (retention of image data). Meanwhile, in the driving method illustrated in FIG. 7A and FIG. 8A, a period in which the pixels 15 in each row perform the operation EPS (also referred to as a light exposure period) can be longer than that in the driving method illustrated in FIG. 9A in some cases.

Although FIG. 7A to FIG. 9B illustrate an example of a method for driving the display device 10 in the case where the pixels in m/2 rows are provided in the display region 11, the number of rows of the pixels 15 is not limited to m/2. For example, even in the case where the pixels 15 in m/3 rows are provided in the display region 11, FIG. 7A to FIG. 9B can be referred to as the method for driving the display device 10. For example, in the case where the display device 10 is driven by the method illustrated in FIG. 8A to FIG. 9B, the pixels 15 in the first row perform the operation EPS in a period in which the pixels 13 in the first to third rows perform the operation BLK. Next, in a period in which the pixels 13 in the fourth to sixth rows perform the operation BLK, the pixels 15 in the second row perform the operation EPS. As described above, the pixels 15 in the first to m/3 rows sequentially perform the operation EPS. Note that even in the case where the pixels 15 in m/4 rows or rows smaller than or equal to m/4 are provided in the display region 11, for example, the display device 10 can be driven in a similar manner.

### Example_1 of Pixel Driving Method

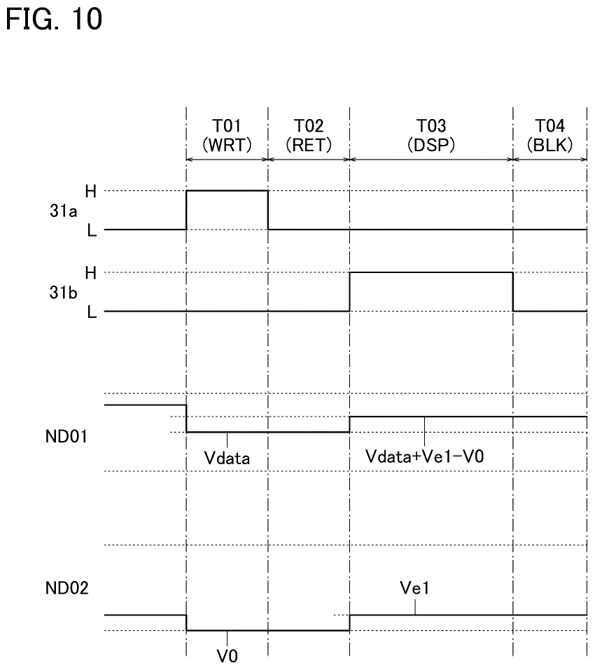

FIG. 10 is a timing chart showing an example of a method for driving the subpixel 19 illustrated in FIG. 3. FIG. 10 shows changes in the potentials of the wiring 31a, the wiring 31b, the node ND01, and the node ND02 over time which are divided into a period T01 to a period T04.

In this specification, drawings, and the like, loads on wiring and the like (parasitic capacitance and parasitic resistance), for example, sometimes generate a rise time and a fall time at the time of potential change. Each of the times takes, for example, less than 1000 ns, less than 100 ns, less than 10 ns, or less than 1 ns.

In FIG. 10, “H” means a high potential and “L” means a low potential. The high potential is a potential that brings an n-channel transistor into a conduction state when being input to a gate of the n-channel transistor. The low potential is a potential that brings an n-channel transistor into a non-conduction state when being input to a gate of the n-channel transistor. The same applies to other timing charts shown below.

An example of a method for driving the subpixel 19 is described below assuming that the transistor M01 to the transistor M04 are all n-channel transistors; however, the following description can be applied to the case where at least one of the transistor M01 to the transistor M04 is a p-channel transistor, by inverting the potential levels as appropriate, for example.

In the example shown in FIG. 10, the potentials of the wiring 31a and the wiring 31b are set to low potentials just before the period T01. Thus, in the example shown in FIG. 10, the transistor M01, the transistor M03, and the transistor M04 are in a non-conduction state just before the period T01.

In the period T01, the potential of the wiring 31a is set to a high potential. Thus, the transistor M01 and the transistor M04 are brought into a conduction state.

When the transistor M01 is brought into a conduction state, the potential of the node ND01 becomes a potential corresponding to the potential of the wiring 32 functioning as a signal line. When the transistor M04 is brought into a conduction state, the potential of the node ND02 becomes a potential corresponding to the potential of the wiring 53. Specifically, the potential of the node ND01 becomes a potential Vdata corresponding to the image data. The potential of the node ND02 becomes the potential V0 that is the potential of the wiring 53. Here, the potential V0 can be lower than the potential Vdata.

In the period T01, image data is written to the subpixel 19. The period T01 is a period in which the operation WRT shown in FIG. 7A, FIG. 8A, and FIG. 9A is performed.

In the period T02, the potential of the wiring 31a is set to a low potential. Thus, the transistor M01 and the transistor M04 are brought into a non-conduction state. When the transistor M01 is brought into a non-conduction state, electric charge in the node ND01 is retained. Thus, image data is retained in the subpixel 19. Note that when the transistor M04 is brought into a non-conduction state, electric charge in the node ND02 is retained. Thus, the potential of the node ND02 is retained.

The period T02 is a period in which the operation RET shown in FIG. 7A and FIG. 8A is performed. Note that the operation shown in the period T02 may be performed even in the case where the display device of one embodiment of the present invention is driven by the method shown in FIG. 9A.

In the period T03, the potential of the wiring 31b is set to a high potential. Thus, the transistor M03 is brought into a conduction state. Thus, a current with a magnitude corresponding to the potential of the node ND01 flows through the light-emitting element 16. The current flows from the wiring 51 toward the wiring 52. Accordingly, the voltage drop in the light-emitting element 16 changes the potential of the node ND2 to Ve1. Here, the node ND01 is in a floating state, and the node ND01 and the node ND02 are capacitively coupled through the capacitor C01. Thus, the potential of the node ND1 changes in accordance with the potential change of the node ND2. For example, when the capacitive coupling coefficient of the node ND02 is 1, the potential of the node ND01 becomes “Vdata+Ve1−V0”.

In the period T03, the light-emitting element 16 is brought into a light-emitting state to display an image. The period T03 is a period in which the operation DSP shown in FIG. 7A, FIG. 8A, and FIG. 9A is performed.

In the period T04, the potential of the wiring 31b is set to a low potential. Accordingly, the transistor M03 is brought into a non-conduction state. Thus, a current does not flow through the light-emitting element 16, and the light-emitting element 16 is brought into a non-light-emitting state.

In the period T04, the light-emitting element 16 is brought into a non-light-emitting state to perform black display. The period T04 is a period in which the operation BLK shown in FIG. 7A, FIG. 8A, and FIG. 9A is performed.

The above is the example of the method for driving the subpixel 19 shown in FIG. 3.

### Example_2 of Pixel Driving Method

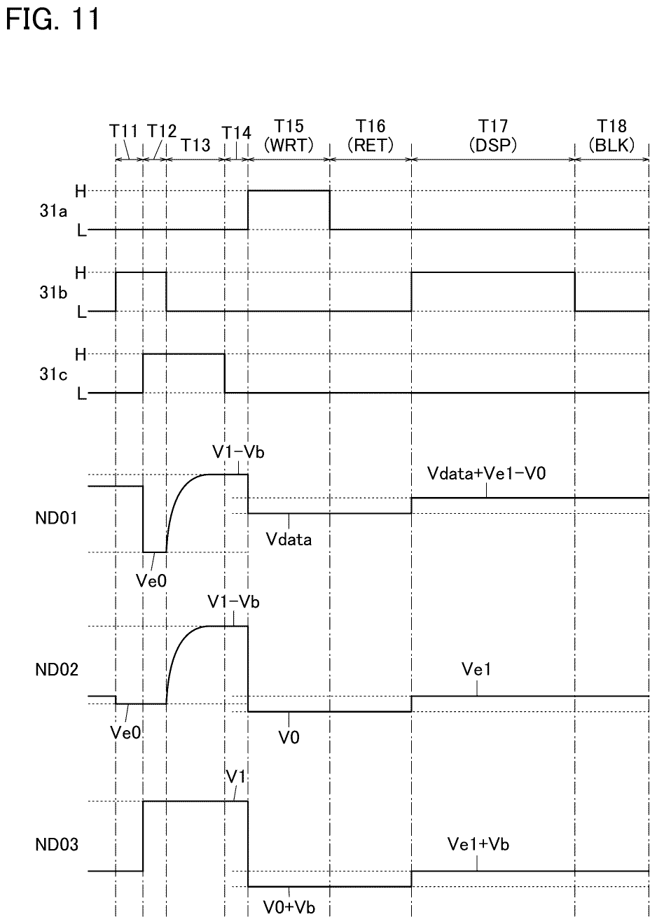

FIG. 11 is a timing chart showing an example of a method for driving the subpixel 19 illustrated in FIG. 4. FIG. 11 shows changes in the potentials of the wiring 31a, the wiring 31b, the wiring 31c, the node ND01, the node ND02, and the node ND03 over time which are divided into a period T11 to a period T18.

An example of a method for driving the subpixel 19 is described below assuming that the transistor M01 to the transistor M06 are all n-channel transistors; however, the following description can be applied to the case where at least one of the transistor M01 to the transistor M06 is a p-channel transistor, by inverting the potential levels as appropriate, for example.

In the example shown in FIG. 11, the potentials of the wiring 31a, the wiring 31b, and the wiring 31c are set to low potentials just before the period T11. Thus, in the example shown in FIG. 11, the transistor M01 and the transistor M03 to the transistor M06 are in a non-conduction state just before the period T11.

In the period T11, the potential of the wiring 31b is set to a high potential. Thus, the transistor M03 is brought into a conduction state. When the transistor M03 is brought into a conduction state, the potential of the node ND02 becomes a potential Ve0. Here, the potential Ve0 is higher than the potential Vc of the wiring 52 by a voltage drop in the light-emitting element 16. The period T11 can be regarded as a period (initialization period) in which the operation of initializing the potential of the node ND02 to the potential Ve0 is performed.

In the period T12, the potential of the wiring 31c is set to a high potential. Thus, the transistor M05 and the transistor M06 are brought into a conduction state. When the transistor M05 is brought into a conduction state, the node ND01 and the node ND02 are electrically connected. Thus, the potential of the node ND01 becomes the potential Ve0. In addition, the transistor M06 is brought into a conduction state, whereby the potential of the node ND03 becomes the potential V1 that is the potential of the wiring 54. When a back-gate voltage of the transistor M02 becomes “V1−Ve0”, the transistor M02 is brought into a normally-on state.

Note that in this specification and the like, a potential difference (voltage) between a gate of a transistor and a source of the transistor is referred to as “gate voltage” in some cases. This leads to the equation: “the gate voltage of a transistor”=“the gate potential of the transistor−“the source potential of the transistor”. In addition, a potential difference (voltage) between a back gate of a transistor and a source of the transistor is referred to as “back-gate voltage” in some cases. This leads to the equation: “the back-gate voltage of a transistor”=“the back gate potential of the transistor”−“the source potential of the transistor”. For example, in the example illustrated in FIG. 4, the difference between the potential of the node ND01 and the potential of the node ND02 can be the gate voltage of the transistor M02. The difference between the potential of the node ND03 and the potential of the node ND02 can be the back-gate voltage of the transistor M02.

In this specification and the like, “normally-on” means that a current flows between a source and a drain of a transistor when the gate-source voltage is 0 V.

In the period T13, the potential of the wiring 31b is set to a low potential. Thus, the transistor M03 is brought into a non-conduction state.

Immediately after the transistor M03 is brought into a non-conduction state, the transistor M02 is in a normally-on state because the back-gate voltage of the transistor M02 is “V1−Ve0”. Accordingly, electric charge is supplied from the wiring 51 to the node ND02 through the transistor M02. This increases the potential of the node ND2 over time. Since the transistor M05 is in an on state, the potential of the node ND01 also increases similarly. Here, as the potential of the node ND02 gradually increases, the back-gate voltage of the transistor M02 gradually decreases. In other words, the threshold voltage of the transistor M02 gradually increases (i.e., shifts in the positive direction). Then, when the threshold voltage of the transistor M02 is as close to 0 V as possible, the transistor M02 is brought into a non-conduction state to stop the increase in the potential of the node ND02. At this time, the back-gate voltage at which the threshold voltage of the transistor M02 becomes 0 V is referred to as correction voltage Vb. Here, in the period T13, the potential of the node ND03 is “V1”. Accordingly, when the increase in the potential of the node ND02 stops, the potential of the node ND02 becomes “V1−Vb”. The potential of the node ND01 also becomes “V1−Vb”.

In the period T14, the potential of the wiring 31c is set to a low potential. Thus, the transistor M05 and the transistor M06 are brought into a non-conduction state. When the transistor M05 is brought into a non-conduction state, the node ND01 is brought into a floating state and the potential of the node ND01 is retained. When the transistor M06 brought into a non-conduction state, the node ND03 is brought into a floating state and the potential of the node ND03 is retained. Accordingly, the back-gate voltage of the transistor M02 is maintained at the correction voltage Vb obtained in the period T13.

Through the operations in the period T12 to the period T14, correction is performed such that the threshold voltage of the transistor M2 becomes 0 V and the state subjected to correction can be maintained. Thus, the period T12 and the period T14 can be referred to as threshold voltage correction periods. Note that in this specification and the like, a method for correcting the threshold voltage of the transistor M02 by performing the operation in the period T12 to the period T14 is referred to as “internal correction” in some cases.

Note that the threshold voltage of the transistor M02 after the correction is not necessarily 0 V. In that case, by replacing 0 V with a desired threshold voltage as appropriate, the description of FIG. 11 can be applied.

In the period T15 to the period T18, operations similar to those in the period T01 to the period T04 shown in FIG. 10 can be performed. Here, in the period T15 to the period T18, the potential of the wiring 31c is set to a low potential. Thus, in the period T15 to the period T18, the transistor M05 and the transistor M06 are brought into a non-conduction state.

Here, in the period T15 to the period T18, the node ND03 is in a floating state, and the node ND02 and the node ND03 are capacitively coupled through the capacitor C02. Thus, the potential of the node ND03 changes in accordance with the potential change of the node ND02. For example, when the capacitive coupling coefficient of the node ND02 is 1, the potential of the node ND03 becomes “V0+Vb” in the period T15 and the period T16 and the potential of the node ND03 becomes “Ve1+Vb” in the period T17 and the period T18.

The period T15 is a period in which the operation WRT shown in FIG. 7A, FIG. 8A, and FIG. 9A is performed. The period T16 is a period in which the operation RET shown in FIG. 7A and FIG. 8A is performed. The period T17 is a period in which the operation DSP shown in FIG. 7A, FIG. 8A, and FIG. 9A is performed. The period T18 is a period in which the operation BLK shown in FIG. 7A, FIG. 8A, and FIG. 9A is performed. The above is the example of the method for driving the subpixel 19 shown in FIG. 4. Note that the operation performed in the period T11 to the period T14 may be included in the operation WRT. In that case, in the driving method shown in FIG. 7A, FIG. 8A, and FIG. 9A, there can be an overlap between the period in which the pixels 13 in a plurality of rows perform the operation WRT. For example, the pixels 13 in the second row can start the operation WRT in a period in which the pixels 13 in the first row perform the operation WRT. For example, the pixels 13 in the second row can perform at least part of the operation in the period T11 to the period T14 in a period in which the pixels 13 in the first row perform the operation in the period T15.

### Example_3 of Pixel Driving Method

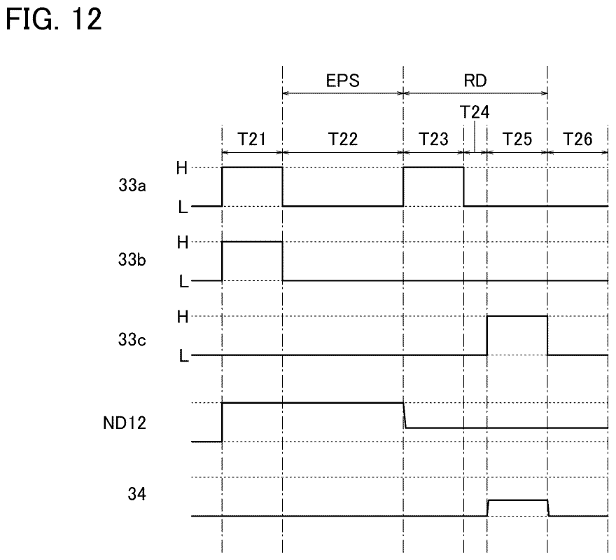

FIG. 12 is a timing chart showing an example of a method for driving the pixel 15 illustrated in FIG. 5A to FIG. 6B. FIG. 12 shows changes in the potentials of the wiring 33a, the wiring 33b, the wiring 33c, the node ND12, and the wiring 34 over time which are divided into a period T21 to a period T26.

An example of a method for driving the pixel 15 is described below assuming that the transistor M11 to the transistor M14 are all n-channel transistors; however, the following description can be applied to the case where at least one of the transistor M11 to the transistor M14 is a p-channel transistor, by inverting the potential levels as appropriate, for example.

In the example shown in FIG. 12, the potentials of the wiring 33a, the wiring 33b, and the wiring 33c are set to low potentials just before the period T21. Thus, in the example shown in FIG. 12, the transistor M11, the transistor M12, and the transistor M14 are in a non-conduction state just before the period T21.

In the period T21, the potentials of the wiring 33a and the wiring 33b are set to high potentials. Since the potential of the wiring 33a is set to a high potential, the transistor M11 is brought into a conduction state, and since the potential of the wiring 33b is set to a high potential, the transistor M12 is brought into a conduction state. Thus, a current flows from the wiring 56 toward the wiring 55, and electric charge accumulated in the node ND11 and electric charge accumulated in the node ND12 are reset. The potential of the node ND12 becomes a potential corresponding to the potential of the wiring 56, e.g., a high potential. Although not shown in FIG. 12, the potential of the node ND11 also becomes the potential corresponding to the potential of the wiring 56, e.g., a high potential.

In the period T22, the potentials of the wiring 33a and the wiring 33b are set to low potentials. Since the potential of the wiring 33a is set to a high potential, the transistor M11 is brought into a non-conduction state, and since the potential of the wiring 33b is set to a high potential, the transistor M12 is brought into a non-conduction state. Thus, light incident on the light-receiving element 17, e.g., a photocurrent with a magnitude corresponding to the illuminance of infrared light, flows from the node ND11 toward the wiring 55. Thus, electric charge is accumulated in the node ND11.

The period T22 is a period in which light exposure is performed on the light-receiving element 17 to obtain imaging data. Electric charge accumulated in the node ND11 in the period T22 corresponds to imaging data. The period T22 is a period in which the operation EPS shown in FIG. 7B, FIG. 7C, FIG. 8B, and FIG. 9B is performed.

In the period T23, the potential of the wiring 33a is set to a high potential. Thus, the transistor M11 is brought into a conduction state. Accordingly, electric charge accumulated in the node ND11 is transferred to the node ND12.

In the period T24, the potential of the wiring 33a is set to a low potential. Thus, the transistor M11 is brought into a non-conduction state, so that the electric charge in the node ND12 is retained. Accordingly, the imaging data is retained in the pixel 15.

In the period T25, the potential of the wiring 33c is set to a high potential. Thus, the transistor M14 is brought into a conduction state. Accordingly, the potential of the wiring 34 becomes a potential corresponding to the potential of the node ND12. In the above manner, the imaging data is read out from the pixel 15.

The period T23 to the period T25 are periods in which the operation RD shown in FIG. 7B, FIG. 7C, FIG. 8B, and FIG. 9B is performed. Note that the period T23 and the period T24 can be excluded from the period in which the operation RD is performed. For example, in the case where image capturing is performed in the global shutter mode as shown in FIG. 7C, the period T23 and the period T24 are not included in the period in which the operation RD is performed. For example, the period T24 is a period in which the operation RET2 is performed. Note that the period T23 may be included in the period in which the operation RET2 is performed.

In the period T26, the potential of the wiring 33c is set to a low potential. Thus, the transistor M14 is brought into a non-conduction state. In this manner, the reading of imaging data from the pixel 15 is completed. The above is the example of the method for driving the pixel 15 illustrated in FIG. 5A to FIG. 6B.

As described above, electric charge in the node ND12 is retained in the period T24, whereby imaging data is retained in the pixel 15. In the case where image capturing is performed in a global shutter mode as described above, imaging data needs to be retained for a long time. Accordingly, in the case where image capturing is performed in a global shutter mode, it is particularly preferable to use transistors with a low off-state current as the transistor M11 and the transistor M12. For example, OS transistors are preferably used as the transistor M11 and the transistor M12.

Note that OS transistors may be used also as the transistor M13 and the transistor M14. In addition, an OS transistor and a Si transistor may be used in appropriate combination. Furthermore, all the transistors may be either OS transistors or Si transistors.

### Structure Example_1 of Semiconductor Device

A structure example of a semiconductor device included in the display device 10 is described below.

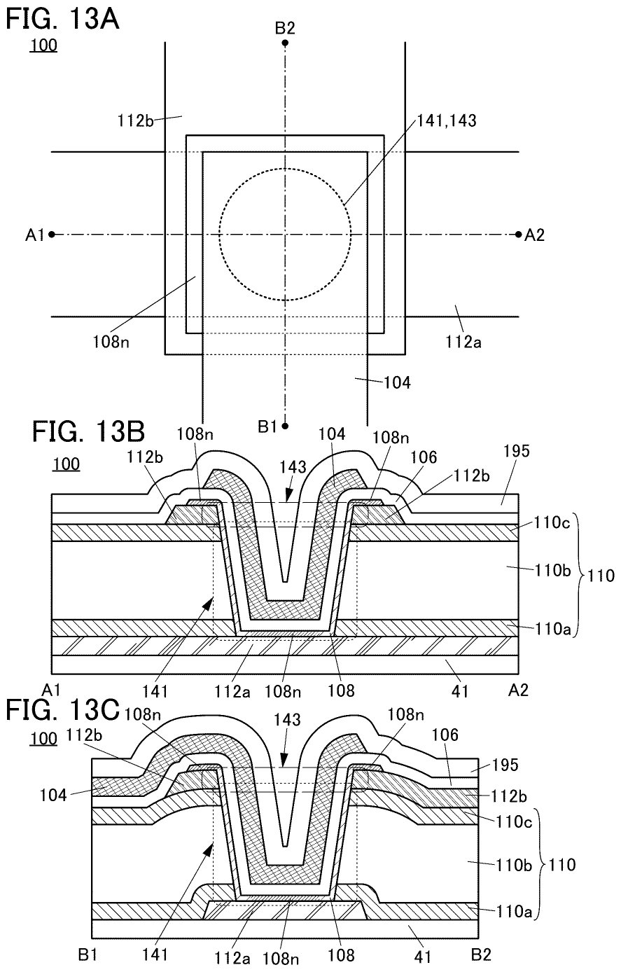

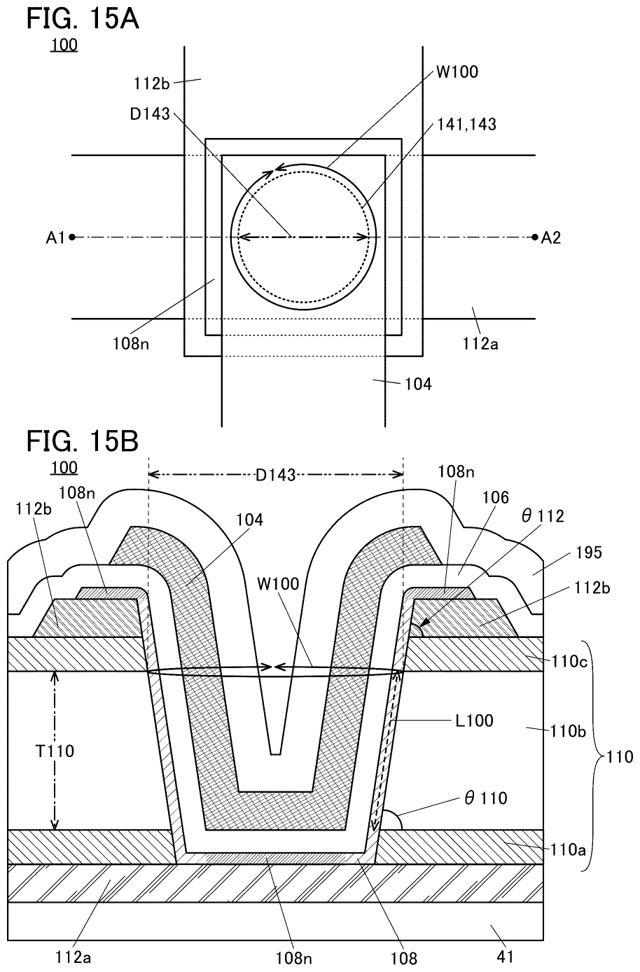

FIG. 13A and FIG. 15A are plan views each illustrating a structure example of a semiconductor device including the transistor 100 that is a transistor of one embodiment of the present invention. Transistors having a structure similar to that of the transistor 100 can be used as the transistor M01 to the transistor M06 included in the pixel circuit 29, for example. Transistors having a structure similar to that of the transistor 100 can be used as the transistor M11 to the transistor M14 included in the pixel circuit 25, for example. A transistor having a structure similar to that of the transistor 100 can be used as the transistor M15, for example. Furthermore, transistors having a structure similar to that of the transistor 100 can be used as transistors provided in the driver circuit 21 to the driver circuit 24, for example.

FIG. 15A is different from FIG. 13A in that a diameter D143 and a channel width W100 are illustrated and dashed-dotted line B1-B2 is not illustrated. FIG. 13A and FIG. 15A omit insulating layers. Other plan views also omit some components.

FIG. 13B and FIG. 15B are cross-sectional views along dashed-dotted lines A1-A2 in FIG. 13A and FIG. 15A, respectively. FIG. 15B can be regarded as an enlarged view of FIG. 13B. FIG. 13B illustrates an opening portion 141 and the opening portion 143, and FIG. 15B illustrates the diameter D143, the channel width W100, a channel length L100, a thickness T110, an angle θ110, and an angle θ112. The other components are common between FIG. 13B and FIG. 15B. FIG. 13C is a cross-sectional view along dashed-dotted line B1-B2 in FIG. 13A.

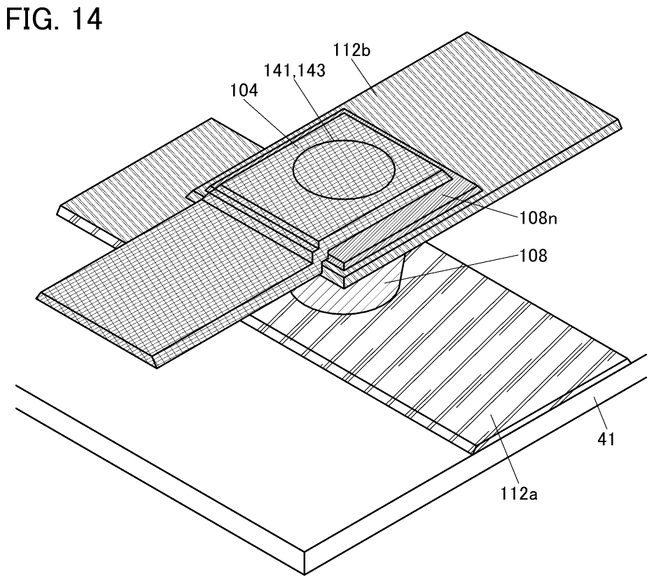

FIG. 14 is a perspective view illustrating a structure example of a semiconductor device including the transistor 100. FIG. 14 omits insulating layers.

The transistor 100 is provided over the substrate 41. The transistor 100 includes a conductive layer 112a, an insulating layer 110 (insulating layers 110a, 110b, and 110c), a semiconductor layer 108, a conductive layer 112b, an insulating layer 106, and a conductive layer 104. The layers forming the transistor 100 may each have a single-layer structure or a stacked-layer structure. The insulating layer 110 is not necessarily regarded as a component of the transistor 100. In other words, the semiconductor device of one embodiment of the present invention can be regarded as including the transistor 100 and the insulating layer 110.

The conductive layer 112a is provided over the substrate 41. The conductive layer 112a functions as one of a source electrode and a drain electrode of the transistor 100.

The insulating layer 110 is positioned over the substrate 41 and the conductive layer 112a. The insulating layer 110 is in contact with the conductive layer 112a. The opening portion 141 reaching the conductive layer 112a is provided in the insulating layer 110.

The insulating layer 110 has a stacked-layer structure of the insulating layer 110a over the substrate 41 and the conductive layer 112a, the insulating layer 110b over the insulating layer 110a, and the insulating layer 110c over the insulating layer 110b.

The conductive layer 112b is positioned over the insulating layer 110. The opening portion 143 overlapping with the opening portion 141 is provided in the conductive layer 112b. The conductive layer 112b functions as the other of the source electrode and the drain electrode of the transistor. It is preferable that the conductive layer 112b not be provided in the opening portion 141. In other words, it is preferable that the conductive layer 112b not include a region that is in contact with a side surface of the insulating layer 110 on the opening portion 141 side.

The semiconductor layer 108 is in contact with the top surface of the conductive layer 112a, the side surface of the insulating layer 110, and the top surface and a side surface of the conductive layer 112b. The semiconductor layer 108 is provided in contact with an end portion of the insulating layer 110 on the opening portion 141 side (which can be regarded as a side wall of the opening portion 141) and an end portion of the conductive layer 112b on the opening portion 143 side (which can be regarded as a side wall of the opening portion 143). The semiconductor layer 108 is in contact with the conductive layer 112a via the opening portion 141 and the opening portion 143.

Part of the semiconductor layer 108 includes a low-resistance region 108n. The low-resistance region 108n contains an impurity element. The low-resistance region 108n is a region having a higher impurity element concentration and lower electric resistance than the other region (e.g., a channel formation region) of the semiconductor layer 108.

In the semiconductor layer 108, the low-resistance region 108n in contact with the conductive layer 112a functions as one of a source region and a drain region, and the low-resistance region 108n in contact with the conductive layer 112b functions as the other of the source region and the drain region. In the semiconductor layer 108, a region between the source region and the drain region includes a region functioning as a channel formation region.

FIG. 13A to FIG. 13C illustrate an example in which the low-resistance region 108n is formed in a region of the semiconductor layer 108 that is in contact with the top surface of the conductive layer 112a and positioned between the top surface of the conductive layer 112a and the bottom surface of the conductive layer 104. The region where the low-resistance region 108n is formed is not limited thereto; for example, the low-resistance region 108n may be formed over the entire region in contact with the top surface of the conductive layer 112a. For example, when an impurity element is supplied or when heat is applied in a step after the impurity element is supplied, the impurity element sometimes diffuses in a direction parallel to the top surface of the substrate 41.

FIG. 13A to FIG. 13C illustrate an example in which the low-resistance region 108n is formed in a region of the semiconductor layer 108 that is in contact with the top surface of the conductive layer 112b. Note that the low-resistance region 108n may also be provided in a region of the semiconductor layer 108 that is in contact with the side surface of the conductive layer 112b. The low-resistance region 108n may also be provided in part of a region of the semiconductor layer 108 that is in contact with the side surface of the insulating layer 110.

The first element is preferably used as the impurity element. Alternatively, both the first element and hydrogen are preferably used as the impurity element. As the first element, it is preferable to use one or more kinds of boron, aluminum, indium, carbon, silicon, germanium, tin, phosphorus, arsenic, antimony, magnesium, calcium, titanium, copper, zinc, tungsten, molybdenum, tantalum, hafnium, cerium, and a noble gas (helium, neon, argon, krypton, xenon, and the like). The first element is not limited to the above elements, and one or more kinds of first transition elements (3d transition elements or 3d transition metals), second transition elements (4d transition elements or 4d transition metals), third transition elements (5d transition elements or 5d transition metals), alkaline earth metal elements, and rare earth elements can be used.

The insulating layer 106 is positioned over the insulating layer 110, the semiconductor layer 108, and the conductive layer 112b. The insulating layer 106 is provided along the side wall of the opening portion 141 and the side wall of the opening portion 143 with the semiconductor layer 108 between the insulating layer 106 and the side walls. The insulating layer 106 functions as a gate insulating layer (also referred to as a first gate insulating layer).

The conductive layer 104 is positioned over the insulating layer 106. The conductive layer 104 overlaps with the semiconductor layer 108 with the insulating layer 106 provided therebetween, in the opening portion 141 and the opening portion 143. The conductive layer 104 functions as a gate electrode (also referred to as a first gate electrode) of the transistor.

An insulating layer 195 is provided to cover the transistor 100. The insulating layer 195 functions as a protective layer of the transistor 100.

The conductive layer 112a, the conductive layer 112b, and the conductive layer 104 can function as wirings, and the transistor 100 can be provided in the region where these wirings overlap with each other. That is, the areas occupied by the transistor 100 and the wirings can be reduced in a circuit including the transistor 100 and the wirings. Accordingly, the area occupied by the circuit can be reduced, which makes it possible to provide a small semiconductor device.

When the semiconductor device of one embodiment of the present invention is used for a pixel circuit of a display apparatus, for example, the area occupied by the pixel circuit can be reduced and a high-resolution display apparatus can be obtained. When the semiconductor device of one embodiment of the present invention is used for a driver circuit of a display apparatus, the area occupied by the driver circuit can be reduced and the display apparatus can have a narrow bezel, for example.

The channel length, channel width, and the like of the transistor 100 will be described with reference to FIG. 15A and FIG. 15B.

The transistor 100 is a transistor in which at least part of a channel formation region provided in the semiconductor layer 108 is provided along the side surface of the insulating layer 110. Accordingly, the transistor 100 is a vertical transistor. In FIG. 15B, the channel length L100 of the transistor 100 is indicated by a dashed double-headed arrow. It can be said that in a cross-sectional view, the channel length L100 is the shortest distance between the portion of the semiconductor layer 108 that is in contact with the insulating layer 110a and the portion of the semiconductor layer 108 that is in contact with the insulating layer 110c.

The channel length L100 of the transistor 100 corresponds to the length of a side surface of the insulating layer 110b on the opening portion 141 side in a cross-sectional view. In other words, the channel length L100 depends on the thickness T110 of the insulating layer 110b and the angle θ110 formed by the side surface of the insulating layer 110b on the opening portion 141 side and the formation surface of the insulating layer 110b (which is the top surface of the insulating layer 110a here). Thus, the channel length L100 can have a value smaller than that of the resolution limit of a light-exposure apparatus, for example, which enables the transistor to have a minute size. Specifically, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, it is also possible to obtain a transistor with a channel length shorter than 10 nm without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 is preferably greater than or equal to 10 nm and less than or equal to 1 μm, further preferably greater than or equal to 10 nm and less than or equal to 500 nm, still further preferably greater than or equal to 10 nm and less than or equal to 100 nm, yet still further preferably greater than or equal to 10 nm and less than or equal to 50 nm.

When the channel length L100 is small, the transistor 100 can have high on-state current. With the use of the transistor 100, a circuit capable of high-speed operation can be manufactured. Furthermore, the area occupied by the circuit can be reduced. Thus, a semiconductor device with a small size can be obtained. The application of the semiconductor device of one embodiment of the present invention to a large display apparatus or a high-resolution display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110 of the insulating layer 110b and the angle θ110, the channel length L100 can be controlled. Note that in FIG. 15B, the thickness T110 of the insulating layer 110b is indicated by the dashed-dotted double-headed arrow.

The thickness T110 of the insulating layer 110b can be, for example, greater than or equal to 10 nm, greater than or equal to 50 nm, greater than or equal to 100 nm, greater than or equal to 150 nm, greater than or equal to 200 nm, greater than or equal to 300 nm, greater than or equal to 400 nm, or greater than or equal to 500 nm and less than 3.0 μm, less than or equal to 2.5 μm, less than or equal to 2.0 μm, less than or equal to 1.5 μm, less than or equal to 1.2 μm, or less than or equal to 1.0 μm. In the case of manufacturing a transistor having a smaller channel length L100, the thickness T110 of the insulating layer 110b can be, for example, greater than or equal to 5 nm, greater than or equal to 7 nm, or greater than or equal to 10 nm and less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

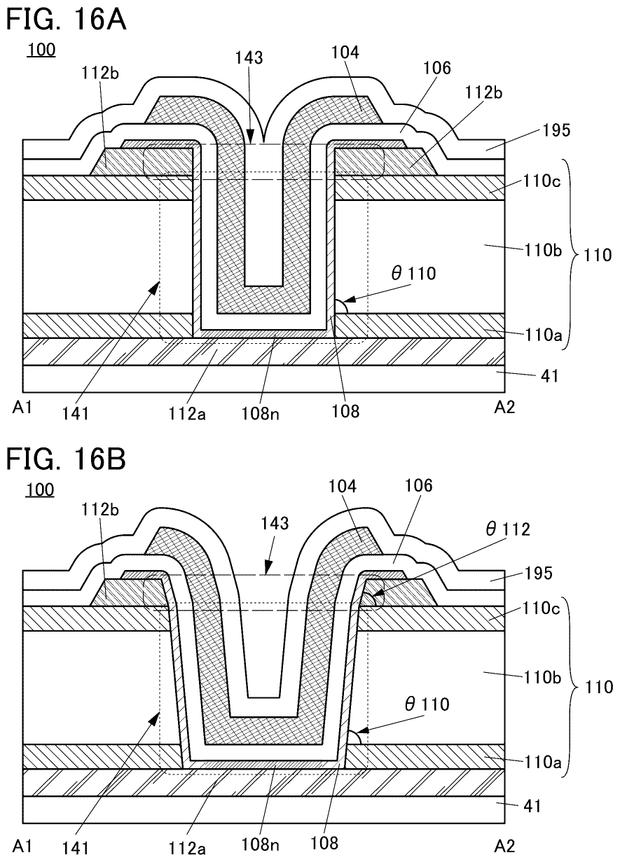

The side surface of the insulating layer 110b on the opening portion 141 side preferably has a vertical shape or a tapered shape. The angle θ110 formed by the side surface of the insulating layer 110b on the opening portion 141 side and the formation surface of the insulating layer 110b (here, the top surface of the insulating layer 110a) is preferably less than or equal to 90°. When the angle θ110 is small, the coverage with a layer provided over the insulating layer 110b (e.g., the semiconductor layer 108) can be increased. The smaller the angle θ110 is, the larger the channel length L100 can be, and the larger the angle θ110 is, the smaller the channel length L100 can be. FIG. 13B, FIG. 13C, and FIG. 15B illustrate an example in which the side surface of the insulating layer 110b on the opening portion 141 side has a tapered shape (the angle θ110 is less than 90°). FIG. 16A illustrates an example in which the side surface of the insulating layer 110b on the opening portion 141 side has a vertical shape (the angle θ110 is 90°).

FIG. 15B illustrates an example in which the angle θ110 is equal to the angle θ112 formed by the side surface of the conductive layer 112b on the opening portion 143 side and the formation surface of the conductive layer 112b (here, the top surface of the insulating layer 110c). Meanwhile, FIG. 16B illustrates an example in which the angle θ110 and the angle θ112 are different from each other.

As illustrated in FIG. 16B, the angle θ112 is preferably smaller than the angle θ110 in a cross-sectional view. When the angle θ112 is smaller than the angle θ110, a step of the formation surface of the layer (e.g., the semiconductor layer 108) formed over the conductive layer 112b and the insulating layer 110 is small, so that coverage with the layer can be improved. This can inhibit generation of a defect such as step disconnection or a void in the layer.

For example, by employing different methods for formation of the opening portion 141 and the opening portion 143, the angle θ110 and the angle θ112 can be made different from each other. For example, when a wet etching method is used for the formation of the opening portion 143 and a dry etching method is used for the formation of the opening portion 141, the angle θ112 can be made smaller than the angle θ110.

The angle θ110 and the angle θ112 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, greater than or equal to 70°, or greater than or equal to 75°and less than or equal to 90°, less than or equal to 85°, or less than or equal to 80°. The angle θ110 and the angle θ112 may be less than or equal to 75°, less than or equal to 70°, less than or equal to 65°, or less than or equal to 60°.

In the case where the angle θ110 and the angle θ112 are each greater than or equal to 80° and less than or equal to 90°, a film to cover the insulating layer 110 is preferably formed by a deposition method that enables favorable coverage. For example, it is preferable that the conductive layer 104 be formed by a chemical vapor deposition (CVD) method and the insulating layer 106 and the semiconductor layer 108 be formed by an atomic layer deposition (ALD) method. For another example, it is preferable that the conductive layer 104, the insulating layer 106, and the semiconductor layer 108 be formed by an ALD method. In the case where the angle θ110 and the angle θ112 are greater than or equal to 60° and less than or equal to 85°, a film to cover the insulating layer 110 may be formed by a deposition method with higher productivity. For example, it is preferable that the semiconductor layer 108 be formed by a sputtering method.

The angle θ110 is defined with reference to the insulating layer 110b here but may be defined with reference to the whole insulating layer 110. In other words, the angle θ110 may be the angle between the side surface of the insulating layer 110 on the opening portion 141 side and the formation surface of the insulating layer 110 (which is the top surface of the conductive layer 112a here).

In the case where, in the semiconductor layer 108, a region in contact with the insulating layer 110a and a region in contact with the insulating layer 110c are included in the channel formation region, in a cross-sectional view, the channel length L100 can be the shortest distance between the portion of the semiconductor layer 108 that is in contact with the conductive layer 112a and the portion of the semiconductor layer 108 that is in contact with the conductive layer 112b. The channel length L100 corresponds to the sum of the lengths of side surfaces of the insulating layer 110a, the insulating layer 110b, and the insulating layer 110c on the opening portion 141 side in a cross-sectional view.

In FIG. 15A and FIG. 15B, the diameter D143 of the opening portion 143 is indicated by the dashed-two dotted double-headed arrow. In the example illustrated in FIG. 15A, the plan-view shape of each of the opening portion 141 and the opening portion 143 is a circle having the diameter D143. Here, the channel width W100 of the transistor 100 is equal to the length of the circumference of this circle. That is, the channel width W100 is π×D143. In the case where the opening portion 141 and the opening portion 143 have circular plan-view shapes as described above, the channel width of the transistor can be smaller than in the case where the opening portion 141 and the opening portion 143 have any other shape.

The diameter of the opening portion 141 and the diameter of the opening portion 143 are sometimes different from each other. Each of the diameter of the opening portion 141 and the diameter of the opening portion 143 varies from position to position in the depth direction in some cases. The average value of the following three diameters can be used as the diameter of the opening portion, for example: the diameter at the highest level of the insulating layer 110 (or the insulating layer 110b) in a cross-sectional view, the diameter at the lowest level of the insulating layer 110 (or the insulating layer 110b) in a cross-sectional view, and the diameter at the midpoint between these levels. For another example, any of the diameter at the highest level of the insulating layer 110 (or the insulating layer 110b) in a cross-sectional view, the diameter at the lowest level of the insulating layer 110 (or the insulating layer 110b) in a cross-sectional view, and the diameter at the midpoint between these levels can be used as the diameter of the opening portion.

In the case where the opening portion 143 is formed by a photolithography method and an etching method, the diameter D143 of the opening portion 143 is larger than or equal to the resolution limit of a light-exposure apparatus. The diameter D143 can be, for example, greater than or equal to 20 nm, greater than or equal to 50 nm, greater than or equal to 100 nm, greater than or equal to 200 nm, greater than or equal to 300 nm, greater than or equal to 400 nm, or greater than or equal to 500 nm and less than 5.0 μm, less than or equal to 4.5 μm, less than or equal to 4.0 μm, less than or equal to 3.5 μm, less than or equal to 3.0 μm, less than or equal to 2.5 μm, less than or equal to 2.0 μm, less than or equal to 1.5 μm, or less than or equal to 1.0 μm.

There is no limitation on the planar shapes of the opening portion 141 and the opening portion 143, and the shapes can each be a circle, an ellipse, a polygon such as a triangle, a tetragon (including a rectangle, a rhombus, and a square), a pentagon, and a star polygon; and polygons with rounded corners, for example. Note that the polygon may be a concave polygon (a polygon at least one of the interior angles of which is greater than 180°) or a convex polygon (a polygon all the interior angles of which are less than or equal to 180°). The planar shapes of the opening portion 141 and the opening portion 143 are preferably circles as shown in FIG. 13A and the like. When the planar shapes of the openings are circles, processing accuracy in forming the openings can be high, whereby the openings can be formed to have minute sizes. In this specification and the like, a circular shape is not necessarily a perfect circular shape.

In this specification and the like, the planar shape of the opening portion 141 refers to the shape of the end portion of the top surface of the insulating layer 110 on the opening portion 141 side. The planar shape of the opening portion 143 refers to the shape of the end portion of the bottom surface of the conductive layer 112b on the opening portion 143 side.

For example, as shown in FIG. 13A, the opening portion 141 and the opening portion 143 can have the same or substantially the same planar shapes. In that case, it is preferable that the end portion of the bottom surface of the conductive layer 112b on the opening portion 143 side be aligned with or substantially aligned with the end portion of the top surface of the insulating layer 110 on the opening portion 141 side as shown in FIG. 13B, FIG. 13C, and the like. The bottom surface of the conductive layer 112b refers to the surface thereof on the insulating layer 110 side. The top surface of the insulating layer 110 refers to the surface thereof on the conductive layer 112b side.

Note that the opening portion 141 and the opening portion 143 do not necessarily have the same planar shapes. In the case where the planar shapes of the opening portion 141 and the opening portion 143 are circular, the opening portion 141 and the opening portion 143 may be concentrically arranged, but not necessarily concentrically arranged.

### Structure Example_2 of Semiconductor Device

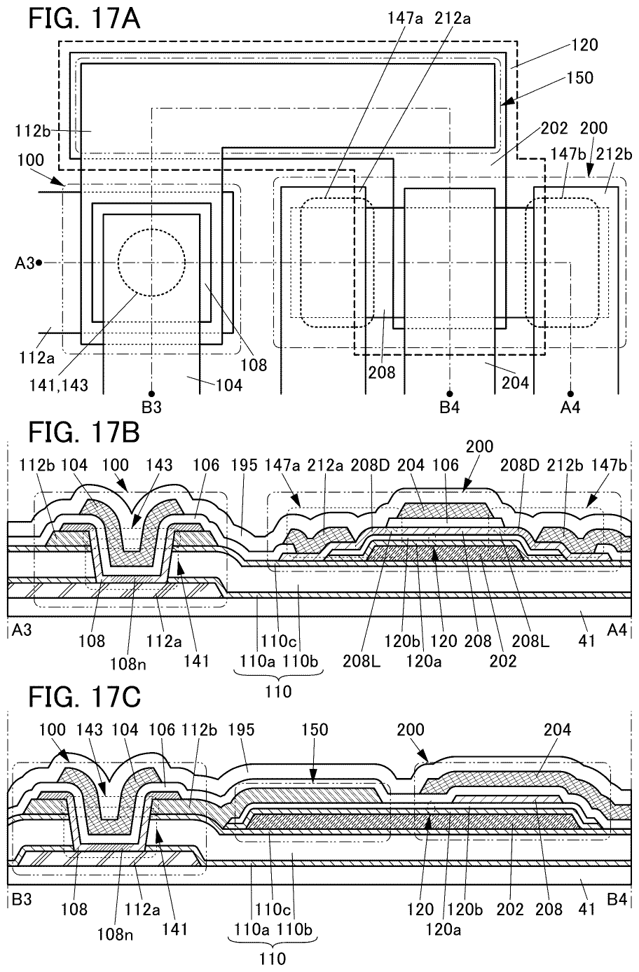

FIG. 17A is a plan view illustrating a structure example of a semiconductor device including, in addition to the transistor 100, a capacitor 150 and a transistor 200 having a structure different from that of the transistor 100. Transistors having a structure similar to that of the transistor 200 can be used as the transistor M01 to the transistor M06 included in the pixel circuit 29, for example. Transistors having a structure similar to that of the transistor 200 can be used as the transistor M11 to the transistor M14 included in the pixel circuit 25, for example. A transistor having a structure similar to that of the transistor 200 can be used as the transistor M15, for example. Furthermore, transistors having a structure similar to that of the transistor 200 can be used as transistors provided in the driver circuit 21 to the driver circuit 24, for example.

The capacitor having a structure similar to that of the capacitor 150 can be used as the capacitor C01 and the capacitor C02 included in the pixel circuit 29, for example. The capacitor having a structure similar to that of the capacitor 150 can be used as the capacitor C11 included in the pixel circuit 25, for example. Furthermore, a capacitor having a structure similar to that of the capacitor 150 can be used as a capacitor provided in the driver circuit 21 to the driver circuit 24, for example.

FIG. 17B is a cross-sectional view along dashed-dotted line A3-A4 in FIG. 17A. FIG. 17C is a cross-sectional view along dashed-dotted line B3-B4 in FIG. 17A.

In the semiconductor device illustrated in FIG. 17A to FIG. 17C, the transistor 100, the transistor 200, and the capacitor 150 are provided over the substrate 41. The transistor 100, the transistor 200, and the capacitor 150 can have some formation steps in common. For the description of the structure example of the transistor 100, the description with reference to FIG. 13A to FIG. 16B can be referred to.

The transistor 200 includes a conductive layer 204, a conductive layer 212a, a conductive layer 212b, the insulating layer 106, a semiconductor layer 208, an insulating layer 120, and a conductive layer 202. In the transistor 200, the conductive layer 204 serves as a gate electrode (also referred to as a first gate electrode), and part of the insulating layer 106 serves as a gate insulating layer (also referred to as a first gate insulating layer). The conductive layer 202 serves as a back gate electrode (also referred to as a second gate electrode), and part of the insulating layer 120 serves as a back gate insulating layer (also referred to as a second gate insulating layer). The conductive layer 212a serves as one of the source electrode and the drain electrode, and the conductive layer 212b serves as the other. The layers constituting the transistor 200 may each have a single-layer structure or a stacked-layer structure. Note that the transistor 200 does not necessarily include the conductive layer 202.

In the semiconductor layer 208 between the source electrode and the drain electrode, the whole region overlapping with the gate electrode with the gate insulating layer therebetween serves as a channel formation region. The semiconductor layer 208 includes a pair of regions 208L between which a channel formation region is sandwiched and a pair of regions 208D outside the pair of regions 208L.

The regions 208L and the regions 208D each include the impurity element. Examples of the impurity element include one or more of hydrogen, boron, carbon, nitrogen, fluorine, phosphorus, sulfur, arsenic, aluminum, magnesium, silicon, and a noble gas. Note that typical examples of a noble gas include helium, neon, argon, krypton, and xenon. It is particularly preferable to use one or more of boron, phosphorus, aluminum, magnesium, and silicon as the impurity element.

An impurity element is supplied (or added or implanted) to the semiconductor layer 208 using the conductive layer 204, the conductive layer 212a, and the conductive layer 212b as masks. Thus, the regions 208D are formed in the region of the semiconductor layer 208 that overlaps with none of the conductive layer 204, the conductive layer 212a, the conductive layer 212b, and the insulating layer 106, and the regions 208L are formed in the region of the semiconductor layer 208 that overlaps with none of the conductive layer 204, the conductive layer 212a, and the conductive layer 212b and overlaps with the insulating layer 106.

In the semiconductor layer 208, a region in contact with the conductive layer 212a and the region 208D adjacent to the region serve as one of a source region and a drain region. In the semiconductor layer 208, a region in contact with the conductive layer 212b and the region 208D adjacent to the region serve as the other of the source region and the drain region.

The conductive layer 202 is provided over the insulating layer 110, and the insulating layer 120 is provided over the conductive layer 202. The insulating layer 120 is provided so as to cover the top surface and the side surface of the conductive layer 202. The insulating layer 120 includes a portion protruding beyond an end portion of the conductive layer 202. An end portion of the insulating layer 120 is in contact with the top surface of the insulating layer 110.

The semiconductor layer 208 is provided over the insulating layer 120. The semiconductor layer 208 includes a region overlapping with the conductive layer 202 with the insulating layer 120 therebetween. The semiconductor layer 208 can be formed using the same material as the semiconductor layer 108. The semiconductor layer 208 can be formed in the same step as the semiconductor layer 108. For example, a film to be the semiconductor layer 108 and the semiconductor layer 208 is formed and then processed, whereby the semiconductor layer 108 and the semiconductor layer 208 can be formed.

The insulating layer 106 is provided over the semiconductor layer 208. Part of the insulating layer 106 serves as the gate insulating layer of the transistor 100 and another part of the insulating layer 106 serves as the gate insulating layer of the transistor 200. The insulating layer 106 includes an opening portion 147a and an opening portion 147b in regions overlapping with the semiconductor layer 208.

The conductive layer 204, the conductive layer 212a, and the conductive layer 212b are provided over the insulating layer 106. The conductive layer 204 includes a region overlapping with the semiconductor layer 208 with the insulating layer 106 therebetween. The conductive layer 204 includes a region overlapping with the conductive layer 202 with the semiconductor layer 208 therebetween. The conductive layer 212a and the conductive layer 212b are provided to cover the opening portion 147a and the opening portion 147b, respectively. The conductive layer 212a is electrically connected to the semiconductor layer 208 through the opening portion 147a, and the conductive layer 212b is electrically connected to the semiconductor layer 208 through the opening portion 147b. The conductive layer 204, the conductive layer 212a, and the conductive layer 212b can include the same material as the conductive layer 104. The conductive layer 204, the conductive layer 212a, and the conductive layer 212b can be formed in the same step as the conductive layer 104. For example, a film to be the conductive layer 104, the conductive layer 204, the conductive layer 212a, and the conductive layer 212b is formed and then processed, whereby the conductive layer 104, the conductive layer 204, the conductive layer 212a, and the conductive layer 212b can be formed.

The transistor 200 is a planar transistor in which the semiconductor layer 208 is provided in a planar shape. The transistor 200 is what is called a top-gate transistor including the gate electrode above the semiconductor layer 208. For example, when an impurity element is added to the semiconductor layer 208 with the conductive layer 204, which serves as the gate electrode, used as a mask, the regions 208D serving as the source region and the drain region can be formed in a self-aligned manner. The transistor 200 can be referred to as a TGSA (Top Gate Self-Aligned) transistor.

The channel length of the transistor 200 can be controlled by the length of the conductive layer 204. Accordingly, the channel length of the transistor 200 has a value larger than or equal to that of the resolution limit of a light-exposure apparatus used for manufacturing the transistor. That is, the channel length of the transistor 200 can be longer than that of the transistor 100. The transistor with a long channel length can have favorable saturation.

In this specification and the like, the state where the change in current is small in a saturation region of the Id-Vd characteristics of a transistor is sometimes described using the expression “favorable saturation”.

The transistor 100 with a short channel length and the transistor 200 with a long channel length can be formed over the same substrate by the formation steps some of which are shared. For example, the transistor 100 is used as the transistor required to have high on-state current and the transistor 200 is used as the transistor required to have favorable saturation, thereby providing a high-performance semiconductor device.

For example, transistors having a structure similar to that of the transistor 100 can be used as the transistor M01 and the transistor M03 to the transistor M06 included in the pixel circuit 29, and a transistor having a structure similar to that of the transistor 200 can be used as the transistor M02. Transistors having a structure similar to that of the transistor 100 can be used as the transistor M11, the transistor M12, the transistor M14, and the transistor M15 included in the pixel circuit 25, and a transistor having a structure similar to that of the transistor 200 can be used as the transistor M13. That is, as the transistor functioning as a switch, a transistor having a structure similar to that of the transistor 100 is preferably used in order to drive the display device of one embodiment of the present invention at high speed. The driving transistor and the reading transistor are preferably transistors having a structure similar to that of the transistor 200 because they are driven in a saturation region.

The capacitor 150 includes the conductive layer 112b and the conductive layer 202 serving as a pair of electrodes and the insulating layer 120. The conductive layer 112b serves as the other of the source electrode and the drain electrode of the transistor 100 and also serves as one of the pair of electrodes of the capacitor 150. The conductive layer 202 serves as the back gate electrode of the transistor 200 and as the other of the pair of electrodes of the capacitor 150. In the insulating layer 120, a region sandwiched between the conductive layer 112b and the conductive layer 202 serves as a dielectric of the capacitor 150. When the conductive layer 112b and the conductive layer 202 are formed by different steps, the capacitor 150 having the conductive layer 112b and the conductive layer 202 as the pair of electrodes can be formed. Forming the conductive layer 112b and the conductive layer 202 by different steps enables employing different materials, whereby the range of choices for materials can be widened.

Although an example in which the capacitor 150 is formed of the conductive layer 112b, the conductive layer 202, and the insulating layer 120 is described with reference to FIG. 17A, there is no limitation on the structure of the capacitor 150. The semiconductor device of one embodiment of the present invention does not necessarily include the capacitor 150. In the case where the capacitor 150 including the conductive layer 112b, the conductive layer 202, and the insulating layer 120 is not provided, the conductive layer 112b and the conductive layer 202 may be formed in the same step.

For example, although the other of the source electrode and the drain electrode of the transistor 100 is electrically connected to the one of the pair of electrodes of the capacitor 150 and the one of the source electrode and the drain electrode of the transistor 200 is electrically connected to the other of the pair of electrodes of the capacitor 150 in FIG. 17A, there is no limitation on the electrical connection relation between the transistor 100, the transistor 200, and the capacitor 150.

An insulating layer 195 is provided to cover the transistor 100, the transistor 200, and the capacitor 150. The insulating layer 195 serves as a protective layer of the transistor 100, the transistor 200, and the capacitor 150.

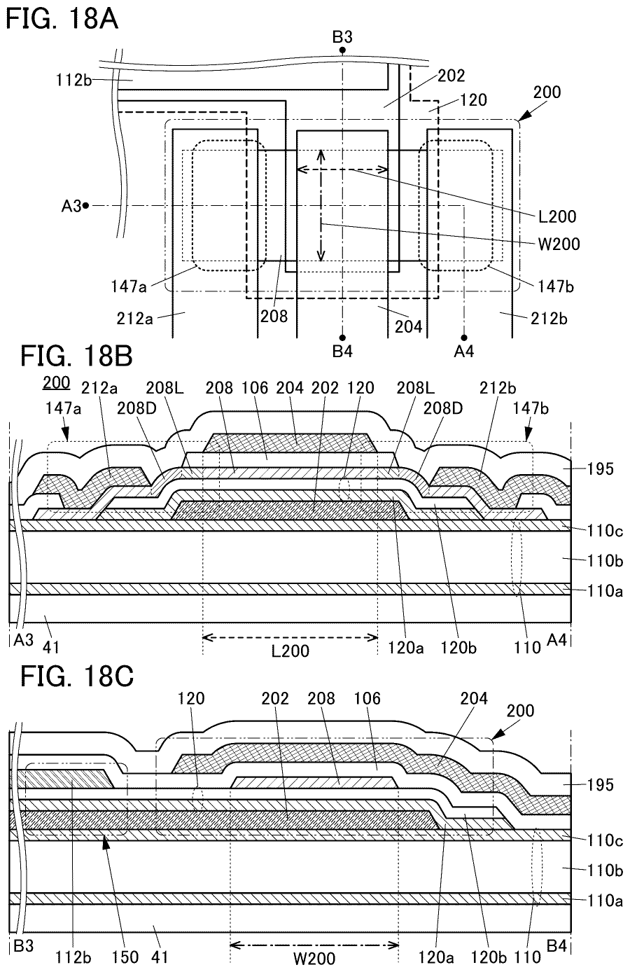

The structure of the transistor 200 is described in detail with reference to FIG. 18A to FIG. 18C. FIG. 18A to FIG. 18C are enlarged views of the transistor 200 shown in FIG. 17A to FIG. 17C, respectively.

The channel length of the transistor 200 is the length of the region between the pair of regions 208D where the semiconductor layer 208 and the conductive layer 204 overlap with each other. In FIG. 18A and FIG. 18B, a channel length L200 of the transistor 200 is indicated by a dashed double-headed arrow. The channel length L200 of the transistor 200 depends on the length of the conductive layer 204 and has a value larger than or equal to that of the resolution limit of the light-exposure apparatus used for manufacturing the transistor. For example, the channel length L200 can be greater than or equal to 1.5 μm. The transistor with a long channel length can have favorable saturation.

The conductive layer 202 serving as the back gate electrode of the transistor 200 preferably extends beyond the end portion of the channel formation region. That is, the size of the conductive layer 202 is preferably larger than the size of the channel formation region. Specifically, the conductive layer 202 preferably has a portion that protrudes beyond the end portion of the conductive layer 204 in the channel length direction.

Note that for easy explanation, in this specification and the like, the portion of the semiconductor layer 208 overlapping with the conductive layer 204 is sometimes described as a channel formation region; however, a channel can be actually formed in a portion not overlapping with the conductive layer 204 and overlapping with the conductive layer 202.

The channel width of the transistor 200 is the width of the region where the semiconductor layer 208 and the conductive layer 204 overlap with each other in the direction orthogonal to the channel length direction. In FIG. 18A and FIG. 18C, a channel width W200 of the transistor 200 is indicated by a dashed-dotted double-headed arrow.

As described above, the channel length L100 of the transistor 100 can have a value smaller than that of the resolution limit of the light-exposure apparatus, and the channel length L200 of the transistor 200 can have a value larger than or equal to that of the resolution limit of the light-exposure apparatus. For example, the transistor 100 is used as the transistor required to have high on-state current and the transistor 200 is used as the transistor required to have favorable saturation, whereby the high-performance semiconductor device utilizing the advantages of the transistors can be provided. Furthermore, some of the formation steps of the transistor 100 can be the same as some of the formation steps of the transistor 200. Specifically, the semiconductor layer 108 and the semiconductor layer 208 can be formed in the same step. Part of the insulating layer 106 serves as the gate insulating layer of the transistor 100 and another part of the insulating layer 106 serves as the gate insulating layer of the transistor 200. The conductive layer 104, the conductive layer 204, the conductive layer 212a, and the conductive layer 212b can be formed in the same process. This allows higher productivity and lower manufacturing cost of the semiconductor device of one embodiment of the present invention.

As shown in FIG. 18A and FIG. 18C, the conductive layer 204 and the conductive layer 202 preferably extend outward from the end portion of the semiconductor layer 208 in the channel width direction of the transistor 200. In that case, as shown in FIG. 18C, the whole of the semiconductor layer 208 in the channel width direction is covered with the conductive layer 204 with the insulating layer 106 therebetween and also covered with the conductive layer 202 with the insulating layer 120 therebetween. In such a structure, the semiconductor layer 208 can be electrically surrounded by electric fields generated by a pair of gate electrodes.

FIG. 18A and FIG. 18C show a structure where the conductive layer 204 and the conductive layer 202 are not electrically connected to each other. A constant potential may be supplied to one of the pair of gate electrodes, and a signal for driving the transistor 200 may be supplied to the other of the pair of gate electrodes. In that case, when the transistor 200 is driven with the signal supplied to the other of the gate electrodes, the potential supplied to the one of the gate electrodes enables control of the threshold voltage.

The conductive layer 204 may be electrically connected to the conductive layer 202. When the same potential is supplied to the conductive layer 204 and the conductive layer 202, electric fields for inducing a channel can be effectively applied to the semiconductor layer 208, whereby the on-state current of the transistor 200 can be increased. Thus, the transistor 200 can also be miniaturized. For example, an opening portion reaching the conductive layer 202 is provided in the insulating layer 106 and the insulating layer 120, and the conductive layer 204 can be formed to cover the opening portion.

The conductive layer 202 may be electrically connected to the conductive layer 212a or the conductive layer 212b. For example, an opening reaching the conductive layer 202 is provided in the insulating layer 120 and the conductive layer 212a or the conductive layer 212b can be formed to cover the opening.

Any of the materials usable for the insulating layer 110 can be used for the insulating layer 120 that is provided in contact with the top surface and the side surface of the conductive layer 202.

The insulating layer 120 preferably has a stacked-layer structure. For example, FIG. 18B shows a structure in which the insulating layer 120 has a stacked-layer structure of an insulating layer 120a and an insulating layer 120b over the insulating layer 120a. For each of the insulating layer 120a and the insulating layer 120b, a material usable for the insulating layer 110 can be used.

For the insulating layer 120b in contact with the channel formation region of the semiconductor layer 208, a film from which oxygen is released by heating is preferably used. When the insulating layer 120b releases oxygen by being heated during the manufacturing process of the transistor 200, the oxygen can be supplied to the semiconductor layer 208, particularly to the channel formation region of the semiconductor layer 208. Oxygen included in the insulating layer 120b diffuses into the insulating layer 120b and is supplied to the semiconductor layer 208 through the interface between the insulating layer 120b and the semiconductor layer 208. Supplying oxygen from the insulating layer 120b to the semiconductor layer 208, particularly to the channel formation region, can repair oxygen vacancies (Vo), whereby the amount of oxygen vacancies (Vo) can be reduced. Consequently, a transistor with favorable electrical characteristics and high reliability can be obtained.

The diffusion coefficient of oxygen in the insulating layer 120b at 350° C. is preferably higher than or equal to 1×10⁻¹² cm²/sec, further preferably higher than or equal to 5×10⁻¹² cm²/sec.

For the insulating layer 120b, a material usable for the insulating layer 110b can be used. The insulating layer 120b preferably includes oxygen and can be formed using any one or more of an oxide and an oxynitride. Specifically, for example, silicon oxide or silicon oxynitride can be used for the insulating layer 120b.

The electrical characteristics of the transistor 200 with a longer channel length are less affected by the oxygen vacancies (Vo) and VoH in the channel formation region than those of the transistor 100 with a shorter channel length. Accordingly, the amount of oxygen supplied from the insulating layer 120b to the semiconductor layer 208 may be smaller than that of oxygen supplied from the insulating layer 110b to the semiconductor layer 108. The amount of oxygen released from the insulating layer 120b may be smaller than that of oxygen released from the insulating layer 110b.

The diffusion coefficient of a substance in the insulating layer 110b is preferably higher than that in the insulating layer 120b. In particular, the diffusion coefficient of oxygen in the insulating layer 110b is preferably higher than that in the insulating layer 120b. This allows the transistor 100 having a short channel length to have favorable electrical characteristics and high reliability.

For the insulating layer 120a in contact with the conductive layer 202, a material that does not easily allow diffusion of a metal element included in the conductive layer 202 is preferably used. This inhibits the metal element included in the conductive layer 202 from diffusing into the channel formation region of the semiconductor layer 208 through the insulating layer 120.

For the insulating layer 120a, a material usable for the insulating layer 110a and the insulating layer 110c is preferably used. The insulating layer 120a preferably includes nitrogen and can be formed using any one or more of a nitride and a nitride oxide. Specifically, for the insulating layer 120a, a silicon nitride can be suitably used, for example. Alternatively, any one or more of an oxide and an oxynitride may be used for the insulating layer 120a. For example, an aluminum oxide can be used for the insulating layer 120a. For the insulating layer 120a, the insulating layer 110a, and the insulating layer 110c, the same material or different materials may be used.

The amount of impurities (e.g., water and hydrogen) released from the insulating layer 120a itself is preferably small. In that case, an impurity included in the insulating layer 120a can be inhibited from diffusing into the channel formation region of the semiconductor layer 208 through the insulating layer 120b, whereby the transistor can have excellent electrical characteristics and high reliability.

Although the insulating layer 120 has a two-layer structure here, one embodiment of the present invention is not limited thereto. The insulating layer 120 may have a stacked-layer structure of three or more layers or a single-layer structure.

Preferably, the insulating layer 120 is provided in a region in contact with at least the channel formation region in the semiconductor layer 208 to cover the top surface and the side surface of the conductive layer 202. For example, FIG. 18B shows the semiconductor layer 208 that includes a portion protruding beyond the end portion of the insulating layer 120. The semiconductor layer 208 includes a region in contact with the side surface of the insulating layer 120. Part of the end portion of the semiconductor layer 208 is in contact with the top surface of the insulating layer 120 and another part of the end portion is in contact with the top surface of the insulating layer 110. It can be said that part of the bottom surface of the semiconductor layer 208 is in contact with the top surface of the insulating layer 120 and another part of the bottom surface is in contact with the top surface of the insulating layer 110. Alternatively, the insulating layer 120 may be provided in a region where the semiconductor layer 208 is provided such that the bottom surface of the semiconductor layer 208 is entirely in contact with the top surface of the insulating layer 120.

Although the thickness of the semiconductor layer 208 is uniform without varying from place to place in the example shown in FIG. 18B, for example, one embodiment of the present invention is not limited to this example. The thickness of the semiconductor layer 208 in the region overlapping with the insulating layer 106 may be different from the thickness of the semiconductor layer 208 in the region not overlapping with the insulating layer 106. For example, when the opening portion 147a and the opening portion 147b are formed, the semiconductor layer 208 is partly removed, so that the semiconductor layer 208 in the region not overlapping with the insulating layer 106 sometimes has a smaller thickness than the semiconductor layer 208 in the region overlapping with the insulating layer 106. Alternatively, the semiconductor layer 208 in the region overlapping with any of the insulating layer 106, the conductive layer 212a, and the conductive layer 212b may differ in thickness from the semiconductor layer 208 in the region not overlapping with any of them. For example, when the conductive layer 212a and the conductive layer 212b are formed, the semiconductor layer 208 is partly removed, so that the semiconductor layer 208 in the region not overlapping with any of the insulating layer 106, the conductive layer 212a, and the conductive layer 212b sometimes has a smaller thickness than the semiconductor layer 208 in the region overlapping with any of them. Alternatively, there may be a difference in the thickness of the semiconductor layer 208 among the region overlapping with the insulating layer 106, the region overlapping with any of the insulating layer 106, the conductive layer 212a, and the conductive layer 212b, and the region not overlapping with any of them.

In the semiconductor layer 208, the region 208D has lower electric resistance than the channel formation region. It can be said that the region 208D has a higher carrier concentration, a higher oxygen vacancy density, or a higher impurity concentration than the channel formation region.

The region 208L is a region whose electric resistance is substantially equal to or lower than that of the channel formation region. The region 208L can be referred to as a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. The region 208L is a region whose electric resistance is substantially equal to or higher than that of the region 208D. The region 208L can be referred to as a region whose carrier concentration is substantially equal to or lower than the carrier concentration of the region 208D, a region whose oxygen vacancy density is substantially equal to or lower than the oxygen vacancy density of the region 208D, or a region whose impurity concentration is substantially equal to or lower than the impurity concentration of the region 208D.

The region 208L serves as a buffer region that relieves a drain electric field. The region 208L is a region not overlapping with the conductive layer 204 and thus is a region where a channel is hardly formed by application of gate voltage to the conductive layer 204. The region 208L preferably has a higher carrier concentration than the channel formation region. Thus, the region 208L can serve as an LDD (Lightly Doped Drain) region. The region 208L serving as the LDD region is provided between the channel formation region and the region 208D, whereby the transistor 200 can have high drain breakdown voltage.

The carrier concentration in the semiconductor layer 208 preferably has a distribution such that the concentration is lowest in the channel formation region and increases in the order of the region 208L and the region 208D. Providing the region 208L between the channel formation region and the region 208D can keep the carrier concentration of the channel formation region extremely low even when an impurity such as hydrogen diffuses from the region 208D during the manufacturing process, for example.

Note that the carrier concentration in the region 208L is not necessarily uniform and sometimes has a gradient such that the carrier concentration decreases from the region 208D side toward the channel formation region. For example, one or both of the hydrogen concentration and the oxygen vacancy concentration in the region 208L may have a gradient such that the concentration decreases from the region 208D side to the channel formation region side.

As shown in FIG. 18A and FIG. 18B, part of the end portions of the conductive layer 212a and the conductive layer 212b are preferably positioned in the opening portion 147a and the opening portion 147b, respectively. In other words, part of the end portions of the conductive layer 212a and the conductive layer 212b are preferably in contact with the semiconductor layer 208 in the opening portion 147a and the opening portion 147b, respectively. Accordingly, the region in contact with the conductive layer 212a can be adjacent to one of the pair of regions 208D and the region in contact with the conductive layer 212b can be adjacent to the other of the pair of regions 208D.

There is no limitation on the planar shapes of the opening portion 147a and the opening portion 147b. The planar shapes of the opening portion 147a and the opening portion 147b can be any of the shapes that can be used for the opening portion 141 and the opening portion 143. The planar shapes of the opening portion 147a and the opening portion 147b are different from the planar shapes of the opening portion 141 and the opening portion 143 and are quadrangles with rounded corners in the structure shown in FIG. 18A, for example; however, one embodiment of the present invention is not limited thereto. The planar shapes of the opening portion 147a and the opening portion 147b may be the same as those of the opening portion 141 and the opening portion 143.

Although the conductive layer 212a and the conductive layer 212b are formed in the same process as the conductive layer 204 here, one embodiment of the present invention is not limited thereto. The conductive layer 212a and the conductive layer 212b may be formed in a step different from that for the conductive layer 204. For example, the conductive layer 104 and the conductive layer 204 are formed over the insulating layer 106 and an impurity element is supplied to the semiconductor layer 208 with the use of the conductive layer 204 as a mask, whereby the source region and the drain region are formed. The insulating layer 195 is formed over the conductive layer 104 and the conductive layer 204, an opening portion reaching the source region and an opening portion reaching the drain region are formed in the insulating layer 106 and the insulating layer 195, and the conductive layer 212a and the conductive layer 212b can be formed to cover the opening portions.

### Material Example

Examples of materials that can be used for components included in the semiconductor device of one embodiment of the present invention are described below.

### [Insulating Layer 110]

The insulating layer 110 can have a single-layer structure or a stacked-layer structure, and preferably has a stacked-layer structure of three or more layers.

The layers constituting the insulating layer 110 are preferably formed using inorganic insulating films. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film.

The insulating layer 110 includes a portion that is in contact with the semiconductor layer 108. In the case where the semiconductor layer 108 is formed using an oxide semiconductor, at least part of the portion of the insulating layer 110 that is in contact with the semiconductor layer 108 is preferably formed using an oxide to improve the characteristics of the interface between the semiconductor layer 108 and the insulating layer 110. Specifically, the portion of the insulating layer 110 that is in contact with the channel formation region of the semiconductor layer 108 is preferably formed using an oxide. The channel formation region is a high-resistance region having a low carrier concentration. The channel formation region can be regarded as an i-type (intrinsic) or substantially i-type region.

As the insulating layer 110b, which is in contact with the channel formation region of the semiconductor layer 108, a layer including oxygen is preferably used. It is preferable that the insulating layer 110b include a region having a higher oxygen content than one or both of the insulating layer 110a and the insulating layer 110c.

The insulating layer 110b is preferably formed using any one or more of the oxide insulating films and oxynitride insulating films described above. Specifically, the insulating layer 110b is preferably formed using one or both of a silicon oxide film and a silicon oxynitride film. By having a high oxygen content, the insulating layer 110b can facilitate formation of an i-type region in a region of the semiconductor layer 108 that is in contact with the insulating layer 110b and the vicinity of this region.

The insulating layer 110b is further preferably formed using a film that releases oxygen when heated. When the insulating layer 110b releases oxygen by being heated during the manufacturing process of the transistor 100, the oxygen can be supplied to the semiconductor layer 108. The oxygen supply from the insulating layer 110b to the semiconductor layer 108, particularly to the channel formation region of the semiconductor layer 108, reduces the amount of oxygen vacancies in the semiconductor layer 108, so that the transistor can have favorable electrical characteristics and high reliability.

For example, the insulating layer 110b can be supplied with oxygen when heat treatment in an oxygen-containing atmosphere or plasma treatment in an oxygen-containing atmosphere is performed. Alternatively, an oxide film may be formed over the top surface of the insulating layer 110b by a sputtering method in an oxygen atmosphere to supply oxygen. After that, the oxide film may be removed.

The insulating layer 110b is preferably formed by a film formation method such as a sputtering method or a plasma-enhanced chemical vapor deposition (PECVD) method. It is particularly preferable to employ a sputtering method, in which a hydrogen gas does not need to be used as a film formation gas, to form a film having an extremely low hydrogen content. In that case, supply of hydrogen to the semiconductor layer 108 is inhibited and the electrical characteristics of the transistor 100 can be stabilized.

For each of the insulating layer 110a and the insulating layer 110c, a film into which oxygen hardly diffuses is preferably used. In that case, it is possible to prevent oxygen included in the insulating layer 110b from being transmitted toward the substrate 41 side through the insulating layer 110a and being transmitted toward the conductive layer 112b side and the insulating layer 106 side through the insulating layer 110c due to heating. In other words, when the insulating layer 110a and the insulating layer 110c that do not easily allow diffusion of oxygen are provided below and above the insulating layer 110b such that the insulating layer 110b is sandwiched therebetween, oxygen can be enclosed in the insulating layer 110b. Accordingly, oxygen can be effectively supplied to the semiconductor layer 108.

For each of the insulating layer 110a and the insulating layer 110c, a film that does not easily allow diffusion of hydrogen is preferably used. In that case, hydrogen can be inhibited from being diffused from outside the transistor to the semiconductor layer 108 through the insulating layer 110a or the insulating layer 110c.

It is preferable that the insulating layer 110a and the insulating layer 110c be each formed using any one or more of the oxide insulating films, nitride insulating films, oxynitride insulating films, and nitride oxide insulating films described above. Specifically, it is preferable to use one or more of a silicon nitride film, a silicon nitride oxide film, a silicon oxynitride film, an aluminum oxide film, an aluminum oxynitride film, an aluminum nitride film, a hafnium oxide film, and a hafnium aluminate film.

It is preferable that the insulating layer 110a and the insulating layer 110c be each formed using any one or more of the nitride insulating films and nitride oxide insulating films described above. Specifically, it is preferable that the insulating layer 110a and the insulating layer 110c be each formed using one or both of a silicon nitride film and a silicon nitride oxide film.

A silicon nitride film and a silicon nitride oxide film release fewer impurities (e.g., water and hydrogen), are less likely to transmit oxygen and hydrogen, and thus can be suitably used for each of the insulating layer 110a and the insulating layer 110c.

The insulating layer 110a and the insulating layer 110c may be formed using any of the aluminum-containing films, for example. The insulating layer 110a and the insulating layer 110c are each preferably formed using, for example, an aluminum oxide film. An aluminum oxide film is suitable because it can have a lower hydrogen content than a silicon nitride film.

The thickness of each of the insulating layer 110a and the insulating layer 110c is preferably greater than or equal to 5 nm and less than or equal to 200 nm, further preferably greater than or equal to 5 nm and less than or equal to 150 nm, still further preferably greater than or equal to 5 nm and less than or equal to 100 nm, yet still further preferably greater than or equal to 10 nm and less than or equal to 70 nm, yet still further preferably greater than or equal to 10 nm and less than or equal to 50 nm, yet still further preferably greater than or equal to 20 nm and less than or equal to 50 nm. When the thickness of each of the insulating layer 110a and the insulating layer 110c is in the above-described range, the amount of oxygen vacancies in the semiconductor layer 108, or specifically the channel formation region, can be reduced. Note that the insulating layer 110a and the insulating layer 110c may have the same thickness or different thicknesses.

It is preferable that, for example, the insulating layer 110a and the insulating layer 110c be formed using silicon nitride films or silicon nitride oxide films and the insulating layer 110b be formed using a silicon oxide film or a silicon oxynitride film.

### [Semiconductor Layer 108 and Semiconductor Layer 208]

The semiconductor layer 108 and the semiconductor layer 208 each include a metal oxide exhibiting semiconductor characteristics (also referred to as an oxide semiconductor).

There is no particular limitation on the crystallinity of the semiconductor materials used for the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The band gaps of metal oxides used for the semiconductor layer 108 and the semiconductor layer 208 are each preferably 2.0 eV or more, further preferably 2.5 eV or more.

Examples of the metal oxides that can be used for the semiconductor layer 108 and the semiconductor layer 208 include indium oxide, gallium oxide, and zinc oxide. The metal oxide preferably contains at least indium or zinc. The metal oxide preferably contains two or three selected from indium, an element M, and zinc. The element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more of the above elements, further preferably one or more selected from aluminum, gallium, tin, and yttrium, still further preferably gallium. In this specification and the like, a metal element and a metalloid element may be collectively referred to as a “metal element”, and a “metal element” described in this specification and the like may encompass a metalloid element.

For example, the semiconductor layer 108 and the semiconductor layer 208 can be formed using indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), indium gallium tin oxide (also referred to as In—Ga—Sn oxide or IGTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be used. Alternatively, the above-described oxide having an amorphous structure can be used. For example, indium oxide having an amorphous structure, indium tin oxide having an amorphous structure, or the like can be used.

By increasing the proportion of the number of indium atoms in the total number of atoms of all the metal elements included in the metal oxide, the field-effect mobility of the transistor can be increased. In addition, the transistor can have a high on-state current.

Note that the metal oxide may contain, instead of or in addition to indium, one or more metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more nonmetallic elements. By containing a nonmetallic element, the metal oxide sometimes has an increased carrier concentration, a reduced band gap, or the like, in which case the transistor can have increased field-effect mobility.

By increasing the proportion of the number of zinc atoms in the total number of atoms of all the metal elements included in the metal oxide, the metal oxide has high crystallinity, so that diffusion of impurities in the metal oxide can be inhibited. Thus, a change in electrical characteristics of the transistor can be inhibited and the reliability of the transistor can be improved.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

The compositions of the metal oxides used for the semiconductor layer 108 and the semiconductor layer 208 affect the electrical characteristics and reliability of the transistors. Therefore, by determining the composition of the metal oxide in accordance with the electrical characteristics and reliability required for the transistor, the semiconductor device can have both excellent electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements of such an In-M-Zn oxide include In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood of any of these atomic ratios. Note that a composition in the neighborhood includes the range of ±30% of an intended atomic ratio. By increasing the proportion of the number of indium atoms in the metal oxide, the on-state current, field-effect mobility, or the like of the transistor can be improved.

The proportion of the number of In atoms may be less than that of the number of M atoms in the In-M-Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

A sputtering method or an ALD method can be suitably used to form the metal oxide. Note that in the case where the metal oxide is formed by a sputtering method, the composition of the formed metal oxide film may be different from the composition of a target. In particular, the zinc content percentage of the formed metal oxide film may be reduced to approximately 50% of that of the target.

The semiconductor layer 108 and the semiconductor layer 208 may each have a stacked-layer structure of two or more metal oxide layers. The two or more metal oxide layers included in each of the semiconductor layer 108 and the semiconductor layer 208 may have the same composition or substantially the same compositions. When the compositions of the stacked metal oxide layers are the same, they can be formed using the same sputtering target, for example, and the manufacturing cost can thus be reduced.

The two or more metal oxide layers included in each of the semiconductor layer 108 and the semiconductor layer 208 may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In addition, it is particularly preferable to use gallium, aluminum, or tin as the element M. For another example, a stacked-layer structure of any one selected from indium oxide, indium gallium oxide, and IGZO, and any one selected from IAZO, IAGZO, and ITZO (registered trademark) may be employed.

It is preferable that the semiconductor layer 108 and the semiconductor layer 208 each include a metal oxide layer having crystallinity. Examples of the structure of a metal oxide having crystallinity include a CAAC (c-axis aligned crystal) structure, a polycrystalline structure, and a nano-crystal (nc) structure. By using a metal oxide layer having crystallinity as the semiconductor layer 108 and the semiconductor layer 208, the density of defect states in the semiconductor layer 108 and the semiconductor layer 208 can be reduced, which enables the semiconductor device to have high reliability.

The higher the crystallinity of the metal oxide layer used as each of the semiconductor layer 108 and the semiconductor layer 208 is, the lower the density of defect states in each of the semiconductor layer 108 and the semiconductor layer 208 can be. By contrast, the use of a metal oxide layer having low crystallinity makes it possible that a high current flows in the transistor.

In the case where the metal oxide layer is formed by a sputtering method, the higher the substrate temperature (the stage temperature) in the formation is, the higher the crystallinity of the formed metal oxide layer can be. Furthermore, the higher the proportion of the flow rate of an oxygen gas in the whole film formation gas (hereinafter also referred to as an oxygen flow rate ratio) used in the formation is, the higher the crystallinity of the formed metal oxide layer can be.

The semiconductor layer 108 and the semiconductor layer 208 may each have a stacked-layer structure of two or more metal oxide layers having different crystallinities. For example, a stacked-layer structure of the first metal oxide layer and the second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

The thickness of each of the semiconductor layer 108 and the semiconductor layer 208 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm.

In the case where the semiconductor layer 108 and the semiconductor layer 208 are formed using an oxide semiconductor, hydrogen contained in the oxide semiconductor reacts with oxygen bonded to a metal atom to be water, and thus sometimes forms an oxygen vacancy (hereinafter referred to as Vo) in the oxide semiconductor. In some cases, a defect that is an oxygen vacancy into which hydrogen enters (VoH) functions as a donor and generates an electron serving as a carrier. In other cases, bonding of part of hydrogen to oxygen bonded to a metal atom generates electrons serving as carriers. Thus, a transistor including an oxide semiconductor that contains a large amount of hydrogen is likely to have normally-on characteristics (i.e., a negative threshold voltage value). Moreover, hydrogen in an oxide semiconductor is easily transferred by a stress such as heat or an electric field; thus, a large amount of hydrogen in an oxide semiconductor might reduce the reliability of a transistor.

In the case where an oxide semiconductor is used for each of the semiconductor layer 108 and the semiconductor layer 208, the amount of VoH in each of the semiconductor layer 108 and the semiconductor layer 208 is preferably reduced as much as possible so that the semiconductor layer 108 becomes a highly purified intrinsic or substantially highly purified intrinsic semiconductor layer. In order to obtain such an oxide semiconductor with a sufficiently reduced amount of VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment.

When an oxide semiconductor is used for each of the semiconductor layer 108 and the semiconductor layer 208, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in a region functioning as the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be held for a long period. Furthermore, the semiconductor device can have lower power consumption by including the OS transistor.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a meson beam, a proton beam, and a neutron beam).

Other examples of the semiconductor material that can be used for each of the semiconductor layer 108 and the semiconductor layer 208 include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may contain an impurity as a dopant.

Examples of silicon that can be used for each of the semiconductor layer 108 and the semiconductor layer 208 include single crystal silicon, polycrystalline silicon, microcrystalline silicon, and amorphous silicon. An example of polycrystalline silicon is LTPS.

The transistor including amorphous silicon in each of the semiconductor layer 108 and the semiconductor layer 208 can be formed over a large-sized glass substrate, thereby reducing the manufacturing cost. The transistor including polycrystalline silicon in each of the semiconductor layer 108 and the semiconductor layer 208 has high field-effect mobility and can operate at high speed. The transistor including microcrystalline silicon in each of the semiconductor layer 108 and the semiconductor layer 208 has higher field-effect mobility and can operate at higher speed than the transistor including amorphous silicon.

The semiconductor layer 108 and the semiconductor layer 208 may each include a layered substance functioning as a semiconductor. The layered substance generally refers to a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

[Conductive Layer 112a and Conductive Layer 112b]

The conductive layer 112a and the conductive layer 112b can each have a single-layer structure or a stacked-layer structure of two or more layers. The conductive layer 112a and the conductive layer 112b can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a and the conductive layer 112b, a conductive material with low electrical resistance that contains one or more of copper, silver, gold, and aluminum can be suitably used. Copper or aluminum is particularly preferable because of its high mass-productivity.

For each of the conductive layer 112a and the conductive layer 112b, a metal oxide having conductivity (also referred to as an oxide conductor) can be used. Examples of an oxide conductor include an indium oxide, a zinc oxide, an In—Sn oxide (ITO), an In—Zn oxide (also referred to as IZO (registered trademark)), an In—W oxide, an In—W—Zn oxide, an In—Ti oxide, an In—Ti—Sn oxide, an In—Sn—Si oxide (also referred to as an ITO containing silicon or an ITSO), a zinc oxide to which gallium is added, and an In—Ga—Zn oxide. A conductive oxide containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layer 112a and the conductive layer 112b may each have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 112a and the conductive layer 112b. The use of a Cu—X alloy film results in lower manufacturing cost because the film can be processed by a wet etching method.

Each of the conductive layer 112a and the conductive layer 112b has a region in contact with the semiconductor layer 108. In the case where an oxide semiconductor is used for the semiconductor layer 108, when the conductive layer 112a or the conductive layer 112b is formed using a metal that is likely to be oxidized (e.g., aluminum), an insulating oxide (e.g., aluminum oxide) is formed between the semiconductor layer 108 and the conductive layer 112a or the conductive layer 112b, which might prevent electrical continuity between the semiconductor layer 108 and the conductive layer 112a or the conductive layer 112b. Thus, a conductive material that is not easily oxidized, a conductive material that maintains low electric resistance even after being oxidized, or an oxide conductor is preferably used for the conductive layer 112a and the conductive layer 112b. Accordingly, an increase in contact resistance between the semiconductor layer 108 and the conductive layer 112a or the conductive layer 112b can be inhibited.

In the case where the conductive layer 112a or the conductive layer 112b has a stacked-layer structure, a conductive material that is not easily oxidized, a conductive material that maintains low electric resistance even after being oxidized, or an oxide conductor is preferably used for the layer thereof that is in contact with the semiconductor layer 108. For the conductive layer 112a or the conductive layer 112b that is not in contact with the semiconductor layer 108, a variety of conductive materials can be used, and a material with high conductivity (also referred to as a material with low resistance) is preferably used. In that case, the conductive layer 112a and the conductive layer 112b can be suitable as wirings.

Examples of the conductive material that is not easily oxidized or the conductive material that maintains low electric resistance even after being oxidized include titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, and an oxide containing lanthanum and nickel.

Specific examples of the oxide conductor are as described above.

For each of the conductive layer 112a and the conductive layer 112b, a nitride conductor may be used. Examples of the nitride conductor include tantalum nitride and titanium nitride.

The conductive layer 112a and the conductive layer 112b may be formed using the same material or different materials.

In each of the conductive layer 112a and the conductive layer 112b, a conductive material that is not easily oxidized, a conductive material that maintains low electric resistance even after being oxidized, or an oxide conductor is preferably used for the layer thereof in contact with the semiconductor layer 108, and a material having higher conductivity than the material used for the layer in contact with the semiconductor layer 108 is preferably used for at least one of the other layers. Thus, the contact resistance between the semiconductor layer 108 and the conductive layer 112a and the contact resistance between the semiconductor layer 108 and the conductive layer 112b can be inhibited from being increased. In addition, the wiring resistances of the conductive layer 112a and the conductive layer 112b can be reduced.

Specific examples of the structures of the conductive layer 112a and the conductive layer 112b include a stacked-layer structure of one or more metal films and one or more oxide conductor films and a stacked-layer structure in which one or more metal films are provided between a pair of oxide conductor films. Examples of the one or more metal films include a single-layer structure of a tungsten film, a single-layer structure of a titanium film, a single-layer structure of a copper film, a two-layer structure of a titanium film and an aluminum film, and a three-layer structure of a titanium film, an aluminum film, and a titanium film. Examples of the oxide conductor film include a single-layer structure of an In—Zn oxide film, a single-layer structure of an ITO film, and a single-layer structure of an ITSO film.

### [Conductive Layer 104, Conductive Layer 202, and Conductive Layer 204]

The conductive layer 104, the conductive layer 202, and the conductive layer 204 can each have a single-layer structure or a stacked-layer structure of two or more layers. The conductive layer 104, the conductive layer 202, and the conductive layer 204 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 104, the conductive layer 202, and the conductive layer 204, a conductive material with low electrical resistance that contains one or more of copper, silver, gold, and aluminum can be suitably used. Copper or aluminum is particularly preferable because of its high mass-productivity.

The above-described oxide conductor can be used for the conductive layer 104, the conductive layer 202, and the conductive layer 204.

The conductive layer 104, the conductive layer 202, and the conductive layer 204 may each have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film may be used for each of the conductive layer 104, the conductive layer 202, and the conductive layer 204. The use of a Cu—X alloy film results in lower manufacturing cost because the film can be processed by a wet etching method.

It is preferable that the conductive layer 104, the conductive layer 202, and the conductive layer 204 each have a three-layer structure of a titanium film, an aluminum film, and a titanium film, for example. It is also preferable that the conductive layer 104, the conductive layer 202, and the conductive layer 204 each have a two-layer structure of a titanium film and an aluminum film. It is also preferable that the conductive layer 104, the conductive layer 202, and the conductive layer 204 each have a two-layer structure of a copper film and a titanium film or a molybdenum film.

As described above, the same material as for the conductive layer 104 and the conductive layer 204 can be used for the conductive layer 212a and the conductive layer 212b. Note that the conductive layer 112a, the conductive layer 112b, the conductive layer 104, the conductive layer 202, the conductive layer 212a, the conductive layer 212b, and the conductive layer 204 may be formed using the same material, or at least one of them may be formed using a different material.

### [Insulating Layer 106]

The insulating layer 106 may have a single-layer structure or a stacked-layer structure of two or more layers. The insulating layer 106 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 106 includes a portion that is in contact with the semiconductor layer 108. In the case where the semiconductor layer 108 is formed using an oxide semiconductor, at least the film of the insulating layer 106 that is in contact with the semiconductor layer 108 is preferably any of the above-described oxide insulating films and oxynitride insulating films. A film that releases oxygen when heated is further preferably used for the insulating layer 106.

Specifically, in the case where the insulating layer 106 has a single-layer structure, the insulating layer 106 is preferably formed using a silicon oxide film or a silicon oxynitride film.

The insulating layer 106 can have a stacked-layer structure of an oxide insulating film or an oxynitride insulating film on the side that is in contact with the semiconductor layer 108 and a nitride insulating film or a nitride oxide insulating film on the side that is in contact with the conductive layer 104. As the oxide insulating film or an oxynitride insulating film, for example, a silicon oxide film or a silicon oxynitride film is preferably used. As the nitride insulating film or the nitride oxide insulating film, a silicon nitride film or a silicon nitride oxide film is preferably used.

A silicon nitride film and a silicon nitride oxide film can be suitably used for the insulating layer 106 because they release fewer impurities (e.g., water and hydrogen) and are less likely to transmit oxygen and hydrogen. Inhibiting diffusion of impurities from the insulating layer 106 to the semiconductor layer 108 results in favorable electrical characteristics and high reliability of the transistor.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Insulating Layer 195]

The insulating layer 195 serving as a protective layer of the transistor 100, the transistor 200, and the capacitor 150 is preferably formed using a material that does not easily allow diffusion of impurities. Providing the insulating layer 195 can effectively inhibit diffusion of impurities into the transistors from the outside and increase the reliability of the semiconductor device. Examples of the impurities include water and hydrogen.

The insulating layer 195 can be an insulating layer including an inorganic material or an insulating layer including an organic material. For example, an inorganic material such as an oxide, an oxynitride, a nitride oxide, or a nitride can be used for the insulating layer 195. More specifically, one or more of a silicon nitride, a silicon nitride oxide, a silicon oxynitride, an aluminum oxide, an aluminum oxynitride, an aluminum nitride, a hafnium oxide, and a hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

### [Substrate 41]

For the substrate 41, glass, quartz, ceramic, sapphire, a resin, a metal, an alloy, a semiconductor, or the like can be used. Use of a flexible material for the substrate 41 can increase the flexibility of the display device and thus a flexible display can be achieved. Furthermore, a polarizing plate may be used as the substrate 41.

For the substrate 41, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 41.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

### Structure Example_2 of Display Device

Structure examples of a display device 10A, a display device 10B, a display device 10C, a display device 10D, and a display device 10E, which are each a kind of the display device 10, are described below.

### [Display Device 10A]

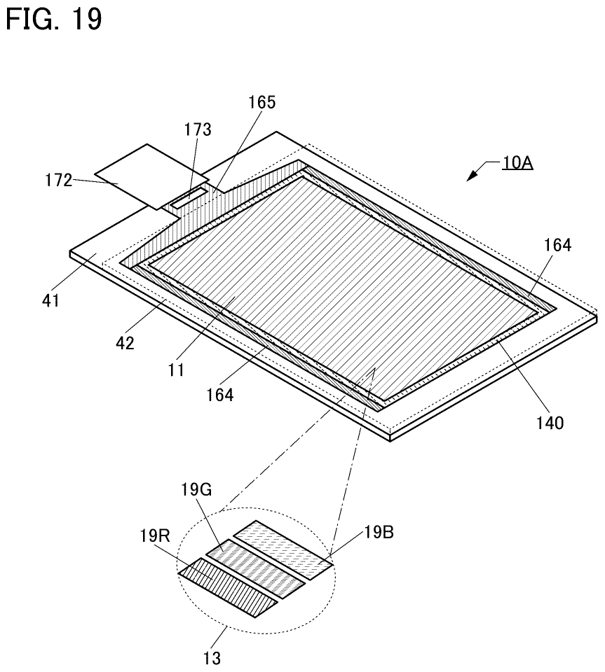

FIG. 19 is a perspective view illustrating a structure example of the display device 10A. The display device 10A has a structure in which the substrate 42 and the substrate 41 are bonded to each other. In FIG. 19, the substrate 42 is denoted by a dashed line.

The display device 10A includes the display region 11, a connection portion 140, a circuit portion 164, a conductive layer 165, and the like. FIG. 19 illustrates an example in which an IC 173 and an FPC 172 are mounted on the display device 10A. Thus, the structure illustrated in FIG. 19 can be regarded as a display module including the display device 10A, the IC, and the FPC.

The connection portion 140 is provided outside the display region 11. The connection portion 140 can be provided along one or more sides of the display region 11. The number of connection portions 140 may be one or more. FIG. 19 illustrates an example where the connection portion 140 is provided to surround the four sides of the display region. In the connection portion 140, a common electrode of a light-emitting element is electrically connected to a conductive layer so that a potential can be supplied to the common electrode.

The circuit portion 164 includes, for example, the driver circuit 21 serving as a scan line driver circuit and the driver circuit 23 serving as a row driver circuit. The conductive layer 165 has a function of supplying a signal and power to the display region 11 and the circuit portion 164. The signal and power are input to the conductive layer 165 from the outside through the FPC 172 or input to the conductive layer 165 from the IC 173.

FIG. 19 illustrates an example in which the IC 173 is provided on the substrate 41 by a COG method, a COF method, or the like. An IC including the driver circuit 22 serving as a signal line driver circuit and the driver circuit 24 serving as a reading circuit can be used as the IC 173, for example. Note that the display device 10A and the display module are not necessarily provided with the IC. The IC may be mounted on the FPC by a COF method, for example.

Note that in the display device 10A, the circuit portion 164 may include one or both of the driver circuit 22 and the driver circuit 24. The IC 173 may include one or both of the driver circuit 21 and the driver circuit 23.

The display region 11 includes the plurality of pixels 13 arranged in a matrix as described above. An enlarged view of one pixel 13 is illustrated in FIG. 19. Although not illustrated in FIG. 19, the display region 11 includes the pixel 15 that is a sensor pixel. Furthermore, although not illustrated in FIG. 19, the display region 11 can include the light-emitting element 14 illustrated in FIG. 1A, for example.

The pixel 13 illustrated in FIG. 19 includes a subpixel 19R that emits red light, a subpixel 19G that emits green light, and a subpixel 19B that emits blue light. There is no particular limitation on the number of subpixels included in one pixel.

The subpixel 19R, the subpixel 19G, and the subpixel 19B each include a light-emitting element and a pixel circuit for controlling the driving of the light-emitting element. The subpixel 19R can include the light-emitting element 16R illustrated in FIG. 1B. The subpixel 19G can include the light-emitting element 16G illustrated in FIG. 1B. The subpixel 19B can include the light-emitting element 16B illustrated in FIG. 1B.

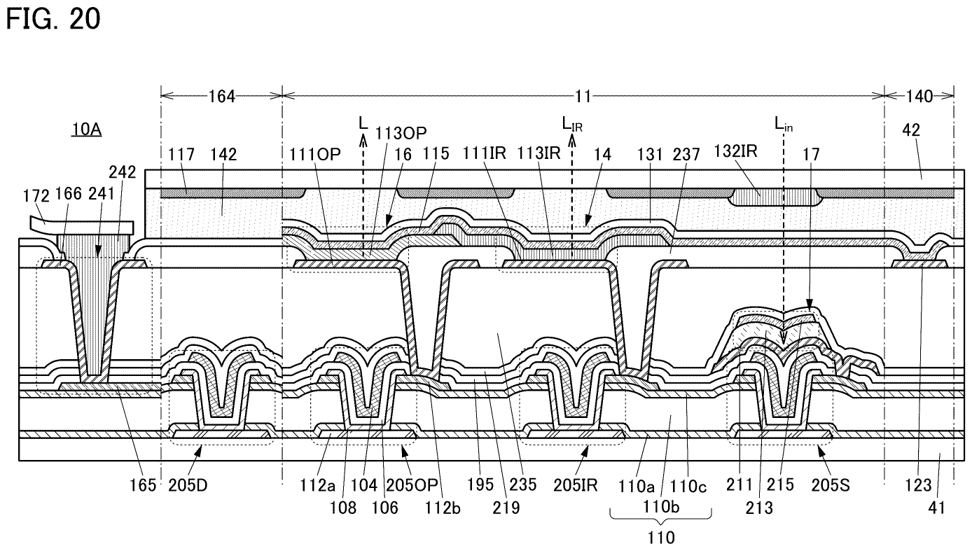

FIG. 20 illustrates an example of cross sections of part of a region including the FPC 172, part of the circuit portion 164, part of the display region 11, part of the connection portion 140, and part of a region including the end portion in the display device 10A.

The display device 10A illustrated in FIG. 20 includes a transistor 205D, a transistor 205OP, a transistor 205IR, a transistor 205S, the light-emitting element 16, the light-emitting element 14, the light-receiving element 17, and the like between the substrate 41 and the substrate 42. The light-emitting element 16 emits visible light as described above and is provided in the subpixel 19R, the subpixel 19G, and the subpixel 19B. As described above, the light-emitting element 14 emits infrared light, for example. As described above, the light-receiving element 17 has sensitivity to infrared light, for example.

The display device 10A employs an SBS structure. The SBS structure can optimize materials and structures of light-emitting elements and thus can extend the freedom of choice of materials and structures, whereby the luminance and the reliability can be easily improved.

The transistor 205D, the transistor 205OP, the transistor 205IR, and the transistor 205S are each formed over the substrate 41. These transistors can be fabricated using the same material in the same process.

This embodiment describes an example in which OS transistors are used as the transistor 205D, the transistor 205OP, the transistor 205IR, and the transistor 205S. Any of the transistors of embodiments of the present invention can be used as the transistor 205D, the transistor 205OP, the transistor 205IR, and the transistor 205S. In other words, the display device 10A includes the transistor of one embodiment of the present invention in both the display region 11 and the circuit portion 164. When the display region 11 includes the transistor of one embodiment of the present invention, the pixel size can be reduced and high definition can be achieved. Furthermore, when the circuit portion 164 includes the transistor of one embodiment of the present invention, the area occupied by the circuit portion 164 can be reduced and a narrower bezel can be achieved.

Specifically, the transistor 205D, the transistor 205OP, the transistor 205IR, and the transistor 205S each include the conductive layer 104 functioning as a gate, the insulating layer 106 functioning as a gate insulating layer, the conductive layer 112a and the conductive layer 112b functioning as a source and a drain, the semiconductor layer 108 containing a metal oxide, and the insulating layer 110 (the insulating layer 110a, the insulating layer 110b, and the insulating layer 110c). Here, a plurality of layers obtained by processing the same conductive film are illustrated with the same hatching pattern. The insulating layer 110 is positioned between the conductive layer 112a and the conductive layer 112b. The insulating layer 106 is positioned between the conductive layer 104 and the semiconductor layer 108.

Note that the transistor included in the display device of this embodiment is not limited to the transistor of one embodiment of the present invention. For example, the display device of this embodiment may include the transistor of one embodiment of the present invention and a transistor having another structure in combination.

The transistor included in the circuit portion 164 and the transistor included in the display region 11 may have the same structure or different structures. One structure or two or more kinds of structures may be employed for a plurality of transistors included in the circuit portion 164. Similarly, one structure or two or more kinds of structures may be employed for a plurality of transistors included in the display region 11.

The insulating layer 195 is provided so as to cover the transistor 205D, the transistor 205OP, the transistor 205IR, and the transistor 205S. The insulating layer 195 preferably functions as a protective layer of the transistors. A material that does not easily allow impurities such as water and hydrogen to diffuse is preferably used for the insulating layer 195. Thus, the insulating layer 195 can function as a barrier layer. Such a structure can effectively inhibit diffusion of impurities into the transistors from the outside and increase the reliability of the display device.

The insulating layer 195 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The light-receiving element 17 is provided over the insulating layer 195. The light-receiving element 17 includes a conductive layer 211, a PD layer 213 over the conductive layer 211, and a conductive layer 215 over the PD layer 213. The conductive layer 211 functions as the one electrode of the light-receiving element 17. The conductive layer 215 functions as the other electrode of the light-receiving element 17. The conductive layer 211 is electrically connected to the conductive layer 112b included in the transistor 205S through the opening portion provided in the insulating layer 106 and the insulating layer 195. The transistor 205S corresponds to the transistor M11 illustrated in FIG. 5A to FIG. 6B, for example.

The PD layer 213 includes at least an active layer (also referred to as a light-receiving layer or a photoelectric conversion layer) as described above. The active layer has sensitivity to light Lᵢₙ entering from the outside of the display device 10A. The light Lᵢₙ can be part of the light L_{IR} emitted from the light-emitting element 14. For example, in the case where the display device 10A functions as a touch sensor or a noncontact sensor, the light L_{IR} that is incident on and reflected by an object can be the light Lᵢₙ. Accordingly, it can be said that the active layer has sensitivity to the light L_{IR}.

The active layer contains a semiconductor material. An inorganic semiconductor can be used as the semiconductor material. Examples of the inorganic semiconductor include silicon and a metal oxide, and specifically, amorphous silicon can be used. Alternatively, single crystal silicon, polycrystalline silicon, or the like may be used as silicon.

An insulating layer 219 is provided to cover the light-receiving element 17. The insulating layer 219 preferably functions as a protective layer of the light-receiving element 17. For the insulating layer 219, a material similar to the material that can be used for the insulating layer 195 can be used.

An insulating layer 235 is provided over the insulating layer 219. The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, formation of a depressed portion in the insulating layer 235 can be inhibited in processing a pixel electrode 111OP, a pixel electrode 111IR, and the like. Alternatively, a depressed portion may be formed in the insulating layer 235 in processing the pixel electrode 111OP, the pixel electrode 111IR, and the like.

The light-emitting element 16 and the light-emitting element 14 are provided over the insulating layer 235.

The light-emitting element 16 includes the pixel electrode 111OP over the insulating layer 235, an EL layer 113OP over the pixel electrode 111OP, and a common electrode 115 over the EL layer 113OP. The pixel electrode 111OP is electrically connected to the conductive layer 112b included in the transistor 205OP through an opening portion provided in the insulating layer 106, the insulating layer 195, the insulating layer 219, and the insulating layer 235. The transistor 205OP corresponds to, for example, the transistor M03 illustrated in FIG. 3 and FIG. 4.

The EL layer 113OP includes a light-emitting layer that emits light L that is visible light. The light-emitting layer emits red light, green light, blue light, yellow light, cyan light, magenta light, or white light, for example. For example, the EL layer 113OP illustrated in FIG. 20 can include a light-emitting layer that emits red light. In that case, in addition to the light-emitting element 16 including the EL layer 113OP emitting red light, the light-emitting element 16 including the EL layer 113OP emitting green light and the light-emitting element 16 including the EL layer 113OP emitting blue light are provided in the display region 11.

The light-emitting element 14 includes the pixel electrode 111IR over the insulating layer 235, an EL layer 113IR over the pixel electrode 111IR, and the common electrode 115 over the EL layer 113IR. The pixel electrode 111IR is electrically connected to the conductive layer 112b included in the transistor 205IR through an opening portion provided in the insulating layer 106, the insulating layer 195, the insulating layer 219, and the insulating layer 235. The transistor 205IR corresponds to, for example, the transistor M12 illustrated in FIG. 5B. Alternatively, the transistor 205IR corresponds to the transistor M15 illustrated in FIG. 6A and FIG. 6B, for example. The EL layer 113IR includes a light-emitting layer that emits light L_{IR} that is infrared light, for example.

End portions of the pixel electrode 111OP and the pixel electrode 111IR are covered with an insulating layer 237. The insulating layer 237 functions as a partition. The insulating layer 237 can have a single-layer structure or a stacked-layer structure including one or both of an inorganic insulating material and an organic insulating material. A material that can be used for the insulating layer 195 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The insulating layer 237 is provided in at least the display region 11. The insulating layer 237 may be provided in not only the display region 11 but also the connection portion 140 and the circuit portion 164. The insulating layer 237 may be provided to extend to the end portion of the display device 10A.

The common electrode 115 is one continuous film shared by the light-emitting element 16 and the light-emitting element 14. The common electrode 115 shared by the light-emitting elements is electrically connected to a conductive layer 123 provided in the connection portion 140. As the conductive layer 123, a conductive layer formed using the same material in the same step as the pixel electrode 111OP and the pixel electrode 111IR is preferably used.

In the display device of one embodiment of the present invention, a conductive film that transmits, for example, visible light and infrared light is used for the electrode through which light is extracted, which is either the pixel electrode or the common electrode. A conductive film reflecting, for example, visible light and infrared light is preferably used for the electrode through which light is not extracted.

A conductive film that transmits, for example, visible light and infrared light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element that belongs to Group 1 or Group 2 of the periodic table and that is not listed above as an example (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element preferably includes, for example, an electrode having properties of transmitting and reflecting visible light and infrared light (a transflective electrode). The other of the pair of electrodes of the light-emitting element preferably includes an electrode having a reflective property with respect to visible light and infrared light (a reflective electrode), for example. When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a transmittance of visible light and infrared light of 40% or higher is preferably used as the transparent electrode of the light-emitting element. The reflectance of visible light and infrared light of the transflective electrode is higher than or equal to 10% and lower than or equal to 95% or, preferably higher than or equal to 30% and lower than or equal to 80%. The reflectance of visible light and infrared light of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The EL layer 113OP and the EL layer 113IR are each provided to have an island shape. FIG. 20 illustrates an example in which an end portion of the EL layer 113OP and an end portion of the EL layer 113IR that are adjacent to each other overlap with each other. When island-shaped EL layers are formed using a fine metal mask, end portions of the EL layers adjacent to each other may overlap with each other as illustrated in FIG. 20; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display device. For example, it is possible that end portions of two adjacent EL layers 113OP overlap with each other and an end portion of the EL layer 113OP and an end portion of the EL layer 113IR, which are adjacent to each other, do not overlap with each other.

In this specification and the like, an island shape refers to a state where two or more layers formed using the same material in the same step are physically separated from each other. For example, an island-shaped EL layer refers to a state where the EL layer and its adjacent EL layer are physically separated from each other.

As described above, the EL layer 113OP and the EL layer 113IR each include at least a light-emitting layer. The light-emitting layer includes one or more kinds of light-emitting substances. Examples of the light-emitting substance include a fluorescent material, a phosphorescent material, a TADF material, and a quantum dot material, as described above.

The light-emitting layer may include one or more kinds of organic compounds (e.g., a host material or an assist material) in addition to the light-emitting substance (a guest material). As the one or more kinds of organic compounds, one or both of a substance with a good hole-transport property (a hole-transport material) and a substance with a good electron-transport property (an electron-transport material) can be used. As the one or more kinds of organic compounds, a substance with a bipolar property (a substance with a good electron-transport property and a good hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a good hole-injection property (a hole-injection layer), a layer including a hole-transport material (a hole-transport layer), a layer including a substance having a good electron-blocking property (an electron-blocking layer), a layer including a substance having a good electron-injection property (an electron-injection layer), a layer including an electron-transport material (an electron-transport layer), and a layer including a substance having a good hole-blocking property (a hole-blocking layer). The EL layer may further include one or both of a substance with a bipolar property and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may be referred to as a stack structure.

In the case where the light-emitting element 16 has a tandem structure in FIG. 20, the EL layer 113OP preferably includes a plurality of light-emitting units that emit red light, a plurality of light-emitting units that emit green light, or a plurality of light-emitting units that emit blue light. In the case where the light-emitting element 14 has a tandem structure, the EL layer 113IR preferably includes a plurality of light-emitting units that emit infrared light.

A protective layer 131 is provided over the light-emitting element 16 and the light-emitting element 14. The protective layer 131 and the substrate 42 are bonded to each other with an adhesive layer 142. The substrate 42 is provided with a light-blocking layer 117. For example, a solid sealing structure or a hollow sealing structure can be employed to seal the light-emitting elements. In FIG. 20, a solid sealing structure is employed, in which a space between the substrate 42 and the substrate 41 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting elements. Furthermore, the space may be filled with a resin other than the frame-shaped adhesive layer 142.

The protective layer 131 is provided at least in the display region 11, and preferably provided to cover the entire display region 11. The protective layer 131 is preferably provided to cover not only the display region 11 but also the connection portion 140 and the circuit portion 164. It is preferable that the protective layer 131 be provided to extend to the end portion of the display device 10A. Meanwhile, a connection portion 241 has a portion not provided with the protective layer 131 so that the FPC 172 and a conductive layer 166 are electrically connected to each other.

By providing the protective layer 131 over the light-emitting element 16 and the light-emitting element 14, the reliability of the light-emitting elements can be increased.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film including ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further include nitrogen.

When light emitted from the light-emitting element is extracted through the protective layer 131, the protective layer 131 preferably has a good transmitting property with respect to visible light and infrared light, for example. For example, ITO, IGZO, and aluminum oxide are preferable because they are inorganic materials having a good transmitting property with respect to visible light and infrared light.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layers.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 241 is provided in a region of the substrate 41 not overlapping with the substrate 42. In the connection portion 241, the conductive layer 165 is electrically connected to the FPC 172 through the conductive layer 166 and a connection layer 242. The conductive layer 165 has a single-layer structure of a conductive layer obtained by processing the same conductive film as the conductive layer 112b, for example. The conductive layer 166 has a single-layer structure of a conductive layer obtained by processing the same conductive film as the pixel electrode 111OP and the pixel electrode 111IR, for example. On the top surface of the connection portion 241, the conductive layer 166 is exposed. Thus, the connection portion 241 and the FPC 172 can be electrically connected to each other through the connection layer 242.

The display device 10A has a top-emission structure. Light emitted from the light-emitting element is emitted toward the substrate 42 side. For the substrate 42, a material having a high transmitting property with respect to visible light and infrared light is preferably used. The pixel electrode 111OP and the pixel electrode 111IR each contain a material that reflects visible light and infrared light, for example. The counter electrode (the common electrode 115) contains a material transmitting visible light and infrared light, for example.

The light-blocking layer 117 is preferably provided on the surface of the substrate 42 on the substrate 41 side. The light-blocking layer 117 can be provided over a region between adjacent light-emitting elements, in the connection portion 140, in the circuit portion 164, and the like.

FIG. 20 illustrates an example in which a filter 132IR is provided on the surface of the substrate 42 on the substrate 41 side to include a region overlapping with the light-receiving element 17. The filter 132IR can have a higher light transmittance in the infrared wavelength range than in the other wavelength ranges, for example. Specifically, the filter 132IR can have a higher light transmittance in the near-infrared wavelength range than in the other wavelength ranges, for example. Note that the filter 132IR may be provided on the surface on the substrate 41 side. In that case, the filter 132IR can be provided over the protective layer 131, for example.

Providing the filter 132IR in the display device 10A can inhibit visible light, ultraviolet light, or the like from entering the PD layer 213, for example. Thus, the display device 10A can perform image capturing with less noise and high sensitivity. Note that the filter 132IR is not necessarily provided in the display device 10A. In that case, the number of steps for manufacturing the display device 10A can be reduced.

The filter 132IR can be formed using one or more of a metal material, a resin material, a pigment, and a dye. The filter 132IR is formed in a desired position by a printing method, an ink-jet method, an etching method using a photolithography method, or the like.

A variety of optical members can be provided on the outer surface of the substrate 42 (the surface opposite to the substrate 41). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 42. For example, a glass layer or a silica layer (SiOₓ layer) is preferably provided as the surface protective layer to inhibit the surface contamination and damage. For the surface protective layer, DLC (diamond-like carbon), aluminum oxide (AlOₓ), a polyester-based material, a polycarbonate-based material, or the like may be used. The surface protective layer is preferably formed using a material having high transmittance of visible light and infrared light, for example. The surface protective layer is preferably formed using a material with high hardness.

For the substrate 42, a material that transmits light emitted from the light-emitting element 16 and light emitted from the light-emitting element 14 among the materials that can be used for the substrate 41 can be used. For the substrate 42, glass, quartz, ceramic, sapphire, or the like can be used, for example. When the substrate 41 and the substrate 42 are formed using a flexible material, the flexibility of the display device can be increased and a flexible display can be achieved. Furthermore, a polarizing plate may be used as at least one of the substrate 41 and the substrate 42.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. A two-component-mixture-type resin may be used. An adhesive sheet may be used, for example.

As the connection layer 242, an anisotropic conductive film (ACF), an anisotropic conductive paste (ACP), or the like can be used.

### [Display Device 10B]

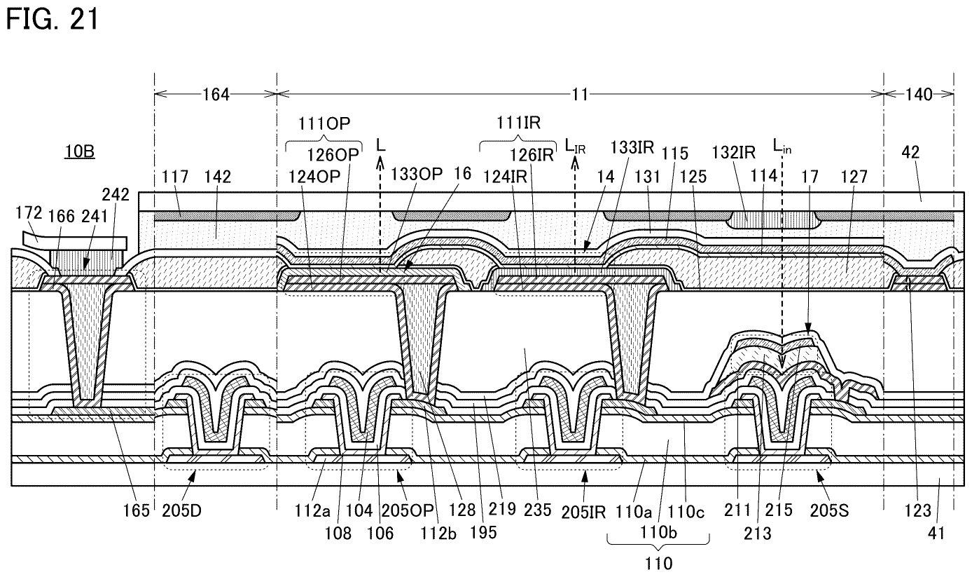

The display device 10B illustrated in FIG. 21 is an example of a display device in which the light-emitting element 16, the light-emitting element 14, and the like illustrated in FIG. 20 each have a metal maskless (MML) structure. Note that in the following description of display devices, the description of portions similar to those of the above-described display device may be omitted.

In this specification and the like, a device formed using a metal mask or an FMM (fine metal mask, high-resolution metal mask) may be referred to as a device having an MM (metal mask) structure. In this specification and the like, a device fabricated without using a metal mask or an FMM is sometimes referred to as a device having an MML structure.

An island-shaped light-emitting layer of the light-emitting element included in the display device having the MML structure is formed in the following manner: a light-emitting layer is formed on the entire surface, and then, the light-emitting layer is processed by a photolithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. For example, in the case where the display device includes a light-emitting element that emits blue light, a light-emitting element that emits green light, a light-emitting element that emits red light, and a light-emitting element that emits infrared light, four kinds of island-shaped light-emitting layers can be formed by repeating formation of a light-emitting layer and processing by photolithography four times.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. For processing by photolithography, an apparatus that is the same as or similar to an apparatus used for manufacturing a transistor can be used; thus, there is no need to introduce a special apparatus to manufacture the device having the MML structure. The MML structure can reduce the manufacturing cost as described above, and thus is suitable for mass production of devices.

A display device having the MML structure does not require a pseudo improvement in resolution by employing unique pixel arrangement such as PenTile arrangement, for example; thus, the display device can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

Moreover, providing a sacrificial layer (also referred to as a mask layer) over the light-emitting layer can reduce damage to the light-emitting layer in the manufacturing process of the display device, resulting in an increase in reliability of the light-emitting element.

In this specification and the like, a sacrificial layer refers to a layer that is positioned above at least a light-emitting layer (specifically, a layer processed into an island shape among layers included in an EL layer) and has a function of protecting the light-emitting layer in the manufacturing process.

Employing a film formation step using an area mask and a processing step using a resist mask enables a light-emitting element to be manufactured by a relatively easy process.

The stacked-layer structure from the substrate 41 to the insulating layer 235 and the stacked-layer structure from the protective layer 131 to the substrate 42 are similar to those in the display device 10A; therefore, description thereof is omitted.

In the display device 10B, the light-emitting element 16 and the light-emitting element 14 are provided over the insulating layer 235.

The light-emitting element 16 includes, as the pixel electrode 111OP, a conductive layer 124OP and a conductive layer 126OP over the conductive layer 124OP. The light-emitting element 14 includes, as the pixel electrode 111IR, a conductive layer 124IR and a conductive layer 126IR over the conductive layer 124IR.

The light-emitting element 16 includes a layer 133OP over the conductive layer 126OP, a common layer 114 over the layer 133OP, and the common electrode 115 over the common layer 114. The light-emitting element 14 includes a layer 133IR over the conductive layer 126IR, the common layer 114 over the layer 133IR, and the common electrode 115 over the common layer 114.

Like the EL layer 113OP included in the display device 10A, the layer 133OP includes a light-emitting layer that emits the light L that is visible light. Like the EL layer 113IR included in the display device 10A, the layer 133IR includes a light-emitting layer that emits the light L_{IR} that can be infrared light, for example.

In the light-emitting element 16, the layer 133OP and the common layer 114 can be collectively referred to as an EL layer. In the light-emitting element 14, the layer 133IR and the common layer 114 can be collectively referred to as an EL layer.

In this specification and the like, in the EL layers included in the light-emitting elements, the island-shaped layer provided in each light-emitting element is referred to as the layer 133, and the layer shared by the light-emitting elements is referred to as the common layer 114. Note that in this specification and the like, only the layer 133OP and the layer 133IR are sometimes referred to as island-shaped EL layers, EL layers formed in an island shape, or the like, in which case the common layer 114 is not included in the EL layer.

The layer 133OP and the layer 133IR are apart from each other. When the EL layer is provided to have an island shape for each light-emitting element, a leakage current between adjacent light-emitting elements can be inhibited. This can prevent crosstalk-induced unintended light emission, so that the display device can achieve extremely high contrast.

The conductive layer 124OP is electrically connected to the conductive layer 112b included in the transistor 205OP through the opening portion provided in the insulating layer 106, the insulating layer 195, the insulating layer 219, and the insulating layer 235. Similarly, the conductive layer 124IR is electrically connected to the conductive layer 112b included in the transistor 205IR.

The conductive layer 124OP and the conductive layer 124IR are formed to cover the opening portions provided in the insulating layer 235. A layer 128 is embedded in each of the depressed portions of the conductive layer 124OP and the conductive layer 124IR.

The layer 128 has a function of filling the depressed portions of the conductive layer 124OP the conductive layer 124IR. The conductive layer 126OP electrically connected to the conductive layer 124OP is provided over the conductive layer 124OP and the layer 128. The conductive layer 126IR electrically connected to the conductive layer 124IR is provided over the conductive layer 124IR and the layer 128. The conductive layer 124OP, the conductive layer 126OP, the conductive layer 124IR, and the conductive layer 126IR are preferably conductive layers functioning as reflective electrodes.

Here, the layer 133OP and the layer 133IR are formed through processing by a photolithography method. Thus, in the case where the layer 128 is not used and the conductive layer 126OP and the conductive layer 126IR are not provided, films to be the layer 133OP and the layer 133IR are formed also in the depressed portions of the conductive layer 124OP and the conductive layer 124IR, respectively. At this time, the film positioned in the depressed portions is not etched and a residue might be accumulated. For this reason, the formation surfaces of the layer 133OP and the layer 133IR are preferably planarized with the layer 128, the conductive layer 126OP, and the conductive layer 126IR.

A portion where the layer 128 is provided is covered with the insulating layer 125 and the insulating layer 127 so as to be a non-light-emitting region in this embodiment; however, regions overlapping with the depressed portions of the conductive layer 124OP and the conductive layer 124IR can also be used as light-emitting regions by not being covered with the insulating layer 125 and the insulating layer 127, increasing the areas of the light-emitting regions.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although the top surface of the layer 128 includes a flat portion in the example illustrated in FIG. 21, the shape of the layer 128 is not particularly limited. The top surface of the layer 128 may include at least one of a convex surface, a concave surface, and a flat surface.

The level of the top surface of the layer 128 and the levels of the top surfaces of the conductive layer 124OP and the conductive layer 124IR may be the same or substantially the same, or may be different from each other. For example, the level of the top surface of the layer 128 may be either lower or higher than the levels of the top surfaces of the conductive layer 124OP and the conductive layer 124IR.

An end portion of the conductive layer 126OP may be aligned with an end portion of the conductive layer 124OP or may cover the side surface of the end portion of the conductive layer 124OP. Similarly, an end portion of the conductive layer 126IR may be aligned with an end portion of the conductive layer 124IR or may cover the side surface of the end portion of the conductive layer 124IR. The end portions of the conductive layer 124OP, the conductive layer 126OP, the conductive layer 124IR, and the conductive layer 126IR each preferably have a tapered shape. Specifically, the end portions of the conductive layer 124OP, the conductive layer 126OP, the conductive layer 124IR, and the conductive layer 126IR each preferably have a tapered shape with a taper angle greater than 0° and less than 90°. In the case where the end portion of the pixel electrode 111OP has a tapered shape, the layer 133OP provided along a side surface of the pixel electrode 111OP has an inclined portion. Similarly, in the case where the end portion of the pixel electrode 111IR has a tapered shape, the layer 133IR provided along a side surface of the pixel electrode 111IR has an inclined portion. When the side surface of the pixel electrode has a tapered shape, coverage with the EL layer provided along the side surface of the pixel electrode can be improved.

The top surface and the side surface of the conductive layer 126OP are covered with the layer 133OP. Similarly, the top surface and the side surface of the conductive layer 126OP are covered with the layer 133IR. Thus, the entire region where the conductive layer 126OP is provided can be used as the light-emitting region of the light-emitting element 16. The entire region where the conductive layer 126IR is provided can be used as the light-emitting region of the light-emitting element 14. As a result, the area of the light-emitting region can be increased and the power consumption of the display device of one embodiment of the present invention can be reduced.

A side surface and part of the top surface of each of the layer 133OP and the layer 133IR are covered with an insulating layer 125 and an insulating layer 127. The common layer 114 is provided over the layer 133OP and the layer 133IR, the insulating layer 125, and the insulating layer 127, and the common electrode 115 is provided over the common layer 114. The common layer 114 and the common electrode 115 are each a continuous film provided to be shared by a plurality of light-emitting elements.

In FIG. 21, the insulating layer 237 illustrated in FIG. 20 is not provided between the conductive layer 126OP and the layer 133OP and between the conductive layer 126IR and the layer 133IR, for example. That is, an insulating layer (also referred to as a partition wall, a bank, a spacer, or the like) that is in contact with the pixel electrode and that covers an upper end portion of the pixel electrode is not provided in the display device 10B. Thus, the distance between adjacent light-emitting elements can be extremely shortened. Accordingly, the display device can have high definition and high resolution. In addition, a mask for forming the insulating layer is not needed, which leads to a reduction in manufacturing cost of the display device.

As described above, the layer 133OP and the layer 133IR each include the light-emitting layer. The layer 133OP and the layer 133IR each preferably include a light-emitting layer and a carrier-transport layer (an electron-transport layer or a hole-transport layer) over the light-emitting layer. Alternatively, the layer 133OP and the layer 133IR each preferably include a light-emitting layer and a carrier-blocking layer (a hole-blocking layer or an electron-blocking layer) over the light-emitting layer. Alternatively, the layer 133OP and the layer 133IR each preferably include a light-emitting layer, a carrier-blocking layer over the light-emitting layer, and a carrier-transport layer over the carrier-blocking layer. Since surfaces of the layer 133OP and the layer 133IR are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting elements can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer.

Note that in the case where the layer 133OP and the layer 133IR each include a light-emitting layer, a carrier-transport layer over the light-emitting layer, and a carrier-injection layer (a hole-injection layer or an electron-injection layer) over the carrier-transport layer, the common layer 114 is not necessarily provided. In that case, the common electrode 115 is provided in contact with the layer 133OP, the layer 133IR, the insulating layer 127, the insulating layer 125, and the like.

The side surfaces of the layer 133OP and the layer 133IR are each covered with the insulating layer 125. The insulating layer 127 covers the side surfaces of the layer 133OP and the layer 133IR with the insulating layer 125 therebetween.

Since the side surface (and part of the top surface) of each of the layer 133OP and the layer 133IR are covered with at least one of the insulating layer 125 and the insulating layer 127, the common layer 114 (or the common electrode 115) can be inhibited from being in contact with the pixel electrode and the side surfaces of the layer 133OP and the layer 133IR. Thus, a short circuit in the light-emitting element can be inhibited, leading to an increase in the reliability of the light-emitting element.

The insulating layer 125 is preferably in contact with the side surfaces of the layer 133OP and the layer 133IR. The insulating layer 125 in contact with the layer 133OP and the layer 133IR can prevent film separation of the layer 133OP and the layer 133IR, whereby the reliability of the light-emitting elements can be increased.

The insulating layer 127 is provided over the insulating layer 125 to fill a depressed portion of the insulating layer 125. The insulating layer 127 preferably covers at least part of a side surface of the insulating layer 125.

The insulating layer 125 and the insulating layer 127 can fill a gap between adjacent island-shaped layers, whereby unevenness with a large level difference on the formation surface of the layers (e.g., the carrier-injection layer and the common electrode) provided over the island-shaped layers can be reduced and the formation surface can be flatter. Consequently, coverage with the carrier-injection layer, the common electrode, and the like can be improved.

The common layer 114 and the common electrode 115 are provided over the layer 133OP and the layer 133IR, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, connection defects caused by step disconnection can be inhibited. In addition, an increase in electrical resistance, which is caused by local thinning of the common electrode 115 due to the step, can be inhibited.

The top surface of the insulating layer 127 preferably has a shape with higher planarity. The top surface of the insulating layer 127 may include at least one of a flat surface, a convex surface, and a concave surface. For example, the top surface of the insulating layer 127 preferably has a convex shape with a large radius of curvature.

The insulating layer 125 can include an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer, entry of impurities (typically, at least one of water and oxygen) that would be diffused to the light-emitting elements from the outside can be inhibited. With this structure, a highly reliable light-emitting element and a highly reliable display device can be provided.

The insulating layer 125 preferably has a low impurity concentration. In that case, degradation of the EL layer due to entry of impurities into the EL layer from the insulating layer 125 can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of reducing unevenness with a large level difference on the insulating layer 125, which is formed between the adjacent light-emitting elements. In other words, the insulating layer 127 has an effect of improving the planarity of the formation surface of the common electrode 115.

As the insulating layer 127, an insulating layer including an organic material can be suitably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymers in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, any of precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the organic photosensitive resin, either a positive-type material or a negative-type material may be used.

### [Display Device 10C]

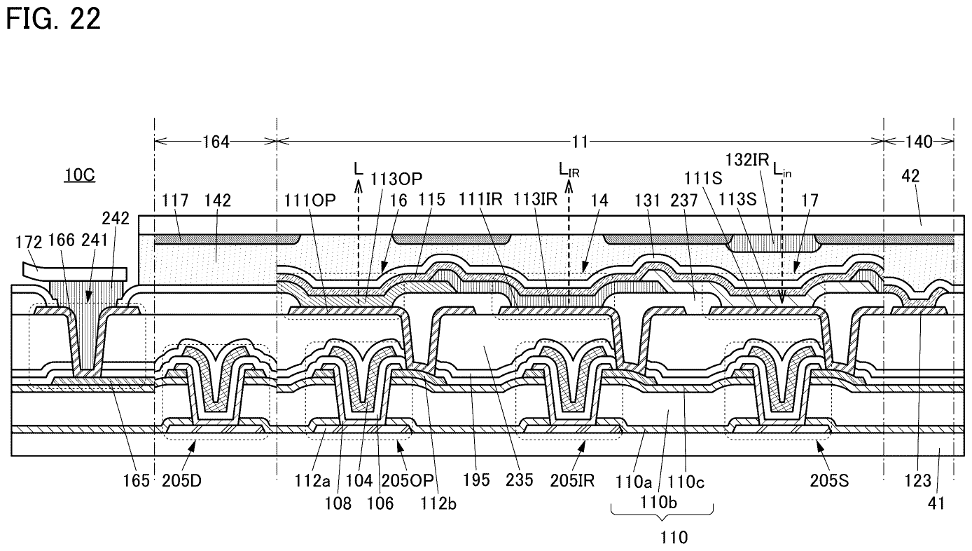

FIG. 22 is a cross-sectional view illustrating a structure example of the display device 10C. The display device 10C is different from the display device 10A mainly in that the light-receiving element 17 is provided over the insulating layer 235.

The light-receiving element 17 includes a pixel electrode 111S over the insulating layer 235, a PD layer 113S over the pixel electrode 111S, and the common electrode 115 over the PD layer 113S. Light Lᵢₙ from outside the display device 10D enters the PD layer 113S.

The pixel electrode 111S is electrically connected to the conductive layer 112b included in a transistor 205S through an opening portion provided in the insulating layer 106, the insulating layer 195, the insulating layer 219, and the insulating layer 235.

An end portion of the pixel electrode 111S is covered with the insulating layer 237.

The common electrode 115 is one continuous film shared by the light-emitting element 16, the light-emitting element 14, and the light-receiving element 17. The common electrode 115 shared by the light-emitting elements and the light-receiving element is electrically connected to the conductive layer 123 provided in the connection portion 140.

The PD layer 113S includes at least an active layer. The active layer contains a semiconductor as described above. The active layer included in the PD layer 113S can contain an organic semiconductor, for example. In that case, the light-emitting layer and the active layer can be formed by the same method (e.g., a vacuum evaporation method) and thus the same manufacturing apparatus can be used, which is preferable.

In addition to the active layer, the PD layer 113S may further include a layer including a substance having a good hole-transport property, a substance having a good electron-transport property, a substance having a bipolar property, or the like. Without limitation to the above, the functional layer 113S may further include a layer including a substance having a good hole-injection property, a hole-blocking material, a substance having a good electron-injection property, an electron-blocking material, or the like. The PD layer 113S can be formed using a material that can be used for the light-emitting element, for example.

Either a low molecular compound or a high molecular compound can be used in the light-receiving element 17, and an inorganic compound may also be included. Each layer included in the light-receiving element 17 can be formed by any of the following methods: an evaporation method (including a vacuum evaporation method), a transfer method, a printing method, an inkjet method, a coating method, and the like.

### [Display Device 10D]

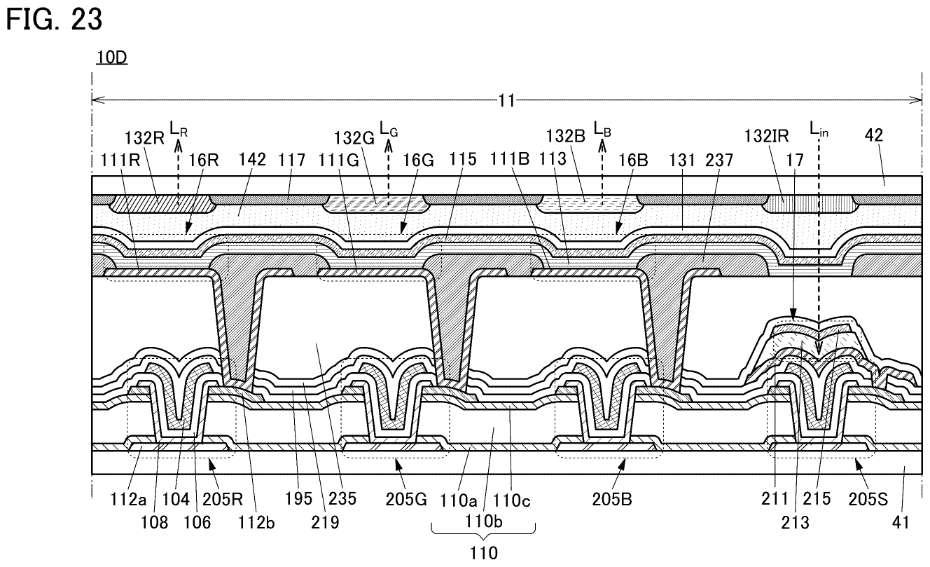

FIG. 23 is a cross-sectional view illustrating a structure example of the display device 10D and illustrates a structure example of the display region 11. In FIG. 23, the light-emitting element 16R, the light-emitting element 16G, and the light-emitting element 16B are illustrated as the light-emitting element 16. Also in FIG. 23, a transistor 205R, a transistor 205G, a transistor 205B, and a transistor 205S are illustrated as the transistor 205. The EL layer 113 included in the display device 10D is provided to be shared by the light-emitting element 16R, the light-emitting element 16G, and the light-emitting element 16B. The structure illustrated in FIG. 23 can be combined with the structure of the region including the FPC 172, the circuit portion 164, the stacked-layer structure from the substrate 41 to the insulating layer 235 in the display region 11, the connection portion 140, and the end portion, which is illustrated in FIG. 20.

The display device 10D includes a filter 132R including a region overlapping with the light-emitting element 16R, a filter 132G including a region overlapping with the light-emitting element 16G, and a filter 132B including a region overlapping with the light-emitting element 16B, in addition to the filter 132IR including a region overlapping with the light-receiving element 17. FIG. 23 illustrates an example in which the filter 132R, the filter 132G, the filter 132B, and the filter 132IR are provided on the surface of the substrate 42 on the substrate 41 side. Note that the filter 132R, the filter 132G, the filter 132B, and the filter 132IR may be provided on the surface on the substrate 41 side. In that case, the filter 132R, the filter 132G, the filter 132B, and the filter 132IR can be provided over the protective layer 131, for example.

The filter 132R can have a higher light transmittance in the red wavelength range than in the other wavelength ranges, for example. The filter 132G can have a higher light transmittance in the green wavelength range than in the other wavelength ranges, for example. The filter 132B can have a higher light transmittance in the blue wavelength range than in the other wavelength ranges, for example.

The filter 132R, the filter 132G, and the filter 132B can be formed using one or more of a metal material, a resin material, a pigment, and a dye. The filter 132R, the filter 132G, and the filter 132B are formed in desired positions by a printing method, an ink-jet method, an etching method using a photolithography method, or the like.

The light-emitting element 16R includes a pixel electrode 111R, the EL layer 113 over the pixel electrode 111R, and the common electrode 115 over the EL layer 113. The pixel electrode 111R is electrically connected to the conductive layer 112b included in the transistor 205R. Light emitted from the light-emitting element 16R is extracted as, for example, red light L_{R} to the outside of the display device 10D through the filter 132R.

The light-emitting element 16G includes a pixel electrode 111G, the EL layer 113 over the pixel electrode 111G, and the common electrode 115 over the EL layer 113. The pixel electrode 111G is electrically connected to the conductive layer 112b included in the transistor 205G. Light emitted from the light-emitting element 16G is extracted as, for example, green light L_{G} to the outside of the display device 10D through the filter 132G.

The light-emitting element 16B includes a pixel electrode 111B, the EL layer 113 over the pixel electrode 111B, and the common electrode 115 over the EL layer 113. The pixel electrode 111B is electrically connected to the conductive layer 112b included in the transistor 205B. Light emitted from the light-emitting element 16B is extracted as, for example, blue light L_{B} to the outside of the display device 10D through the filter 132B.

The EL layer 113 and the common electrode 115 are shared by the light-emitting element 16R, the light-emitting element 16G, and the light-emitting element 16B. The number of manufacturing steps can be smaller in the structure where the EL layer 113 is provided to be shared by the subpixels of different colors than in the structure where the subpixels of different colors are provided with different EL layers.

The light-emitting element 16R, the light-emitting element 16G, and the light-emitting element 16B illustrated in FIG. 23 emit white light, for example. When white light emitted from the light-emitting element 16R, the light-emitting element 16G, and the light-emitting element 16B passes through the filter 132R, the filter 132G, and the filter 132B, light of desired colors can be obtained.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are provided in this order; and a three-unit tandem structure in which a light-emitting unit that emits blue light, a light-emitting unit that emits yellow, yellow-green, or green light and red light, and a light-emitting unit that emits blue light are provided in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Note that in the case where the light-emitting element emitting white light has a microcavity structure, light with a specific wavelength such as red, green, or blue is sometimes intensified to be emitted.

Alternatively, the light-emitting element 16R, the light-emitting element 16G, and the light-emitting element 16B illustrated in FIG. 23 emit blue light, for example. In this case, the EL layer 113 includes one or more light-emitting layers that emit blue light. In the subpixel 19B that emits blue light, blue light emitted from the light-emitting element 16B can be extracted. In each of the subpixel 19R that emits red light and the subpixel 19G that emits green light, by providing a color conversion layer between the light-emitting element 16R or the light-emitting element 16G and the substrate 42, blue light emitted from the light-emitting element 16R or the light-emitting element 16G can be converted into light with a longer wavelength, and red light or green light can be extracted. Furthermore, it is preferable that over the light-emitting element 16R, the filter 132R be provided between the color conversion layer and the substrate 42 and over the light-emitting element 16G, the filter 132G be provided between the color conversion layer and the substrate 42. In some cases, part of light emitted from the light-emitting element is transmitted through the color conversion layer without being converted. When light transmitted through the color conversion layer is extracted through the coloring layer, light other than light of the intended color can be absorbed by the coloring layer, and the color purity of light exhibited by a subpixel can be improved.

In the display device 10D, for example, a material absorbing visible light and near-infrared light is preferably used for the insulating layer 237. When the insulating layer 237 absorbs visible light, light emitted from the light-emitting element 16 can be inhibited from entering the PD layer 213. In the case where the insulating layer 237 absorbs near-infrared light, near-infrared light other than the near-infrared light reflected by an object can be inhibited from entering the PD layer 213 in the display device 10D functioning as, for example, a touch sensor or a noncontact sensor. In this manner, the display device 10D can perform image capturing with less noise and high sensitivity. Thus, the display device 10D can detect contact of an object with or proximity of the object to the display region 11 with high sensitivity, for example. Accordingly, the display device 10D can function as, for example, a highly sensitive touch sensor or a highly sensitive noncontact sensor.

In FIG. 23, for example, the use of a material absorbing visible light and near-infrared light for the insulating layer 237 is shown with a hatching pattern of the insulating layer 237. Examples of the material absorbing visible light and near-infrared light include a resin material having a light-absorbing property, such as polyimide.

### [Display Device 10E]

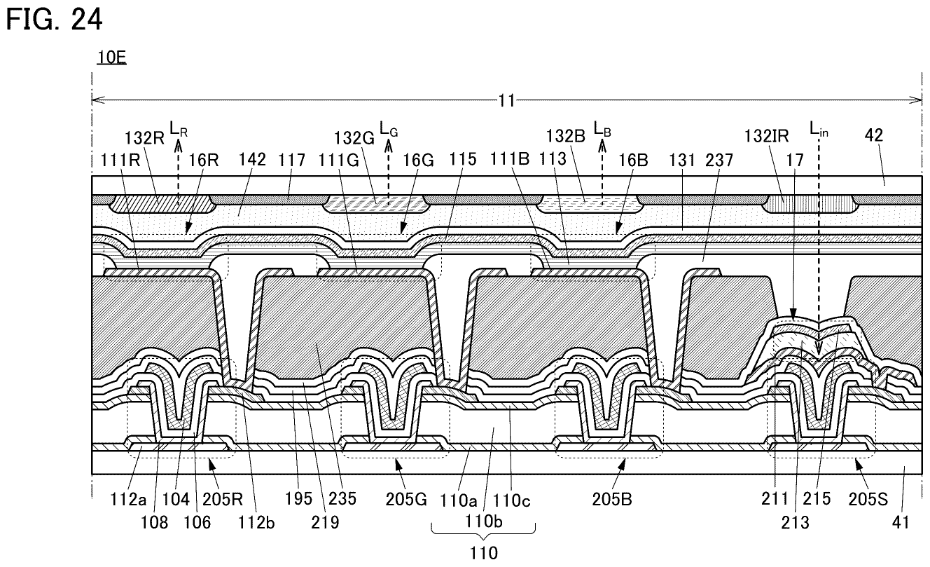

FIG. 24 is a cross-sectional view illustrating a structure example of the display device 10E and illustrates a structure example of the display region 11. The display device 10E is different from the display device 10D mainly in that an opening portion that reaches the insulating layer 219 and includes a region overlapping with the PD layer 213 is provided in the insulating layer 235, and the insulating layer 237 is provided to fill the opening portion.

In the display device 10E, a material that transmits light, e.g., near-infrared light, which enters the PD layer 213 as the light Lᵢₙ is used for the insulating layer 237. By contrast, for the insulating layer 235, a material absorbing visible light and near-infrared light is preferably used, for example. In this manner, the display device 10E can capture images with less noise and high sensitivity, and for example, can detect contact of an object with or proximity of the object to the display region 11 with high sensitivity. Accordingly, the display device 10E can function as, for example, a highly sensitive touch sensor or a highly sensitive noncontact sensor. In FIG. 24, for example, the use of a material absorbing visible light and near-infrared light for the insulating layer 235 is shown with a hatching pattern of the insulating layer 235.

The filter 132R, the filter 132G, and the filter 132B included in the display device 10D and the display device 10E may be provided in the display device 10A, the display device 10B, and the display device 10C. In that case, one of the filter 132R, the filter 132G, and the filter 132B is provided in a region overlapping with the light-emitting element 16 illustrated in FIG. 20 to FIG. 22. For example, in the case where the EL layer 113OP illustrated in FIG. 20 to FIG. 22 includes a light-emitting layer emitting red light, the filter 132R is provided in a region overlapping with the light-emitting element 16 illustrated in FIG. 20 to FIG. 22. In the case where the EL layer 113OP illustrated in FIG. 20 to FIG. 22 includes a light-emitting layer emitting green light, the filter 132G is provided in a region overlapping with the light-emitting element 16 illustrated in FIG. 20 to FIG. 22. In the case where the EL layer 113OP illustrated in FIG. 20 to FIG. 22 includes a light-emitting layer emitting blue light, the filter 132B is provided in a region overlapping with the light-emitting element 16 illustrated in FIG. 20 to FIG. 22. The filter 132IR may be provided in a region overlapping with the light-emitting element 14.

In the case where a filter is provided to include a region overlapping with the light-emitting element, the color purity of light extracted to the outside of the display device can be improved as compared with that in the case where a filter is not provided. Thus, a high-quality image can be displayed on the display region 11. By contrast, in the case where a filter is not provided, an image can be displayed on the display region 11 with high luminance as compared with the case where a filter is provided.

The structure in which an opening portion that reaches the insulating layer 219 and includes a region overlapping with the PD layer 213 is provided in the insulating layer 235 and the insulating layer 237 is provided to fill the opening portion can also be applied to the display device 10A. In that case, a material absorbing visible light and near-infrared light can be used for the insulating layer 235, for example.

The display device 10A, the display device 10B, and the display device 10C can be used as the display device 10 illustrated in FIG. 1A, for example. The display device 10D and the display device 10E can be used as the display device 10 illustrated in FIG. 2, for example.

This embodiment can be combined with the other embodiments as appropriate.

### EMBODIMENT 2

In this embodiment, electronic devices of one embodiment of the present invention are described.

Electronic devices of this embodiment each include the display apparatus of one embodiment of the present invention in a display region. The display apparatus of one embodiment of the present invention can be easily increased in definition and resolution and can achieve high display quality. Thus, the display apparatus of one embodiment of the present invention can be used for a display region of a variety of electronic devices. As described in the above embodiment, the display device of one embodiment of the present invention can function as, for example, a highly sensitive touch sensor or a highly sensitive noncontact sensor.

Examples of the electronic devices include electronic devices with a relatively large screen, such as a television device, a desktop or laptop personal computer, a monitor of a computer or the like, digital signage, and a large game machine such as a pachinko machine; a digital camera; a digital video camera; a digital photo frame; a mobile phone; a portable game machine; a portable information terminal; and an audio reproducing device.

In particular, the display apparatus of one embodiment of the present invention can have high resolution, and thus can be suitably used for an electronic device having a relatively small display region. Examples of such an electronic device include a watch-type or a bracelet-type information terminal (wearable device), and a wearable device that can be worn on a head, such as a device for VR like a head-mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display region, a touch sensor function, a function of displaying a calendar, date, time, and the like, a function of executing a variety of software (programs), a wireless communication function, and a function of reading out a program or data stored in a recording medium.

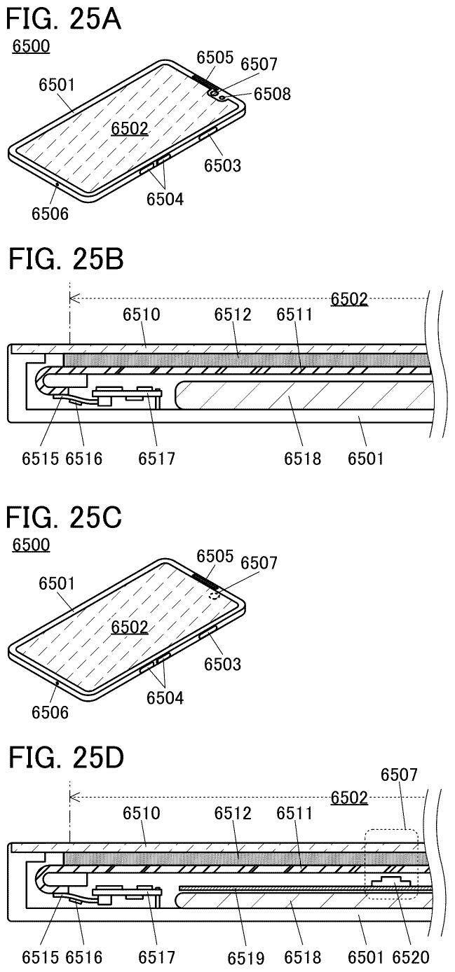

An electronic device 6500 illustrated in FIG. 25A is a portable information terminal that can be used as a smartphone.

The electronic device 6500 includes a housing 6501, a display region 6502, a power button 6503, buttons 6504, a speaker 6505, a microphone 6506, a camera 6507, a light source 6508, and the like. The display region 6502 has a touch sensor function.

The display device of one embodiment of the present invention can be used for the display region 6502. Thus, the electronic device 6500 can have a function of a highly sensitive touch sensor or a highly sensitive noncontact sensor, for example.

FIG. 25B is a schematic cross-sectional view including an end portion of the housing 6501 on the microphone 6506 side.

A protection member 6510 having a light-transmitting property is provided on a display surface side of the housing 6501, and a display apparatus 6511, an optical member 6512, a printed circuit board 6517, a battery 6518, and the like are provided in a space surrounded by the housing 6501 and the protection member 6510.

The display apparatus 6511 and the optical member 6512 are fixed to the protection member 6510 with an adhesive layer (not illustrated).

Part of the display apparatus 6511 is folded back in a region outside the display region 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display apparatus 6511. Thus, an extremely lightweight electronic device can be achieved. Since the display apparatus 6511 is extremely thin, the battery 6518 with high capacity can be mounted while an increase in the thickness of the electronic device is suppressed. Moreover, part of the display apparatus 6511 is folded back so that a connection portion with the FPC 6515 is provided on the back side of a pixel portion, whereby an electronic device with a narrow bezel can be achieved.

In the electronic device 6500 illustrated in FIG. 25A and FIG. 25B, the camera 6507 is provided in a notch provided in the display region 6502, but the present invention is not limited thereto. As illustrated in FIG. 25C and FIG. 25D, the camera 6507 may be provided to overlap with the display region 6502. Note that FIG. 25C corresponds to FIG. 25A, FIG. 25D corresponds to FIG. 25B, and the description of FIG. 25A and FIG. 25B can be referred to for the structures of FIG. 25C and FIG. 25D with the same reference numerals.

As illustrated in FIG. 25D, a housing 6519 may be provided over the battery 6518, and a sensor portion 6520 included in the camera 6507 may be provided over the housing 6519. As the sensor portion 6520, a package including an image sensor chip or a sensor module can be used, for example. By providing the camera 6507, the user can take an image data in a state where the user sees on the display region 6502. In addition, personal authentication can be performed by taking an image of the face of the user.

Moreover, a structure may be employed where the number of pixels in a region overlapping with the sensor portion 6520 in the display region 6502 is reduced. Such a structure can increase the intensity of light incident on the sensor portion 6520 and improve the sensitivity of sensing.

The sensor portion 6520 is preferably provided to be fixed to the housing 6519. In this case, the position of the light-receiving portion of the sensor portion 6520 is fixed, enabling more accurate sensing. Note that the housing 6519 may be fixed to the housing 6501, or the housing 6519 may be unified with the housing 6501.

With the structure illustrated in FIG. 25C and FIG. 25D, the camera 6507 can be provided in the electronic device 6500, without providing a notch on the display region 6502.

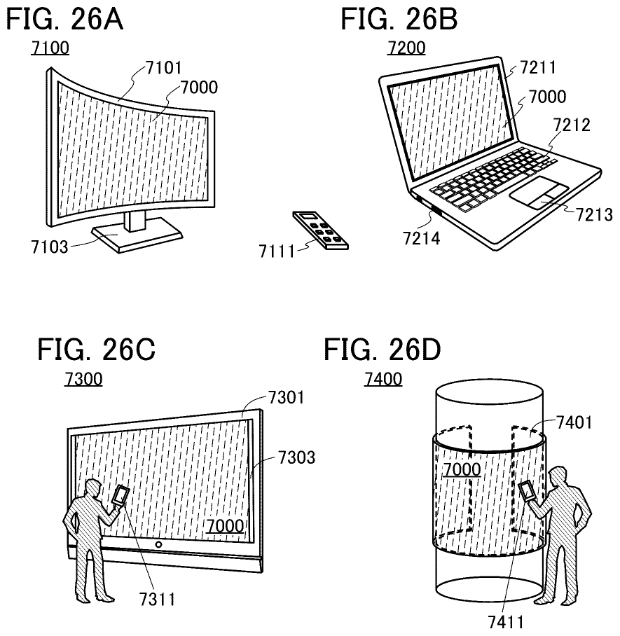

FIG. 26A illustrates an example of a television device. In a television device 7100, a display region 7000 is incorporated in a housing 7101. Here, the housing 7101 is supported by a stand 7103.

The display apparatus of one embodiment of the present invention can be used for the display region 7000. Thus, the television device 7100 can have a function of a highly sensitive touch sensor or a highly sensitive noncontact sensor, for example.

Operation of the television device 7100 illustrated in FIG. 26A can be performed with an operation switch provided in the housing 7101 and a separate remote control 7111. Alternatively, the display region 7000 may be provided with a touch sensor, and the television device 7100 may be operated by touch on the display region 7000 with a finger or the like. The remote control 7111 may include a display region for displaying information output from the remote control 7111. With operation keys or a touch sensor provided in the remote control 7111, channels and volume can be controlled and videos displayed on the display region 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 26B illustrates an example of a laptop personal computer. A laptop personal computer 7200 includes a housing 7211, a keyboard 7212, a pointing device 7213, an external connection port 7214, and the like. In the housing 7211, the display region 7000 is incorporated.

The display apparatus of one embodiment of the present invention can be used for the display region 7000. Thus, the laptop personal computer 7200 can have a function of a highly sensitive touch sensor or a highly sensitive noncontact sensor, for example.

FIG. 26C and FIG. 26D illustrate examples of digital signage.

Digital signage 7300 illustrated in FIG. 26C includes a housing 7301, the display region 7000, a speaker 7303, and the like. The digital signage 7300 can also include an LED lamp, an operation key (including a power switch or an operation switch), a connection terminal, a variety of sensors, a microphone, and the like.

FIG. 26D is digital signage 7400 attached to a cylindrical pillar 7401. The digital signage 7400 includes the display region 7000 provided along a curved surface of the pillar 7401.

The display device of one embodiment of the present invention can be used for the display region 7000 illustrated in each of FIG. 26C and FIG. 26D. Thus, the digital signage 7300 and the digital signage 7400 can have a function of a highly sensitive touch sensor or a highly sensitive noncontact sensor, for example.

A larger area of the display region 7000 can increase the amount of information that can be provided at a time. The larger display region 7000 attracts more attention, so that the effectiveness of the advertisement can be increased, for example.

The digital signage 7300 and the digital signage 7400 each preferably have a function of a highly sensitive touch sensor or a highly sensitive noncontact sensor, for example, in which case user's intuitive operation is possible in addition to display of an image or a moving image on the display region 7000. Moreover, in the case of an application for providing information such as route information or traffic information, usability can be enhanced by intuitive operation.

As illustrated in FIG. 26C and FIG. 26D, it is preferable that the digital signage 7300 or the digital signage 7400 can work with an information terminal 7311 or an information terminal 7411 such as a smartphone a user has through wireless communication. For example, information of an advertisement displayed on the display region 7000 can be displayed on a screen of the information terminal 7311 or the information terminal 7411. By operation of the information terminal 7311 or the information terminal 7411, display on the display region 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

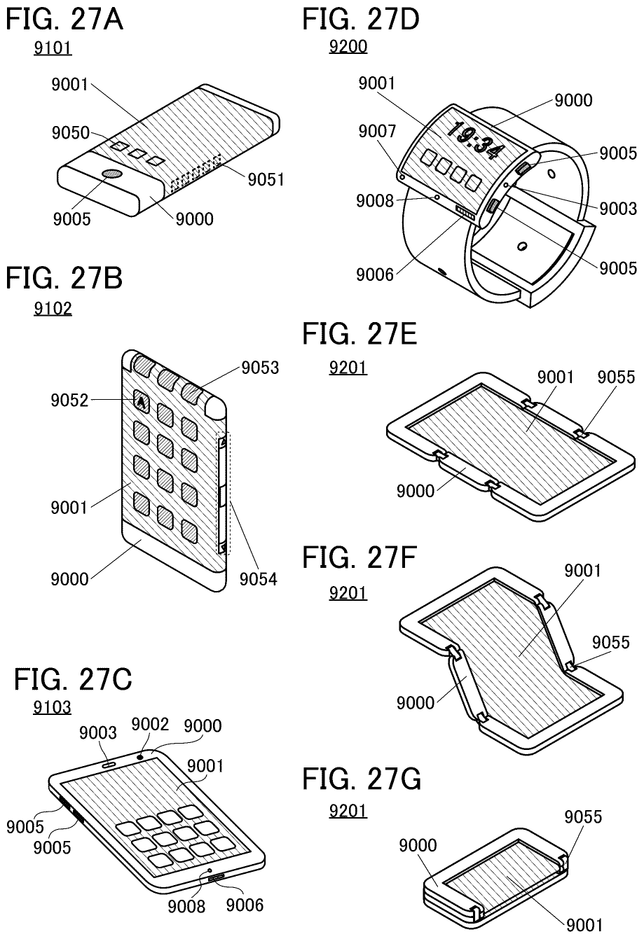

Electronic devices illustrated in FIG. 27A to FIG. 27G include a housing 9000, a display region 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays), a microphone 9008, and the like.

The display device of one embodiment of the present invention can be used for the display region 9001. Thus, the electronic devices illustrated in FIG. 27A to FIG. 27G can have a function of a highly sensitive touch sensor or a highly sensitive noncontact sensor, for example.

The details of the electronic devices illustrated in FIG. 27A to FIG. 27G are described below.

FIG. 27A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 27A illustrates an example where three icons 9050 are displayed. Furthermore, information 9051 indicated by dashed rectangles can be displayed on another surface of the display region 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 27B is a perspective view illustrating a portable information terminal 9102. The portable information terminal 9102 has a function of displaying information on three or more surfaces of the display region 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 27C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display region 9001, the camera 9002, the microphone 9008, and the speaker 9003 on the front surface of the housing 9000; the operation keys 9005 as buttons for operation on the left side surface of the housing 9000; and the connection terminal 9006 on a bottom surface of the housing 9000.

FIG. 27D is a perspective view illustrating a watch-type portable information terminal 9200. For example, the portable information terminal 9200 can be used as a Smartwatch (registered trademark). The display surface of the display region 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 27E to FIG. 27G are perspective views each illustrating a foldable portable information terminal 9201. FIG. 27E is a perspective view of an opened state of the portable information terminal 9201, FIG. 27G is a perspective view of a folded state thereof, and FIG. 27F is a perspective view of a state in the middle of change from one of FIG. 27E and FIG. 27G to the other. The portable information terminal 9201 is highly portable in the folded state and is highly browsable in the opened state because of a seamless large display region. The display region 9001 of the portable information terminal 9201 is supported by three housings 9000 joined together by hinges 9055. The display region 9001 can be folded with a radius of curvature of greater than or equal to 0.1 mm and less than or equal to 150 mm, for example.

This embodiment can be combined with the other embodiments as appropriate.

### REFERENCE NUMERALS

10: display device, 10A: display device, 10B: display device, 10C: display device, 10D: display device, 10E: display device, 11: display region, 13: pixel, 14: light-emitting element, 15: pixel, 16: light-emitting element, 16B: light-emitting element, 16G: light-emitting element, 16R: light-emitting element, 17: light-receiving element, 19: subpixel, 19B: subpixel, 19G: subpixel, 19R: subpixel, 21: driver circuit, 22: driver circuit, 23: driver circuit, 24: driver circuit, 25: pixel circuit, 29: pixel circuit, 31: wiring, 31a: wiring, 31b: wiring, 31c: wiring, 32: wiring, 33: wiring, 33a: wiring, 33b: wiring, 33c: wiring, 33d: wiring, 34: wiring, 40: finger, 41: substrate, 42: substrate, 43: functional layer, 51: wiring, 52: wiring, 53: wiring, 54: wiring, 55: wiring, 56: wiring, 57: wiring, 58: wiring, 60: wiring, 61: wiring, 62: wiring, 100: transistor, 104: conductive layer, 106: insulating layer, 108: semiconductor layer, 108n: low-resistance region, 110: insulating layer, 110a: insulating layer, 110b: insulating layer, 110c: insulating layer, 111B: pixel electrode, 111G: pixel electrode, 111IR: pixel electrode, 111OP: pixel electrode, 111R: pixel electrode, 111S: pixel electrode, 112a: conductive layer, 112b: conductive layer, 113: EL layer, 113IR: EL layer, 113OP: EL layer, 113S: PD layer, 114: common layer, 115: common electrode, 117: light-blocking layer, 120: insulating layer, 120a: insulating layer, 120b: insulating layer, 123: conductive layer, 124IR: conductive layer, 124OP: conductive layer, 125: insulating layer, 126IR: conductive layer, 126OP: conductive layer, 127: insulating layer, 128: layer, 131: protective layer, 132B: filter, 132G: filter, 132IR: filter, 132R: filter, 133: layer, 133IR: layer, 133OP: layer, 140: connection portion, 141: opening portion, 142: adhesive layer, 143: opening portion, 147a: opening portion, 147b: opening portion, 150: capacitor, 164: circuit portion, 165: conductive layer, 166: conductive layer, 172: FPC, 173: IC, 195: insulating layer, 200: transistor, 202: conductive layer, 204: conductive layer, 205: transistor, 205B: transistor, 205D: transistor, 205G: transistor, 205IR: transistor, 205OP: transistor, 205R: transistor, 205S: transistor, 208: semiconductor layer, 208D: region, 208L: region, 211: conductive layer, 212a: conductive layer, 212b: conductive layer, 213: PD layer, 215: conductive layer, 219: insulating layer, 235: insulating layer, 237: insulating layer, 241: connection portion, 242: connection layer, 6500: electronic device, 6501: housing, 6502: display region, 6503: power supply button, 6504: button, 6505: speaker, 6506: microphone, 6507: camera, 6508: light source, 6510: protective member, 6511: display device, 6512: optical member, 6515: FPC, 6516: IC, 6517: printed circuit board, 6518: battery, 6519: housing, 6520: sensor portion, 7000: display region, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display region, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A method for driving a display device comprising a display region,
wherein a first pixel comprising a first light-emitting element, a second pixel comprising a second light-emitting element, and a first sensor pixel comprising a first light-receiving element are provided in the display region,
wherein the method comprises:
a first period in which first image data is written to the first pixel;
a second period in which second image data is written to the second pixel;
a third period in which the first light-emitting element and the second light-emitting element are brought into a light-emitting state; and
a fourth period in which the first light-emitting element and the second light-emitting element are brought into a non-light-emitting state, and
wherein light exposure is performed on the first light-receiving element in the fourth period.

2. The method for driving a display device, according to claim 1,
wherein the first sensor pixel comprises a transistor,
wherein the transistor comprises a semiconductor layer where a channel formation region is provided, and
wherein the channel formation region is provided along a side surface of an insulating layer.

3. The method for driving a display device, according to claim 1,
wherein the first pixel comprises a first transistor,
wherein the second pixel comprises a second transistor,
wherein the first transistor is in a conduction state in the first period and is in a non-conduction state in the second to the fourth periods,
wherein the second transistor is in a conduction state in the second period, and is in a non-conduction state in the first period, the third period, and the fourth period,
wherein the first transistor comprises a first semiconductor layer provided with a first channel formation region,
wherein the second transistor comprises a second semiconductor layer provided with a second channel formation region, and
wherein the first semiconductor layer and the second semiconductor layer each comprise a metal oxide.

4. The method for driving a display device, according to claim 3,
wherein the first channel formation region and the second channel formation region are each provided along a side surface of an insulating layer.

5. The method for driving a display device, according to claim 1,
wherein a third pixel comprising a third light-emitting element, a fourth pixel comprising a fourth light-emitting element, and a second sensor pixel comprising a second light-receiving element are provided in the display region,
wherein a fifth period in which third image data is written to the third pixel and a sixth period in which fourth image data is written to the fourth pixel are provided between the second period and the third period,
wherein the third light-emitting element and the fourth light-emitting element are brought into a light-emitting state in the third period,
wherein the third light-emitting element and the fourth light-emitting element are brought into a non-light-emitting state in the fourth period, and
wherein light exposure is performed on the second light-receiving element in the fourth period.

6. The method for driving a display device, according to claim 5,
wherein the first sensor pixel comprises a first transistor,
wherein the second sensor pixel comprises a second transistor,
wherein the first transistor comprises a first semiconductor layer provided with a first channel formation region,
wherein the second transistor comprises a second semiconductor layer provided with a second channel formation region, and
wherein the first channel formation region and the second channel formation region are each provided along a side surface of an insulating layer.

7. The method for driving a display device, according to claim 6,
wherein the first semiconductor layer and the second semiconductor layer each comprise a metal oxide.

8. A method for driving a display device comprising a display region,
wherein a first pixel comprising a first light-emitting element, a second pixel comprising a second light-emitting element, a third pixel comprising a third light-emitting element, a fourth pixel comprising a fourth light-emitting element, a first sensor pixel comprising a first light-receiving element, and a second sensor pixel comprising a second light-receiving element are provided in the display region,
wherein the method comprises:
a first period in which first image data is written to the first pixel;
a second period in which second image data is written to the second pixel;
a third period in which the first light-emitting element and the second light-emitting element are brought into a light-emitting state and third image data is written to the third pixel and fourth image data is written to the fourth pixel sequentially;
a fourth period in which the first light-emitting element and the second light-emitting element are brought into a non-light-emitting state and the third light-emitting element and the fourth light-emitting element are brought into a light-emitting state; and
a fifth period in which the third light-emitting element and the fourth light-emitting element are brought into a non-light-emitting state,
wherein light exposure is performed on the first light-receiving element in the fourth period, and
wherein light exposure is performed on the second light-receiving element in the fifth period.

9. The method for driving a display device, according to claim 8,
wherein the first sensor pixel comprises a first transistor,
wherein the second sensor pixel comprises a second transistor,
wherein the first transistor comprises a first semiconductor layer provided with a first channel formation region,
wherein the second transistor comprises a second semiconductor layer provided with a second channel formation region, and
wherein the first channel formation region and the second channel formation region are each provided along a side surface of an insulating layer.

10. A method for driving a display device comprising a display region,
wherein a first pixel comprising a first light-emitting element, a second pixel comprising a second light-emitting element, and a sensor pixel comprising a light-receiving element are provided in the display region,
wherein a first operation for writing first image data to the first pixel, a second operation for bringing the first light-emitting element into a light-emitting state, and a third operation for bringing the first light-emitting element into a non-light-emitting state are performed sequentially,
wherein a fourth operation for writing second image data to the second pixel is performed in a period in which the second operation is performed, and then a fifth operation for bringing the second light-emitting element into a light-emitting state and a sixth operation for bringing the second light-emitting element into a non-light-emitting state are performed sequentially,
wherein a period in which the third operation is performed and a period in which the sixth operation is performed partly overlap with each other, and
wherein light exposure is performed on the light-receiving element in the overlap period in which both the third operation and the sixth operation are performed.

11. The method for driving a display device, according to claim 10,
wherein the sensor pixel comprises a transistor,
wherein the transistor comprises a semiconductor layer provided with a channel formation region, and
wherein the channel formation region is provided along a side surface of an insulating layer.

12. The method for driving a display device, according to claim 1,
wherein an infrared light-emitting element emitting infrared light is provided in the display region.
